(19) United States
(12) Patent Application Publication
(10) Pub. No.: US 2022/0204696 A1
(43) Pub. Date: Jun. 30, 2022

(54) PHENOLIC FUNCTIONALIZED POLYIMIDES AND COMPOSITIONS THEREOF

(71) Applicant: Designer Molecules, Inc., San Diego, CA (US)

(72) Inventors: Farhad G Mizori, San Diego, CA (US); Eunsook Chae Barber, San Diego, CA (US)

(21) Appl. No.: 17/604,990

(22) PCT Filed: Apr. 24, 2020
(86) PCT No.: PCT/US2020/029779

§ 371 Date: Oct. 19, 2021

Related U.S. Application Data
(60) Provisional application No. 62/839,566, filed on Apr. 26, 2019.

(51) Int. Cl. C08G 73/10; C08G 59/62; C08G 59/24; C08G 59/32; C08K 3/36; C08J 5/24; C09D 179/08; C09D 7/61; C09J 179/08; C09J 11/04; H05K 3/02; H05K 1/09; H05K 1/02; H05K 1/03; C25D 3/38; C25D 7/00

(52) U.S. Cl. CPC C08G 73/1042; H05K 2201/0355; C08G 73/1032; C08G 73/1021; C08G 73/1053; C08G 73/105; C08G 73/1057; C08G 59/621; C08G 59/245; C08G 59/3218; C08K 3/36; C08J 5/24; C09D 179/08; C09D 7/61; C09J 179/08; C09J 11/04; H05K 3/02; H05K 1/09; H05K 1/028; H05K 3/022; H05K 1/0366; C25D 3/38; C25D 7/00; C08J 2379/08; C08G 73/1082

(57) ABSTRACT

Phenolic-terminated and phenolic pendent curable polyimides with very good dielectric properties have been prepared. These materials in combination with epoxy resins and other co-curable resins are ideal for being transformed into flexible films that are ready to be laminated for example between copper foils for applications such as copper-clad laminates for a variety of electronics applications.

### RELATED APPLICATIONS

This application claims the benefit of priority under 35 USC § 119 of U.S. Provisional Patent Application Ser. No. 62/839,566 (filed Apr. 26, 2019), the entire disclosure of which is incorporated herein by reference.

### FIELD OF INVENTION

The present invention relates to curable polyimides resins with low dielectric constant and low dielectric dissipation factor. In particular, the invention is directed to high molecular weight, flexible polyimide resins that are functionalized with phenolic moieties. The invention is also related to curable polyimide resins that form flexible, rollable films when dried, and upon further heating and curing with epoxies and/or other resins, form flexible thermosets that can be used as the dielectric layer and adhesive layer in forming copper-clad laminates.

### BACKGROUND OF INVENTION

Due to a rapid increase in communication information, there is a strong demand for miniaturization, weight reduction and speed of electronic devices for high-density mounting. The electronics industry has put a greater demand for low dielectric electrically insulating materials and polymers that are adapted for operation in a high frequency environment.

The polymeric materials used in high-power devices must satisfy a number of critical thermal, environmental, and electrical requirements to meet performance criteria for microelectronics applications. The desired attributes include thermal stability, low moisture uptake, high breakdown voltage (low leakage current), low dielectric constant and low dissipation factor. The use of these polymers allows for advanced electronic packaging techniques, resulting in improved system performance and reliability.

To ensure the proper operation of a high-power electronic circuit, proper isolation must be assured between adjacent conductors. High voltage arcing and leakage currents are typical problems encountered in high voltage circuits and are exacerbated at high frequencies. To counter these effects, a good dielectric material must display low values for dielectric constant and dissipation factor (loss tangent) and a high value for breakdown voltage.

### Polyimides

Aliphatic, low modulus maleimide-terminated polyimides have high temperature stability (based on dynamic TGA measurements performed in air). These polyimide materials perform well in very short duration (a few seconds) high temperature excursions, such as solder reflow at 260° C. Yet even these short duration exposures, temperatures greater than 200° C. can cause maleimide-terminated polyimides materials to lose flexibility, while prolonged exposure leads to thermo-oxidative degradation causing the material to turn black and become brittle. Adding antioxidants can remedy some of these problems, however, a large quantity of antioxidant is required to prevent the effect of thermal degradation and aging and antioxidant leaching can occur.

Maleimide oligomers UV-cure much slower than acrylics. In order to aid the UV-curing without adding large amounts of initiator, it would be useful a UV sensitizer built into the system. A potential solution to the problem of leaching would be to make the antioxidant a part of the polymer itself, that way it could be self-healing without the addition of materials that could be depleted over time or affect neighboring materials and structures.

Polyimides are frequently used in photolithography and photoresists, wafer passivation. Polyimide passivation layers of 4-6 microns in thickness protect delicate thin films of metals and oxides on the chip surface from damage during handling and from induced stress after encapsulation in plastic molding compound. Patterning is simple and straightforward. Because of the low defect density and robust plasma etch resistance inherent with polyimide films, a single mask process can be implemented, which permits the polyimide layer to function both as a stress buffer and as a dry etch mask for an underlying silicon nitride layer. In addition, polyimide layers are readily used for flip-chip bonding applications, including both C-4 and dual-layer bond pad redistribution (BPR) applications. Polyimide layers can also be patterned to form the structural components in microelectromechanical systems (MEMS).

Polyimides may also serve as an interlayer dielectric in both semiconductors and thin film multichip modules (MCM-Ds). The low dielectric constant, low stress, high modulus, and inherent ductility of polyimide films make them well suited for these multiple layer applications. Other uses for polyimides include alignment and/or dielectric layers for displays, and as a structural layers in micro machining. In lithium-ion battery technology, polyimide films can be used as protective layers for PTC thermistor (positive temperature coefficient) controllers.

However, polyimides are difficult to process. They are typically applied as a solution of the corresponding polyamic acid precursors onto a substrate, and then thermally cured to smooth, rigid, intractable films and structural layers. The film can be patterned using a lithographic (photographic) process in conjunction with liquid photoresists. Polyimides formed in situ by imidization through cyclodehydration of the polyamic acid precursors require the evaporation of high boiling point, polar aprotic solvents, which can be difficult to remove. Removal typically requires temperature of >300° C., is sometimes referred to as the “hard bake” step. This process is important, because if the polyimide is not fully imidized the material will absorb a great deal of moisture.

Polyimides have been used as interlayer dielectric materials in microelectronic devices such as integrated circuits (ICs) due dielectric constants lower than that of silicon dioxide. Also, such polyimide materials can serve as planarization layers for ICs as they are generally applied in a liquid form, allowed to level, and subsequently cured. However, thermally cured polyimides, can generate stress, which can lead to delamination and can warp thin wafers.

Existing polyimide materials are generally hydrophilic and usually require tedious multi-step processes to form vias required for electrical interconnects. Moreover, polyimides readily absorb moisture even after curing which can result in device failure when the moisture combined with ionic impurities, causes corrosion. Accordingly, there is a need for hydrophobic, polyimides that are compatible with very thin silicon wafers and will not cause warping of thin silicon wafers.

Polyimides are a class of polymers that typically possess very good dielectric properties, they are also known for having very high temperature resistance and very high glass transition temperature (T_{g}) and low coefficient of thermal expansion (CTE).

A major drawback of polyimides is that they are typically synthesized through a polyamic acid intermediate, which must be converted to a polyimide product. Conversion of the polyamic acid to polyimide via a cyclodehydration is often incomplete, leading to poor yields and products with incomplete ring closures that are susceptible to undesirable moisture absorption.

The cyclodehydration can be accomplished by high temperature (200-300° C.) in a film form, in which a solution of polyamic acid is first applied to a substrate and the solvent removed (e.g., by drying at ˜100° C.) to form the film. However, the high temperatures required to obtain a high degree of imidization can be problematic as certain polyimides are unstable at elevated temperatures and functionalizations can prematurely cure at such temperatures. When the process is performed in situ as a film on a substrate (e.g. a metal substrate), the high temperature processing can cause thermo-oxidative damage to the substrate or adjacent electronics elements and devices.

Moreover, the solvents typically used in the production of polyimides are toxic polar aprotic solvents, such as 1-Methyl-2-pyrrolidone (NMP), Dimethylformamide (DMF), Dimethyl sulfoxide (DMSO), and Dimethylacetamide (DMAC), which are increasingly disfavored.

### Flexible Copper-Clad Laminates

Flexible copper-clad laminates (FCCLs) are increasingly used in electronics as they can provide the ultrathin profile demanded by increasing miniaturization and non-conventional, three-dimensional shapes. Polyimide films typically used in the preparation of FCCLs are sold under many brand names such as Dupont™'s Kapton® products. Kapton® is a thermoplastic polyimide with very high temperature resistance, which can been used to form flexible copper-clad laminates (FCCL). However, Kapton® films are not adhesive, necessitating the use of adhesive compositions and films to adhere the Kapton® films to copper foil. Furthermore, Kapton® is dielectric properties are insufficient for high frequency applications. Teflon™ has been added to some forms of Kapton® to reduce dielectric constant and dielectric dissipation factor. The addition of Teflon™ makes Kapton® films even harder to adhere and necessitating special techniques such as plasma treatment and/or etching substrates to improve adhesion.

### Temporary Adhesives

Temporary adhesive tapes and other temporary adhesive compositions are extensively used in wafer backgrinding, wafer dicing and many other processes in electronics fabrication. For temporary applications, adhesives must be fully removable after serving its purpose. However, many of the new processes that are encountered require high temperature stability over 250° C. and for these applications the traditional materials are inadequate because they are unstable at very high temperature and can cause voids and delamination.

### Coatings and Packaging

Curable monomers used in adhesive compositions for electronics packaging must be hydrophobic, have low ionic content, high thermal stability, and good mechanical strength. They must also be thermally stable for extended periods of time at temperatures in excess of 250° C., with little or no weight loss that would cause delamination, and as well as being resistant to many solvents.

Often in electronics applications, a non-filled conformal coating is an appropriate way to protect or encapsulate an electronic component. In this type of application, the coating protects delicate wiring that can easily be damaged (e.g. by shock), and/or circuitry that is susceptible to mechanical damage and/or corrosion.

During certain stages in the assembly of electronics components, such as solder reflow, high temperatures are encountered. Similarly, during operation, electronics components generate heat and thus, adhesives and coatings used must be resistant to high temperatures encountered during assembly and operation. Coatings and adhesives used in electronics must also be very hydrophobic to resist and protect against moisture, which can be very destructive.

In certain applications, such as underfilling, materials are required that have a very high glass transition temperature (T_{g}) along with a very low coefficient of thermal expansion (CTE). In other applications, softer materials are required (i.e., with a low T_{g}). Softer materials are generally more useful as conformal coatings because they can withstand shock and remain flexible even at very cold temperatures.

Thus, there is need for improved polyimides that are both adhesive and have dielectric properties suitable for high-energy, high frequency electronics applications.

### SUMMARY OF THE INVENTION

The invention provides curable polyimides that are the condensation product of a diamine with a dianhydride followed by condensation with an aminophenolic compound to produce a phenol-terminated polyimide. The present invention provides compositions comprising a the phenolic-functionalized polyimide having a structure according to Formula I, II or III:

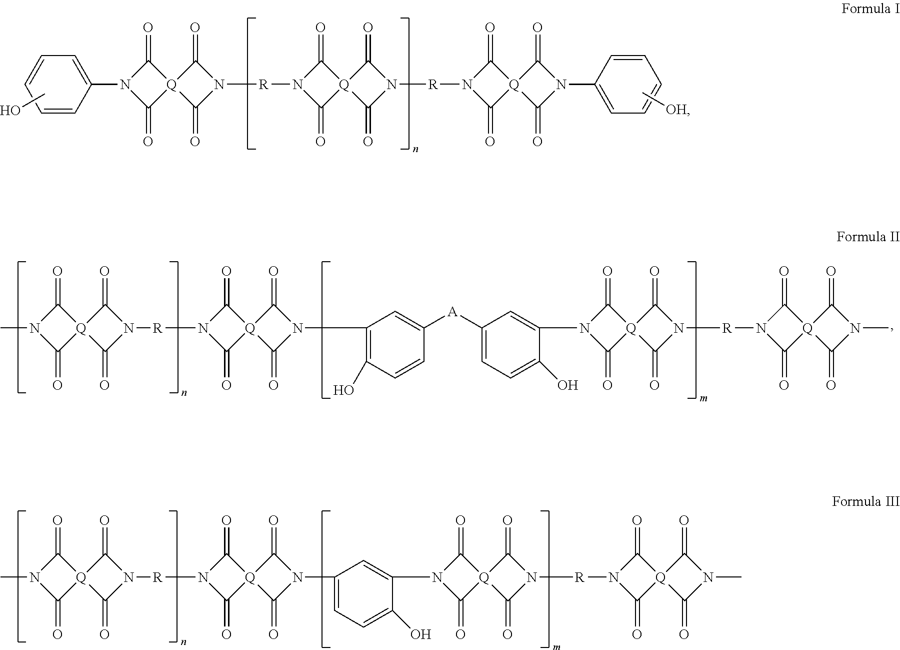

wherein: R is a moiety independently selected from the group consisting of: substituted or unsubstituted aromatic, heteroaromatic aliphatic, cycloaliphatic, alkenyl, polyether, polyester, polyamide, and siloxane; Q is a moiety independently selected from the group consisting of: substituted or unsubstituted aromatic, heteroaromatic aliphatic, cycloaliphatic, alkenyl, polyether, polyester, polyamide, and siloxane; A is a moiety independently selected from the group consisting of: substituted or unsubstituted aromatic, heteroaromatic aliphatic, cycloaliphatic, alkenyl, polyether, polyester, polyamide, and siloxane; and n and m are each independently 0 or an integer having the value from 1-100; with the proviso that the average molecular weight of the polyimide is greater than 20,000 Daltons, such as 25,000 to 50,000 Dalton. In some aspects, n and m are each independently 20-100.

In some embodiments, the compositions further comprise anisole.

R can be a moiety selected from the group consisting of:

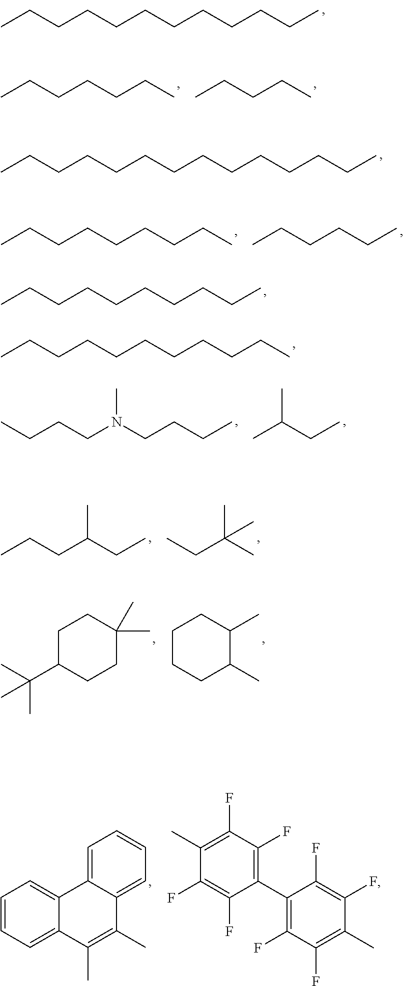

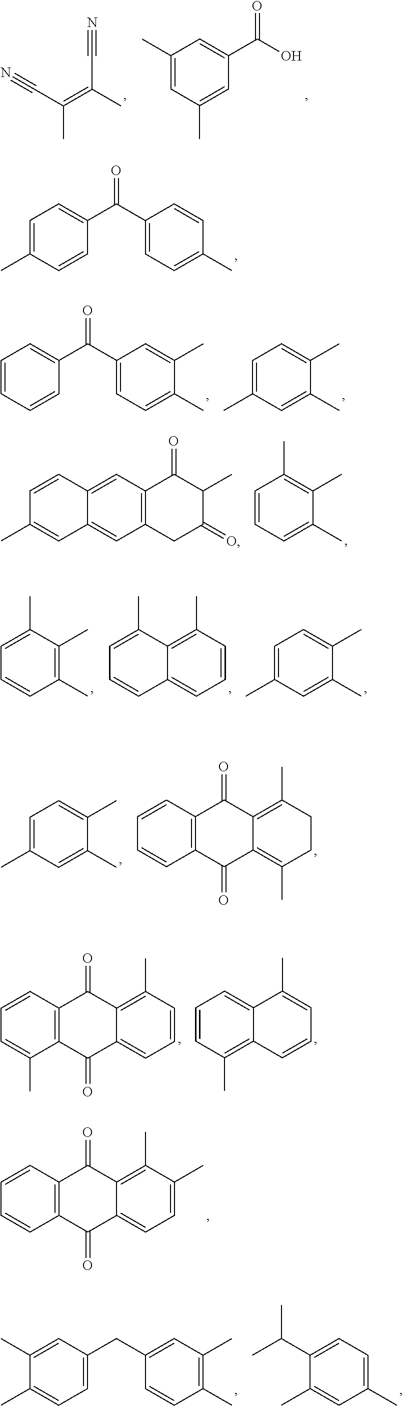

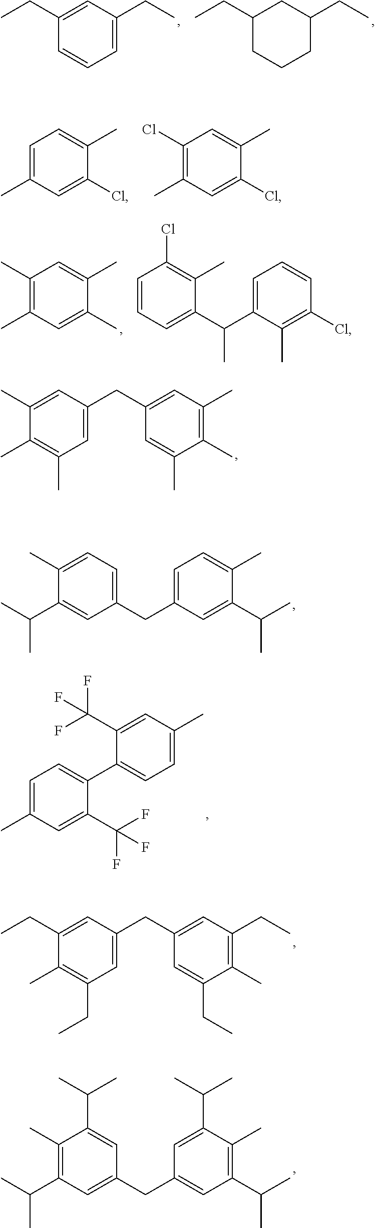

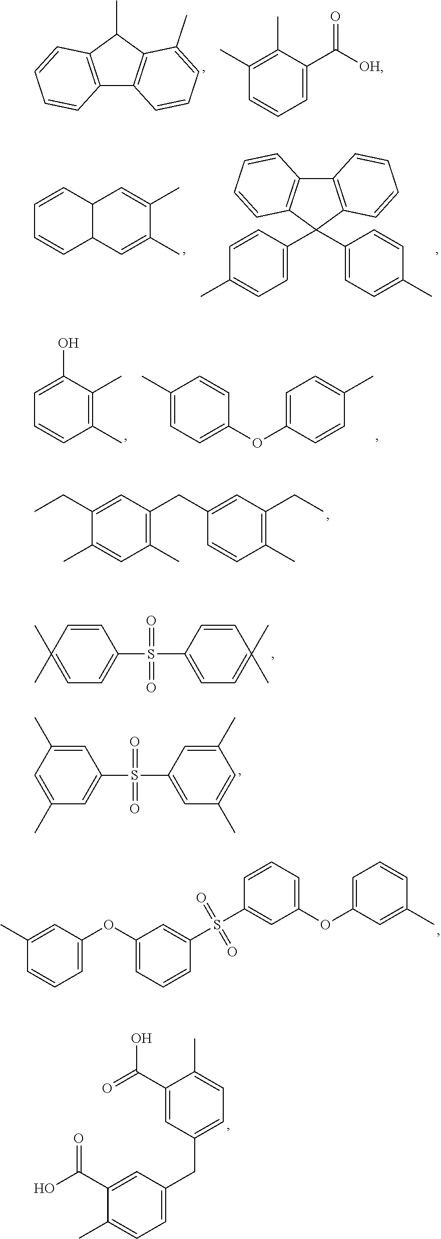

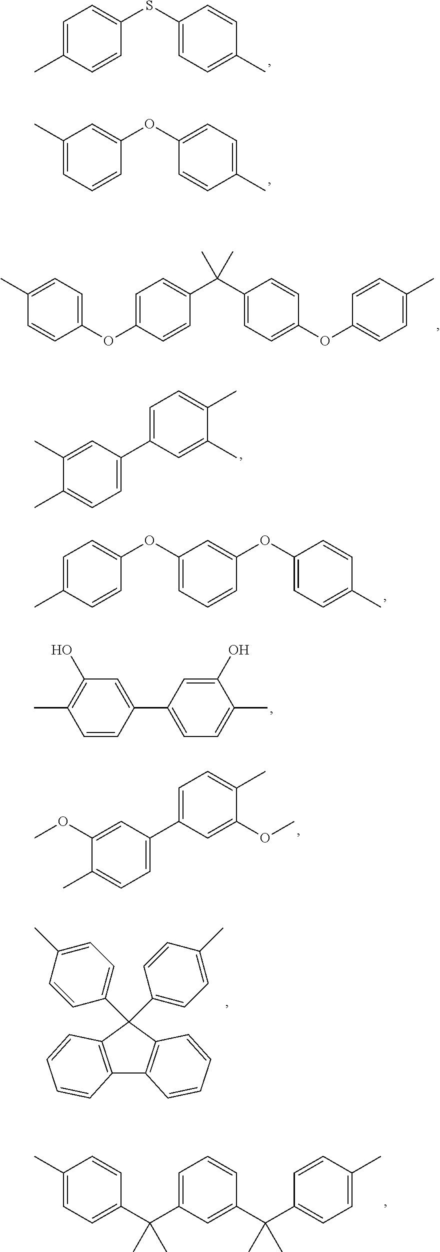

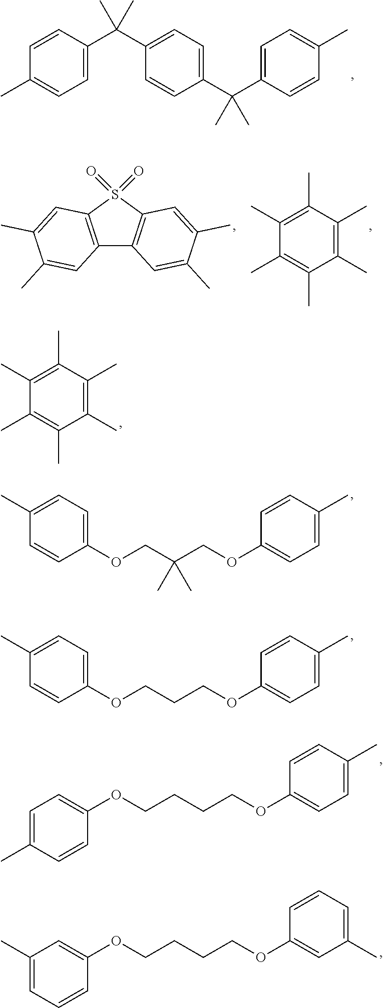

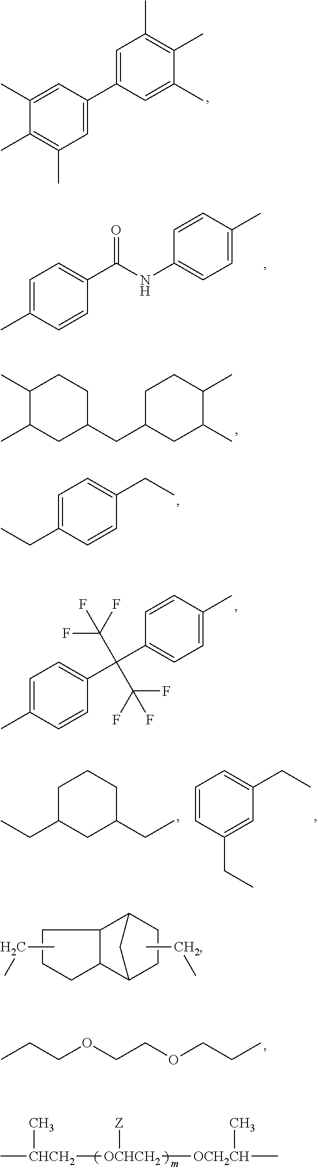

wherein Z is H or Me and m is an integer wherein the average molecular weight between 200 and 800 Daltons, or combinations thereof.

Q can be a moiety selected from the group consisting of:

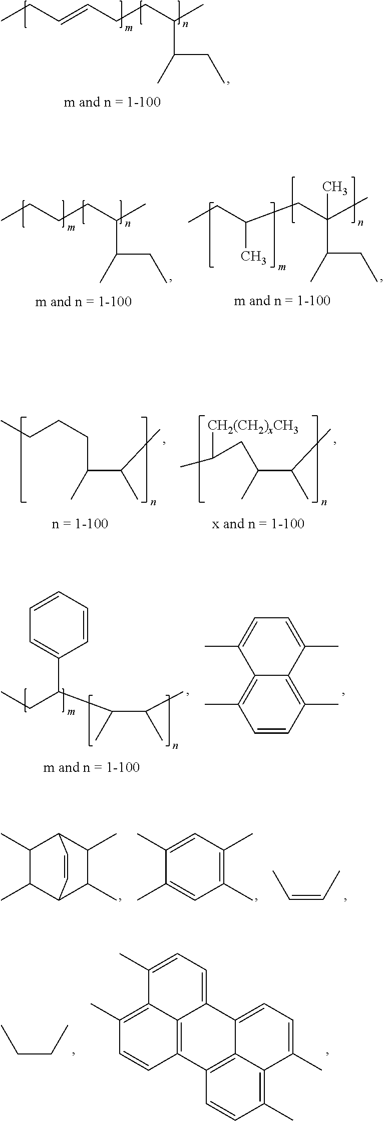

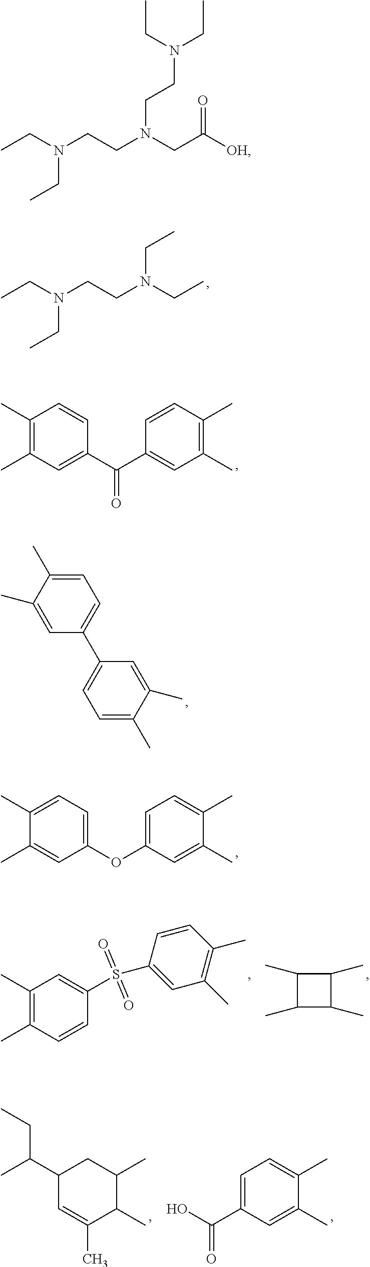

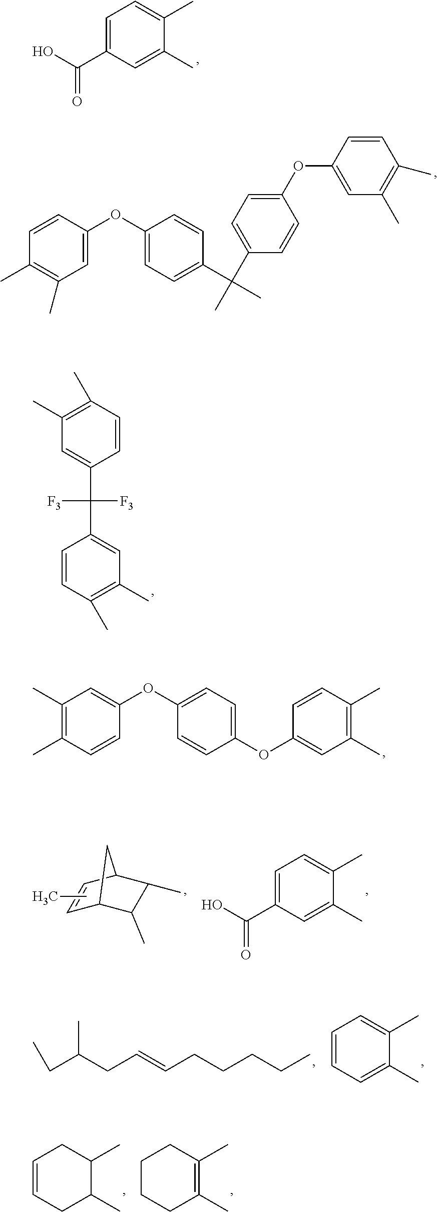

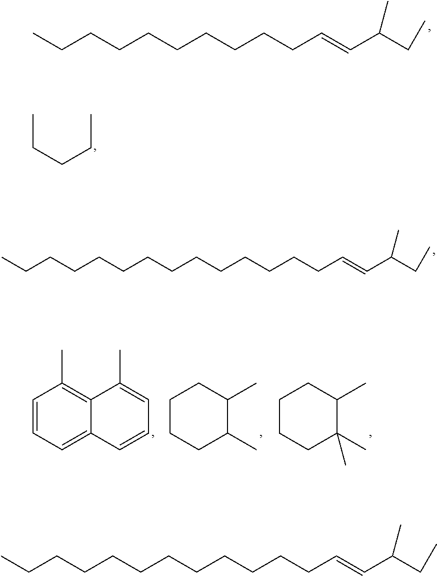

and combinations thereof.

In some embodiments of the invention, the phenolic-functionalized polyimide is the product of a condensation of at least one diamine with at least one dianhydride.

The at least one diamine can include a diamine selected from the group:

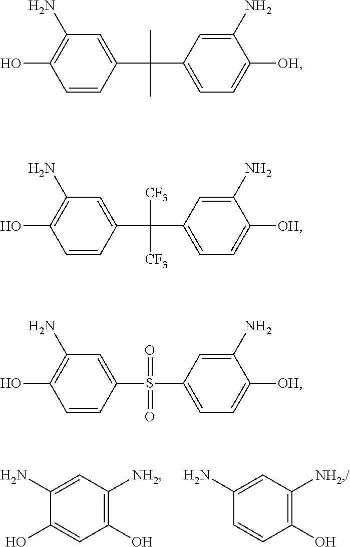

and combinations thereof.

In certain aspects, the at least one diamine can include one or more diamines selected from: 1,10-diaminodecane; 1,12-diaminododecane; dimer diamine; hydrogenated dimer diamine; 1,2-diamino-2-methylpropane; 1,2-diaminocyclohexane; 1,2-diaminopropane; 1,3-diaminopropane; 1,4-diaminobutane; 1,5-diaminopentane; 1,7-diaminoheptane; 1,8-diaminomenthane; 1,8-diaminooctane; 1,9-diaminononane; 3,3′-diamino-N-methyldipropylamine; diaminomaleonitrile; 1,3-diaminopentane; 9,10-diaminophenanthrene; 4,4′-diaminooctafluorobiphenyl; 3,5-diaminobenzoic acid; 3,7-diamino-2-methoxyfluorene; 4,4′-diaminobenzophenone; 3,4-diaminobenzophenone; 3,4-diaminotoluene; 2,6-diaminoanthroquinone; 2,6-diaminotoluene; 2,3-diaminotoluene; 1,8-diaminonaphthalene; 2,4-diaminotoluene; 2,5-diaminotoluene; 1,4-diaminoanthroquinone; 1,5-diaminoanthroquinone; 1,5-diaminonaphthalene; 1,2-diaminoanthroquinone; 2,4-cumenediamine; 1,3-bisaminomethylbenzene; 1,3-bisaminomethylcyclohexane; 2-chloro-1,4-diaminobenzene; 1,4-diamino-2,5-dichlorobenzene; 1,4-diamino-2,5-dimethylbenzene; 4,4′-diamino-2,2′-bistrifluoromethylbiphenyl; bis(amino-3-chlorophenyl)ethane; bis(4-amino-3,5-dimethylphenyl)methane; bis(4-amino-3,5-diisopropylphenyl)methane; bis(4-amino-3,5-methyl-isopropylphenyl)methane; bis(4-amino-3,5-diethylphenyl)methane; bis(4-amino-3-ethylphenyl)methane; diaminofluorene; 4,4′-(9-Fluorenylidene)dianiline; diaminobenzoic acid; 2,3-diaminonaphthalene; 2,3-diaminophenol; -5-methylphenyl)methane; bis(4-amino-3-methylphenyl)methane; bis(4-amino-3-ethylphenyl)methane; 4,4′-diaminophenylsulfone; 3,3′-diaminophenylsulfone; 2,2-bis(4-(4-aminophenoxy)phenyl)sulfone; 2,2-bis(4-(3-aminophenoxy)phenyl)sulfone; 4,4′-oxydianiline; 4,4′-diaminodiphenyl sulfide; 3,4′-oxydianiline; 2,2-bis(4-(4-aminophenoxy)phenyl)propane; 1,3-bis(4-aminophenoxy)benzene; 4,4′-bis(4-aminophenoxy)biphenyl; 4,4′-diamino-3,3′-dihydroxybiphenyl; 4,4′-diamino-3,3′-dimethylbiphenyl; 4,4′-diamino-3,3′-dimethoxybiphenyl; Bisaniline M; Bisaniline P; 9,9-bis(4-aminophenyl)fluorene; o-tolidine sulfone; methylene bis(anthranilic acid); 1,3-bis(4-aminophenoxy)-2,2-dimethylpropane; 1,3-bis(4-aminophenoxy)propane; 1,4-bis(4-aminophenoxy)butane; 1,5-bis(4-aminophenoxy)butane; 2,3,5,6-tetramethyl-1,4-phenylenediamine; 3,3′,5,5′-tetramehylbenzidine; 4,4′-diaminobenzanilide; 2,2-bis(4-aminophenyl)hexafluoropropane; polyoxyalkylenediamines; 1,3-cyclohexanebis(methylamine); m-xylylenediamine; p-xylylenediamine; bis(4-amino-3-methylcyclohexyl)methane; 1,2-bis(2-aminoethoxy)ethane; and 3(4),8(9)-bis(aminomethyl)tricyclo(5.2.1.0^{2,6})decane and combinations thereof.

The at least one dianhydride can include one or more dianhydride selected from: polybutadiene-graft-maleic anhydride; polyethylene-graft-maleic anhydride; polyethylene-alt-maleic anhydride; polymaleic anhydride-alt-1-octadecene; polypropylene-graft-maleic anhydride; poly(styrene-co-maleic anhydride); pyromellitic dianhydride; maleic anhydride, succinic anhydride; 1,2,3,4-cyclobutanetetracarboxylic dianhydride; 1,4,5,8-naphthalenetetracarboxylic dianhydride; 3,4,9,10-perylenentetracarboxylic dianhydride; bicyclo(2.2.2)oct-7-ene-2,3,5,6-tetracarboxylic dianhydride; diethylenetriaminepentaacetic dianhydride; ethylenediaminetetraacetic dianhydride; 3,3′,4,4′-benzophenone tetracarboxylic dianhydride; 3,3′,4,4′-biphenyl tetracarboxylic dianhydride; 4,4′-oxydiphthalic anhydride; 3,3′,4,4′-diphenylsulfone tetracarboxylic dianhydride; 2,2′-bis(3,4-dicarboxyphenyl)hexafluoropropane dianhydride; 4,4′-bisphenol A diphthalic anhydride; 5-(2,5-dioxytetrahydro)-3-methyl-3-cyclohexene-1,2-dicarboxylic anhydride; ethylene glycol bis(trimellitic anhydride); hydroquinone diphthalic anhydride; allyl nadic anhydride; 2-octen-1-ylsuccinic anhydride; phthalic anhydride; 1,2,3,6-tetrahydrophthalic anhydride; 3,4,5,6-tetrahydrophthalic anhydride; 1,8-naphthalic anhydride; glutaric anhydride; dodecenylsuccinic anhydride; hexadecenylsuccinic anhydride; hexahydrophthalic anhydride; methylhexahydrophthalic anhydride; tetradecenylsuccinic anhydride; and combinations thereof.

The compositions of the invention can include co-reactants, fillers, catalysts, initiators, coupling agents and combinations thereof. In one embodiment, the composition includes an epoxy resin, at least one anionic initiator and at least one coupling agent.

The co-reactant can include oxetanes, cyanate esters, benzoxazines and combinations thereof.

The co-reactant can be a co-curing resin, such as an epoxy resin, a cyanate ester resin, a benzoxazine resin, a bismaleimide resin, a phenolic resin, a carboxyl resin, a liquid crystal polymer resin, a reactive ester resins, an acrylic resin, a tackifier, an oxetane, a cyanate ester and combinations thereof.

The epoxy can be one or more phenyl glycidyl ether; a cresyl glycidyl ether; a nonylphenyl glycidyl ether; a p-tert-butylphenyl glycidyl ether; a diglycidyl or polyglycidyl ether of any of: bisphenol A, of bisphenol F, ethylidenebisphenol, dihydroxydiphenyl ether, bis(4-hydroxyphenyl)sulfone, bis(hydroxyphenyl)sulfide, 1,1-bis(hydroxyphenyl)cyclohexane, 9,19-bis(4-hydroxyphenyl)fluorene, 1,1,1-tris(hydroxyphenyl)ethane, tetrakis(4-hydroxyphenyl)ethane, trihydroxytritylmethane, 4,4′-(1-alpha-methylbenzylidene)bisphenol, 4,4′-dihydroxybenzophenone, dihydroxy naphthalene, 2,2′-dihydroxy-6,6′-dinaphthyl disulfide, a 1,8,9-trihydroxyanthracene, resorcinol, catechol and tetrahydroxydiphenyl sulfide; triglycidyl-p-aminophenol; N,N,N′,N′-tetraglycidyl-4,4′-diphenylmethane; triglycidyl isocyanurate; a glycidyl ether of a cresol formaldehyde condensate; a glycidyl ether of a phenol formaldehyde condensate; a glycidyl ether of a cresol dicyclopentadiene addition compound; a glycidyl ether of a phenol dicyclopentadiene addition compound; a diglycidyl ether of 1,4 butanediol; a diglycidyl ether of diethylene glycol; a diglycidyl ether of neopentyl glycol; a diglycidyl ether of cyclohexane dimethanol; a diglycidyl ether of tricyclodecane dimethanol; a trimethyolethane triglycidyl ether; mono- or diglycidyl ether of naphthalene derivative; perfluorinated alkyl glycidyl ethers; a trimethyol propane triglycidyl ether; a glycidyl ether of a polyglycol; a polyglycidyl ether of castor oil; a polyoxypropylene diglycidyl ether; a glycidyl derivative of an aromatic amine.

In certain embodiments, the epoxy is selected from:

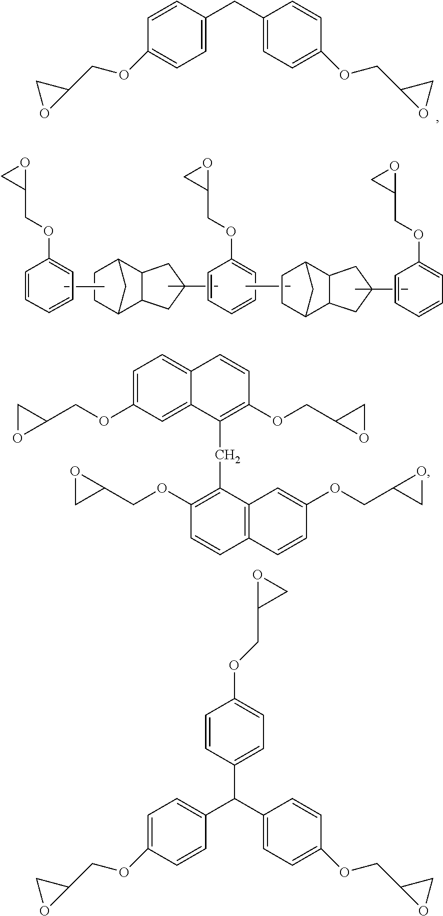

and combinations thereof.

In other embodiments, the epoxy is an epoxy-terminated polydimethylsiloxanes, and epoxy functionalized cyclosiloxanes, epoxy functionalized polyhedral oligomeric silsesquioxane (POSS), or a combination thereof.

The epoxy can be 1 to about 90 weight %, about 5 to about 50 weight %, or about 10 to about 25 weight %, of the composition, based on the total weight of the composition.

The catalyst can be an anionic curing catalyst, such as imidazole; 1-benzyl-2-phenylimidazole (1B2PZ); 1-benzyl-2-methylimidazole (1B2MZ); 2-phenyl-4-methylimidazole (2P4MZ); 2-phenylimidazole (2PZ); 2-ethyl-4-methylimidazole (2E4MZ); 1,2-dimethylimidazole (1.2DMZ); 2-heptadecylimidazole (C17Z); 2-undecylimidazole (C11Z); 2-methylimidazole (2MZ); imidazole (SIZ); 1-cyanoethyl-2-methylimidazole (2MZ-CN); 1-cyanoethyl-2-undecylimidazole (C11Z-CN); 1-cyanoethyl-2-ethyl-4-methylimidazole (2E4MZ-CN); 1-cyanoethyl-2-phenylimidazole (2PZ-CN); 1-cyanoethyl-2-phenylimidazolium-trimellitate (2PZCNS-PW); 1-cyanoethyl-2-undecylimidazolium-trimellitate (C11Z-CNS); 2,4-diamino-6-[2′-ethyl-4′-methylimidazolyl-(1′)]-ethyl-s-triazine (2E4MZ-A); 2,4-diamino-6-[2′-undecylimidazolyl-(1′)]-ethyl-s-triazine (C11Z-A); 2,4-diamino-6-[2′-methylimidazolyl-(1′)]-ethyl-s-triazine (2MZA-PW); 2,4-diamino-6-[2′-methylimidazolyl-(1′)]-ethyl-s-triazine (2MZ-A); 2-phenylimidazoleisocyanuric acid adduct (2PZ-OK); 2,4-diamino-6-[2′-methylimidazolyl-(1′)]-ethyl-s-triazineisocyanuric acid adduct dehydrate (2MA-OK); 2-phenyl-4-methyl-5-hydroxymethylimidazole (2P4MHZ-PW); 2-phenyl-4,5-dihydroxymethylimidazole (2PHZ-PW); 1-dodecyl-2-methyl-3-benzylimidazolium chloride (SFZ); 2,3-dihydro-1H-pyrrolo[1,2-a]benzimidazole (TBZ); 2-phenylimidazoline (2PZL-T); 2,4-diamino-6-methacryloyloxyethyl-1,3,5-triazine (MAVT); 2,4-diamino-6-vinyl-1,3,5-triazineisocyanuric acid adduct (OK); 2,4-diamino-6-vinyl-1,3,5-triazine (VT); Imidazole-4-carboxaldehyde (4FZ); 2-Phenylimidazole-4-carboxaldehyde (2P4FZ); Imidazole-2 carboxaldehyde (2FZ); Imidazole-4-carbonitrile (4CNZ); 2-Phenylimidazole-4-carbonitrile (2P4CNZ); 4-Hydroxymethylimidazolehydrochloride (4HZ-HCL); 2-Hydroxymethylimidazolehydrochloride (2HZ-HCL); Imidazole-4-carboxylic acid (4GZ); Imidazole-4-dithiocarboxylic acid (4SZ); Imidazole-4-thiocarboxamide (4TZ); 2-Bromoimidazole (2BZ); 2-Mercaptoimidazole (2SHZ); 1,2,4-Triazole-1-carboxamidinehydrochloride (TZA); (t-Butoxycarbonylimino-[1,2,4]triazol-1-yl-Methyl)-carbamic acid t-butyl ester (TZA-BOC); Thiazole-2-carboxaldehyde (2FTZ); Thiazole-4-carboxaldehyde (4FTZ); Thiazole-5-carboxaldehyde (5FTZ); Oxazole-2-carboxaldehyde (2FOZ); Oxazole-4-carboxaldehyde (4FOZ); Oxazole-5-carboxaldehyde (5FOZ); Pyrazole-4-carboxaldehyde (4FPZ); Pyrazole-3-carboxaldehyde (3FPZ); 1-azabicyclo[2.2.2]octane (ABCO); 1,4-diazabicyclo[2.2.2]octane (DABCO); 1,5-diazabicyclo[4.3.0]non-5-ene (DBN); 1,8-diazabicyclo[5.4.0]undec-7-ene (DBU); 1,5,7-triazabicyclo[4.4.0]dec-5-ene (TBD); 7-methyl-1,5,7-triazabicyclo[4.4.0]dec-5-ene (MTBD); 1,2,2,6,6-pentamethylpiperidine (PMP); 4-(dimethylamino)-1,2,2,6,6-pentamethylpiperidine; or a combination thereof.

The anionic curing catalyst can be about 0.1 to about 10-weight %, or about 0.5 to about 5 weight % of the composition, based on the total weight of the composition.

The filler comprises include at least one filler selected from silica, polytetrafluoroethylene, alumina, boron nitride, carbon black, carbon nanotubes and combinations thereof.

In other aspects, the filler can be a conductive filler such gold, copper, silver; platinum, palladium and combinations and alloys thereof.

In certain aspects of the compositions of the invention are adhesive, including removable adhesives, which can be a film or a coating. In some aspects, the adhesive is B-staged or is cured.

The present invention also provides methods for preparing prepregs including the steps of: providing a reinforcing fiber (e.g., woven or unwoven fabric); and immersing the reinforcing fiber in a liquid formulation of an uncured composition that includes any phenolic-functionalized polyimide compound described herein. The method can include draining excess liquid formulation and drying the prepreg for storage.

Also included in the invention are prepregs prepared by the methods disclosed herein.

The present invention also includes methods for preparing copper-clad laminates (CCL) including the steps of disposing copper on one or both sides of a prepreg described herein. Disposing can be by electroplating copper to the one or the both sides of the prepreg, or by laminating copper foil to one or the both sides of the prepreg.

The invention also provides CCL comprising a reinforcing fiber impregnated with a composition of the invention, which may be a CCL prepared according to a method described above.

Methods are also provided for preparing a printed circuit board (PCB) including the steps of providing the etching circuit traces in the copper disposed on one or the both sides of a CCL of the invention. A method for preparing a flexible copper-clad laminate (FCCL) comprising the steps of: providing a film comprising a phenolic-functionalized polyimide compound of the invention, applying an adhesive to one of both sides of the film (which can be an adhesive film), and laminating copper foil to the adhesive on the one or the both sides of the film

The invention also provides FCCLs that include a film formulation described herein having copper foil laminated to one or both sides of the film, with or without an adhesive layer between each copper foil and the film. In certain embodiments, the film is an adhesive film.

The invention also provides FCCLs prepared according any method described herein.

Methods provided for preparing thin, flexible electronic circuits, include providing an FCCL of the invention and etching circuit traces in the copper foil on one or both sides of the FCCL.

Thin, flexible electronic circuits provided by the invention include a cured layer of adhesive film having copper circuit traces on one or both sides of the adhesive film.

Methods for backgrinding a wafer, are also provided, that include the steps of: applying a removable adhesive composition of the invention to the top of a wafer (e.g. by spin-coating); adhering the wafer to a support; grinding and polishing the wafer; removing the wafer from the support; and removing the adhesive from the wafer. The adhesive can be removed by applying an air jet to the removable adhesive composition; and peeling the adhesive from the temporary wafer and can further include soaking the wafer in a chemical solvent (such as cyclopentanone, cyclohexanone and combinations thereof) that removes residual adhesive

Method are also provided for dicing a wafer, including applying a temporary adhesive of the invention to the top or bottom side of a wafer (e.g. by spin-coating or by a dicing tape); adhering the wafer to a frame; cutting the wafer to singulate individual die; removing the die from the wafer; and removing the adhesive from the die.

Removing the adhesive can be, e.g. by the same methods used for backgrinding.

Also provided are methods for synthesizing a phenolic-functionalized compound having a structure according to Formula I, II or III:

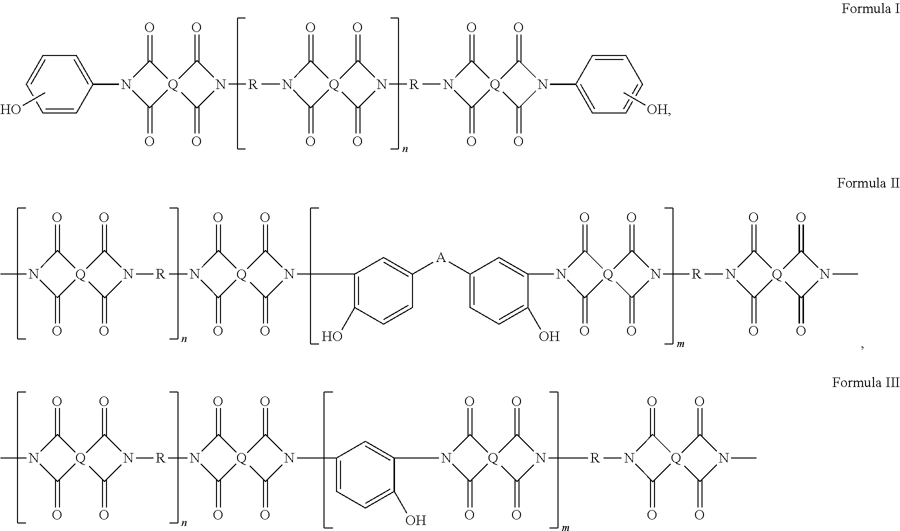

R, Q, A, n and m are as described above and the polyimide is greater than 20,000 Daltons, by providing at least one diamine and at least one dianhydride; combining the at least one diamine with the at least one dianhydride in a solvent (e.g. anisole) to form a mixture; refluxing the mixture, thereby forming a polyamic acid in the solution; and azeotropically distilling the polyamic acid in the solution; thereby forming an amine-terminated polyimide in the solution; where either: the at least one diamine comprises a phenol functionality; the at least one dianhydride comprises a phenol functionality; or by further including the step of functionalizing the amine-terminated polyimide by reacting the terminal amine groups to form a phenol functional terminal moiety.

The diamines and dianhydrides can be any of those listed above, and are typically combined at an equivalent ratio of about 1:1 (i.e., about 1.01:1 to about 1.10:1; about 1.02:1 to about 1.09:1; about 1.03:1 to about 1.08:1; about 1.04:1 to about 1.07:1; or about 1.05:1 to about 1.06)

### BRIEF DESCRIPTION OF THE DRAWINGS

FIG. 1 is a schematic flow diagram illustrating the process of making a printed circuit board including preparing a prepreg, laminating copper onto the prepreg, and etching a circuit pattern on the copper-cladding. Arrows A-E indicate steps in the process.

FIG. 2 is a cross-sectional view through the structures at plane XVII of FIG. 1.

FIG. 3A is a schematic flow diagram illustrating the process of producing a one-sided flexible copper-clad laminate (FCCL) according to one embodiment of the invention that includes an adhesive layer. Arrows A and B indicate steps in the process.

FIG. 3B is a schematic flow diagram illustrating the process of producing a one-sided flexible copper-clad laminate (FCCL) according an embodiment of the invention that includes layers of adhesive. Arrows A and B indicate steps in the process.

FIG. 4A is a schematic flow diagram illustrating the process of producing a one-sided flexible copper-clad laminate (FCCL) according to one embodiment of the invention that omits an adhesive layer. Arrows A and B indicate steps in the process.

FIG. 4B is a schematic flow diagram illustrating the process of producing a one-sided flexible copper-clad laminate (FCCL) according an embodiment of the invention that excludes layers of adhesive. Arrows A and B indicate steps in the process.

FIG. 5. is a schematic flow diagram illustrating the process of backgrinding according to an embodiment of the invention. Solid arrows indicate direction according to an embodiment of the invention. Broken arrows A-H indicate steps in the process.

FIGS. 6A and 6B are consecutive parts of a schematic flow diagram illustrating the process of wafer dicing according to an embodiment of the invention. They are intended to be viewed together as a single diagram. Arrows A-F indicate steps in the process

FIG. 7A is a cross-sectional view through the structures at plane I of FIG. 6A.

FIG. 7B is a cross-sectional view through the structures at plane II of FIG. 6B.

FIG. 7C is a cross-sectional view through the structures at plane III of FIG. 6A.

FIG. 7D is a cross-sectional view through the structures at plane IV of FIG. 6A.

FIG. 7E is a cross-sectional view through the structures at plane V of FIG. 6A.

FIG. 7F is a cross-sectional view through the structures at plane VI of FIG. 6A.

FIG. 7G is a cross-sectional view through the structures at plane VII of FIG. 6B.

FIG. 7H is a cross-sectional view through the structures at plane VII of FIG. 6B.

FIG. 7I is a cross-sectional view through the structures at plane IX of FIG. 6B.

FIG. 7J is a cross-sectional view through the structures at plane X of FIG. 6B.

### DETAILED DESCRIPTION

It is to be understood that both the foregoing general description and the following detailed description are exemplary and explanatory only and are not restrictive of the invention claimed. As used herein, the use of the singular includes the plural unless specifically stated otherwise. It is to be understood that as used in the specification and in the claims, “a” or “an” can mean one or more, depending upon the context in which it is used. Thus, reference to “a compound” can mean that at least one compound molecule is used, but typically refers to a plurality of compound molecules, which may be the same or different species. For example, “a compound having a structure according to the following Formula I” can refer to a single molecule or a plurality of molecules encompassed by the formula, as well all or a subset of the species the formula describes. As used herein, “or” means “and/or” unless stated otherwise. Furthermore, use of the term “including” as well as other forms, such as “includes,” and “included,” is not limiting.

The section headings used herein are for organizational purposes only and are not to be construed as limiting the subject matter described.

Unless specific definitions are provided, the nomenclatures utilized in connection with, and the laboratory procedures and techniques of analytical chemistry, synthetic organic and inorganic chemistry described herein are those known in the art, such as those set forth in “IUPAC Compendium of Chemical Terminology: IUPAC Recommendations (The Gold Book)” (McNaught ed.; International Union of Pure and Applied Chemistry, 2^{nd} Ed., 1997) and “Compendium of Polymer Terminology and Nomenclature: IUPAC Recommendations 2008” (Jones et al., eds; International Union of Pure and Applied Chemistry, 2009). Standard chemical symbols are used interchangeably with the full names represented by such symbols. Thus, for example, the terms “hydrogen” and “H” are understood to have identical meaning. Standard techniques may be used for chemical syntheses, chemical analyses, and formulation.

### Definitions

“About” as used herein, means that a number referred to as “about” comprises the recited number plus or minus 1-10% of that recited number. For example, “about” 100 degrees can mean 95-105 degrees or as few as 99-101 degrees depending on the situation. Whenever it appears herein, a numerical range such as “1 to 20” refers to each integer in the given range; e.g., “1 to 20 carbon atoms” means that an alkyl group can contain only 1 carbon atom, 2 carbon atoms, 3 carbon atoms, etc., up to and including 20 carbon atoms (although the term “alkyl” also includes instances where no numerical range of carbon atoms is designated). Where “about” modifies a range expressed in non-integers, it means the recited number plus or minus 1-10% to the same degree of significant figures expressed. For example, about 1.50 to 2.50 mM can mean as little as 1.35 mM or as much as 2.75 mM or any amount in between in increments of 0.01. Where a range described herein includes decimal values, such as “1.2% to 10.5%”, the range refers to each decimal value of the smallest increment indicated in the given range; e.g. “1.2% to 10.5%” means that the percentage can be 1.2%, 1.3%, 1.4%, 1.5%, etc. up to and including 10.5%; while “1.20% to 10.50%” means that the percentage can be 1.20%, 1.21%, 1.22%, 1.23%, etc. up to and including 10.50%.

As used herein, the term “substantially” refers to a great extent or degree. More specifically, “substantially all” or equivalent expressions, typically refers to at least about 90%, frequently at least about 95%, often at least 99%, and more often at least about 99.9%. “Not substantially” refers to less than about 10%, frequently less than about 5%, and often less than about 1% such as less than 5%, less than 4%, less than 3%, less than 2%, or less than 1%. “Substantially free” or equivalent expressions, typically refers to less than about 10%, frequently less than about 5%, often less than about 1%, and in certain aspects less than about 0.1%.

“Adhesive” or “adhesive compound” as used herein, refers to any substance that can adhere or bond two items together. Implicit in the definition of an “adhesive composition” or “adhesive formulation” is the fact that the composition or formulation is a combination or mixture of more than one species, component or compound, which can include adhesive monomers, oligomers, and/or polymers along with other materials, whereas an “adhesive compound” refers to a single species, such as an adhesive polymer or oligomer.

More specifically, adhesive composition refers to un-cured mixtures in which the individual components in the mixture retain the chemical and physical characteristics of the original individual components of which the mixture is made. Adhesive compositions are typically malleable and may be liquids, pastes, gels, films or another form that can be applied to an item so that it can be bonded to another item.

“Cured adhesive,” “cured adhesive composition” or “cured adhesive compound” refers to adhesive components and mixtures obtained from reactive curable original compounds or mixtures thereof which have undergone a chemical and/or physical changes such that the original compounds or mixtures are transformed into a solid, substantially non-flowing material. A typical curing process may involve crosslinking.

“Curable” means that an original compounds or composition can be transformed into a solid, substantially non-flowing material by means of chemical reaction, crosslinking, radiation crosslinking, or a similar process. Thus, adhesive compounds and compositions of the invention are curable, but unless otherwise specified, the original compounds and compositions are not cured.

As used herein, terms “functionalize”, “functionalized” and “functionalization” refer to the addition or inclusion of a moiety (“functional moiety” or “functional group”) to a molecule that imparts a specific property, often the ability of the functional group to react with other molecules in a predictable and/or controllable way. In certain embodiments of the invention, functionalization is imparted to a terminus of the molecule through the addition or inclusion of a terminal group, X. In other embodiments, internal and/or pendant functionalization can be included in the polyimides of the invention. In some aspects of the invention, the functional group is a “curable group” or “curable moiety”, which is a group or moiety that allows the molecule to undergo a chemical and/or physical change such that the original molecule is transformed into a solid, substantially non-flowing material. “Curable groups” or “curable moieties” may facilitate crosslinking.

“Cross-linking,” as used herein, refers to the attachment of two or more oligomer or longer polymer chains by bridges of an element, a molecular group, a compound, or another oligomer or polymer. Crosslinking may take place upon heating or exposure to light; some crosslinking processes may occur at room temperature or a lower temperature. As cross-linking density is increased, the properties of a material can be changed from thermoplastic to thermosetting.

“Rollable” and “rollability”, as used herein, refers to the ability of a material, such as a polymer film, typically a thin polymer film about 10 μm to about 2.0 mm thickness and to be rolled into a cylindrical shape without resistance or cracking. Typically, rollable materials of the invention can be rolled, unrolled and repeatedly rolled again without damage. Very flexible polymers, such as the high molecular weight polyimides of the invention, are required to withstand such manipulation. “Rollability” is an indication that the material will also withstand the rigorous handling that flexible printed circuits may encounter in use.

As used herein, “B-stageable” refers to the properties of an adhesive having a first solid phase followed by a tacky rubbery stage at elevated temperature, followed by yet another solid phase at an even higher temperature. The transition from the tacky rubbery stage to the second solid phase is thermosetting. However, prior to thermosetting, the material behaves similarly to a thermoplastic material. Thus, such adhesives allow for low lamination temperatures while providing high thermal stability.

A “die” or “semiconductor die” as used herein, refers to a small block of semiconducting material, on which a functional circuit is fabricated.

“Chip” as used herein, refers to die fabricated with a functional circuit, (e.g., a set of electronic circuits or an integrated circuit).

A “flip-chip” semiconductor device is one in which a semiconductor die is directly mounted to a wiring substrate, such as a ceramic or an organic printed circuit board. Conductive terminals on the semiconductor die, usually in the form of solder bumps, are directly physically and electrically connected to the wiring pattern on the substrate without use of wire bonds, tape-automated bonding (TAB), or the like. Because the conductive solder bumps making connections to the substrate are on the active surface of the die or chip, the die is mounted in a facedown manner, thus the name “flip-chip.”

The term “photoimageable”, as used herein, refers to the ability of a compound or composition to be selectively cured only in areas exposed to light. The exposed areas of the compound are thereby rendered cured and insoluble, while the unexposed area of the compound or composition remains un-cured and therefore soluble in a developer solvent. Typically, this operation is conducted using ultraviolet light as the light source and a photomask as the means to define where the exposure occurs. The selective patterning of dielectric layers on a silicon wafer can be carried out in accordance with various photolithographic techniques known in the art. In one method, a photosensitive polymer film is applied over the desired substrate surface and dried. A photomask containing the desired patterning information is then placed in close proximity to the photoresist film. The photoresist is irradiated through the overlying photomask by one of several types of imaging radiation including UV light, e-beam electrons, x-rays, or ion beam. Upon exposure to the radiation, the polymer film undergoes a chemical change (cross-links) with concomitant changes in solubility. After irradiation, the substrate is soaked in a developer solution that selectively removes the non-cross-linked or unexposed areas of the film.

The term “passivation” as used herein, refers to the process of making a material “passive” in relation to another material or condition. The term “passivation layers” (PLs) refers to layers that are commonly used to encapsulate semiconductor devices, such as semiconductor wafers, to isolate the device from its immediate environment and, thereby, to protect the device from oxygen, water, etc., as well airborne or space-borne contaminants, particulates, humidity and the like. Passivation layers are typically formed from inert materials that are used to coat the device. This encapsulation process also passivates semiconductor devices by terminating dangling bonds created during manufacturing processes and by adjusting the surface potential to either reduce or increase the surface leakage current associated with these devices. In certain embodiments of the invention, passivation layers contain dielectric material that is disposed over a microelectronic device. Such PLs are typically patterned to form openings therein that provide for making electrical contact to the microelectronic device. Often a passivation layer is the last dielectric material disposed over a device and serves as a protective layer.

“Conformal coatings” as used herein, refers to a material applied to electronic circuitry to act as protection against moisture, dust, chemicals, and temperature extremes that, if uncoated, could result in damage or failure of the electronics to function properly. Typically, the electronic circuitry or assemblies thereof is coated with a layer of transparent conformal coating to protect the electronics from harsh environment. In some instances, the conformal coating is transparent such that the circuitry can be visually inspected. Suitably chosen conformal coatings can also reduce the effects of mechanical stress, vibration and extreme temperatures. For example, in a chip-on-board packaging process, a silicon die is mounted on the board with adhesive or a soldering, and then electrically connected by wire bonding. To protect the very delicate package, the whole chip-on-board is encapsulated in a conformal coating, commonly referred to as a “glob top”.

“Breakdown voltage”, as used herein, refers to the minimum voltage that causes a portion of an insulator to become electrically conductive. “High breakdown voltage” is at least about 100 V to at least about 900 V, such as 200V, 300V, 400V, 500V, 600V, 700V, 800V, 900V, 1,000V or higher.

“Electric power” is the rate, per unit time, at which electrical energy is transferred by an electric circuit. It is the rate of doing work. In electric circuits, power is measured in Watts (W) and is a function of both voltage and current:

P=IE

where P=power (in watts); I=current (in amperes) and E=voltage (in volts). Since Electric power generally generates heat “high power” is often used to refer to devices and applications that generate heat in excess of 100° C.

“High frequency” or “HF”, as used herein, refers to the range of radio frequency electromagnetic waves between 3 and 30 megahertz (MHz).

“Dielectric”, as used herein, refers to an insulating material that has the property of transmitting electric force without conduction. When a dielectric material is placed in an electric field, electric charges do not flow through the material as they do in an electrical conductor but only slightly shift from their average equilibrium positions causing dielectric polarization. Because of dielectric polarization, positive charges are displaced in the d rection of the field and negative charges shift in the direction opposite to the field. This creates an internal electric field that reduces the overall field within the dielectric itself.

As used herein the term “dielectric constant” and abbreviation “Dk” or “relative permittivity”, is the ratio of the permittivity (a measure of electrical resistance) of a substance to the permittivity of free space (which is given a value of 1). In simple terms, the lower the Dk of a material, the better it will act as an insulator. As used herein, “low dielectric constant” refers to materials with a Dk less than that of silicon dioxide, which has Dk of 3.9. Thus, “low dielectric constant refers” to a Dk of less than 3.9, typically, less than about 3.5, and most often less than about 3.0.

As used herein the term “dissipation dielectric factor”, “dissipation dielectric constant”, and abbreviation “Df” are used herein to refer to a measure of loss-rate of energy in a thermodynamically open, dissipative system. In simple terms, Df is a measure of how inefficient the insulating material of a capacitor is. It typically measures the heat that is lost when an insulator such as a dielectric is exposed to an alternating field of electricity. The lower the Df of a material, the better its efficiency. “Low dissipation dielectric factor” typically refers to a Df of less than about 0.01 at 1 GHz frequency, frequently less than about 0.005 at 1 GHz frequency, and most often 0.001 or lower at 1 GHz frequency.

“Interlayer Dielectric Layer” or “ILD” refer to a layer of dielectric material disposed over a first pattern of conductive traces, separating it from a second pattern of conductive traces, which can be stacked on top of the first. Often, ILD layers are patterned or drilled to provide openings (referred to as “vias”, short for “vertical interconnect access” channels) allowing electrical contact between the first and second patterns of conductive traces in specific regions or in layers of a multilayer printed circuit board. Other regions of such ILD layers are devoid of vias to strategically prevent electrical contact between the conductive traces of first and second patterns or layers.

In electronics, “leakage” is the gradual transfer of electrical energy across a boundary normally viewed as insulating, such as the spontaneous discharge of a charged capacitor, magnetic coupling of a transformer with other components, or flow of current across a transistor in the “off” state or a reverse-polarized diode. Another type of leakage can occur when current leaks out of the intended circuit, instead flowing through some alternate path. This sort of leakage is undesirable because the current flowing through the alternate path can cause damage, fires, RF noise, or electrocution.

“Leakage current” as used herein, refers to the gradual loss of energy from a charged capacitor, primarily caused by electronic devices attached to the capacitor, such as transistors or diodes, which conduct a small amount of current even when they are turned off. “Leakage current” also refers any current that flows when the ideal current is zero. Such is the case in electronic assemblies when they are in standby, disabled, or “sleep” mode (standby power). These devices can draw one or two microamperes while in their quiescent state compared to hundreds or thousands of milliamperes while in full operation. These leakage currents are becoming a significant factor to portable device manufacturers because of their undesirable effect on battery run time for the consumer.

“Thermoplastic”, as used herein, refers to the ability of a compound, composition or other material (e.g. a plastic) to dissolve in a suitable solvent or to melt to a liquid when heated and to freeze to a solid, often brittle and glassy, state when cooled sufficiently.

“Thermoset”, as used herein, refers to the ability of a compound, composition or other material, to irreversibly “cure”, resulting in a single three-dimensional network that has greater strength and less solubility compared to the un-cured material. Thermoset materials are typically polymers that may be cured, for example, through heat (e.g. above 200° C.), via a chemical reaction (e.g. epoxy ring-opening, free-radical polymerization) or through irradiation (with e.g., visible light, UV light, electron beam radiation, ion-beam radiation, or X-ray irradiation).

Thermoset materials, such as thermoset polymers are resins, are typically liquid or malleable forms prior to curing, and therefore may be molded or shaped into their final form, and/or used as adhesives. Curing transforms the thermoset resin into a rigid, infusible and insoluble solid or rubber by a cross-linking process. Energy and/or catalysts are typically added to the uncured thermoset that cause the thermoset molecules to react at chemically active sites (e.g., unsaturated or epoxy sites), thereby linking the thermoset molecules into a rigid, 3-dimensional structure. The cross-linking process forms molecules with higher molecular weight and resulting higher melting point. During the reaction, when the molecular weight of the polymer has increased to a point such that the melting point is higher than the surrounding ambient temperature, the polymer becomes a solid material.

The term “monomer” refers to a molecule that can undergo polymerization or copolymerization thereby contributing constitutional units to the essential structure of a macromolecule (i.e., a polymer).

The term “pre-polymer” refers to a monomer or combination of monomers that have been reacted to a molecular mass state intermediate between that of the monomer and higher molecular weight polymers. Pre-polymers are capable of further polymerization via reactive groups they contain, to a fully cured high molecular weight state. Mixtures of reactive polymers with un-reacted monomers may also be referred to a “resin”. The term “resin”, as used herein, refers to a substance containing pre-polymers, typically with reactive groups. In general, resins are pre-polymers of a single type or class, such as epoxy resins and bismaleimide resins.

“Polymer” and “polymer compound” are used interchangeably herein, to refer generally to the combined the products of a single chemical polymerization reaction. Polymers are produced by combining monomer subunits into a covalently bonded chain. Polymers that contain only a single type of monomer are known as “homopolymers,” while polymers containing a mixture of two or more different monomers are known as “copolymers”.

The term “copolymers” includes products that are obtained by copolymerization of two monomer species, those obtained from three monomers species (terpolymers), those obtained from four monomers species (quaterpolymers), and those obtained from five or more monomer species. It is well known in the art that copolymers synthesized by chemical methods include, but are not limited to, molecules with the following types of monomer arrangements:
alternating copolymers, which contain regularly alternating monomer residues;
periodic copolymers, which have monomer residue types arranged in a repeating sequence;
random copolymers, which have a random sequence of monomer residue types;
statistical copolymers, which have monomer residues arranged according to a known statistical rule;
block copolymers, which have two or more homopolymer subunits linked by covalent bonds. The blocks of homopolymer within block copolymers, for example, can be of any length and can be blocks of uniform or variable length. Block copolymers with two or three distinct blocks are called diblock copolymers and triblock copolymers, respectively; and
star copolymers, which have chains of monomer residues having different constitutional or configurational features that are linked through a central moiety.

The skilled artisan will appreciate that a single copolymer molecule may have different regions along its length that can be characterized as an alternating, periodic, random, etc. A copolymer product of a chemical polymerization reaction may contain individual polymeric molecules and fragments that each differ in the arrangement of monomer units. The skilled artisan will further be knowledgeable in methods for synthesizing each of these types of copolymers, and for varying reaction conditions to favor one type over another.

Furthermore, the length of a polymer chain according to the present invention will typically vary over a range or average size produced by a particular reaction. The skilled artisan will be aware, for example, of methods for controlling the average length of a polymer chain produced in a given reaction and also of methods for size-selecting polymers after they have been synthesized.

“Polydispersity index” (PDI) or “heterogeneity index”, is a measure of the distribution of molecular mass in a given polymer sample. PDI is calculated by the following formula:

PDI=M_{w}/Mₙ,

where M_{w} is the weight average molecular weight and Mₙ is the number average molecular weight.

Unless a more restrictive term is used, “polymer” is intended to encompass homopolymers, and copolymers having any arrangement of monomer subunits as well as copolymers containing individual molecules having more than one arrangement. With respect to length, unless otherwise indicated, any length limitations recited for the polymers described herein are to be considered averages of the lengths of the individual molecules in polymer.

“Thermoplastic elastomer” or “TPE”, as used herein refers to a class of copolymers that consist of materials with both thermoplastic and elastomeric properties.

“Hard blocks” or “hard segments” as used herein refer to a block of a copolymer (typically a thermoplastic elastomer) that is hard at room temperature by virtue of a high melting point (Tm) or T_{g}. By contrast, “soft blocks” or “soft segments” have a T_{g} below room temperature.

As used herein, “oligomer” or “oligomeric” refers to a polymer having a finite and moderate number of repeating monomers structural units. Oligomers of the invention typically have 2 to about 100 repeating monomer units; frequently 2 to about 30 repeating monomer units; and often 2 to about 10 repeating monomer units; and usually have a molecular weight up to about 3,000.

The skilled artisan will appreciate that oligomers and polymers may, depending on the availability of polymerizable groups or side chains, subsequently be incorporated as monomers in further polymerization or crosslinking reactions.

As used herein, “aliphatic” refers to any alkyl, alkenyl, cycloalkyl, or cycloalkenyl moiety.

“Aromatic hydrocarbon” or “aromatic” as used herein, refers to compounds having one or more benzene rings.

“Alkane,” as used herein, refers to saturated straight-chain, branched or cyclic hydrocarbons having only single bonds. Alkanes have general formula CₙH₂ₙ₊₂.

“Cycloalkane,” refers to an alkane having one or more rings in its structure.

As used herein, “alkyl” refers to straight or branched chain hydrocarbyl groups having from 1 to about 500 carbon atoms. “Lower alkyl” refers generally to alkyl groups having 1 to 6 carbon atoms. The terms “alkyl” and “substituted alkyl” include, respectively, substituted and unsubstituted C₁-C₅₀₀ straight chain saturated aliphatic hydrocarbon groups, substituted and unsubstituted C₂-C₂₀₀ straight chain unsaturated aliphatic hydrocarbon groups, substituted and unsubstituted C₄-C₁₀₀ branched saturated aliphatic hydrocarbon groups, substituted and unsubstituted C₁-C₅₀₀ branched unsaturated aliphatic hydrocarbon groups.

For example, the definition of “alkyl” includes but is not limited to: methyl (Me), ethyl (Et), propyl (Pr), butyl (Bu), pentyl, hexyl, heptyl, octyl, nonyl, decyl, undecyl, ethenyl, propenyl, butenyl, penentyl, hexenyl, heptenyl, octenyl, nonenyl, decenyl, undecenyl, isopropyl (i-Pr), isobutyl (i-Bu), tert-butyl (t-Bu), sec-butyl (s-Bu), isopentyl, neopentyl, cyclopropyl, cyclobutyl, cyclopentyl, cyclohexyl, cycloheptyl, cyclooctyl, cyclopentenyl, cyclohexenyl, cycloheptenyl, cyclooctenyl, methylcyclopropyl, ethylcyclohexenyl, butenylcyclopentyl, tricyclodecyl, adamantyl, and norbornyl.

“Substituted” refers to compounds and moieties bearing substituents that include but are not limited to alkyl (e.g. C₁₋₁₀ alkyl), alkenyl, alkynyl, hydroxy, oxo, alkoxy, mercapto, cycloalkyl, substituted cycloalkyl, heterocyclic, substituted heterocyclic, aryl, substituted aryl (e.g., aryl C₁₋₁₀ alkyl or aryl C₁₋₁₀ alkyloxy), heteroaryl, substituted heteroaryl (e.g., heteroarylC₁₋₁₀alkyl), aryloxy, C₁₋₁₀ alkyloxy C₁₋₁₀ alkyl, aryl C₁₋₁₀ alkyloxyC₁₋₁₀ alkyl, C₁₋₁₀ alkylthioC₁₋₁₀ alkyl, aryl C₁₋₁₀ alkylthio C₁₋₁₀ alkyl, C₁₋₁₀ alkylamino C₁₋₁₀ alkyl, aryl C₁₋₁₀ alkylamino C₁₋₁₀ alkyl, N-aryl-N—C₁₋₁₀ alkylamino C₁₋₁₀ alkyl, C₁₋₁₀ alkylcarbonyl C₁₋₁₀ alkyl, aryl C₁₋₁₀ alkylcarbonyl C₁₋₁₀ alkyl, C₁₋₁₀ alkylcarboxy C₁₋₁₀ alkyl, aryl C₁₋₁₀ alkylcarboxy C₁₋₁₀ alkyl, C₁₋₁₀ alkylcarbonylamino C₁₋₁₀ alkyl, and aryl C₁₋₁₀ alkylcarbonylamino C₁₋₁₀ alkyl, substituted aryloxy, halo, haloalkyl (e.g., trihalomethyl), cyano, nitro, nitrone, amino, amido, carbamoyl, ═O, ═CH—, —C(O)H, —C(O)O—, —C(O)—, —S—, —S(O)₂, —OC(O)—O—, —NR—C(O), —NR—C(O)—NR, —OC(O)—NR, where R is H or lower alkyl, acyl, oxyacyl, carboxyl, carbamate, sulfonyl, sulfonamide, sulfuryl, C₁₋₁₀ alkylthio, aryl C₁₋₁₀ alkylthio, C₁₋₁₀ alkylamino, aryl C₁₋₁₀ alkylamino, N-aryl-N—C₁₋₁₀ alkylamino, C₁₋₁₀ alkyl carbonyl, aryl C₁₋₁₀ alkylcarbonyl, C₁₋₁₀ alkylcarboxy, aryl C₁₋₁₀ alkylcarboxy, C₁₋₁₀ alkyl carbonylamino, aryl C₁₋₁₀ alkylcarbonylamino, tetrahydrofuryl, morpholinyl, piperazinyl, and hydroxypyronyl.

In addition, as used herein “C₃₆” and “C₃₆ moiety” refer to all possible structural isomers of a 36 carbon aliphatic moiety, including branched isomers and cyclic isomers with up to three carbon-carbon double bonds in the backbone. One non-limiting example of a C₃₆ moiety is the moiety comprising a cyclohexane-based core and four long “arms” attached to the core, as demonstrated by the following structure:

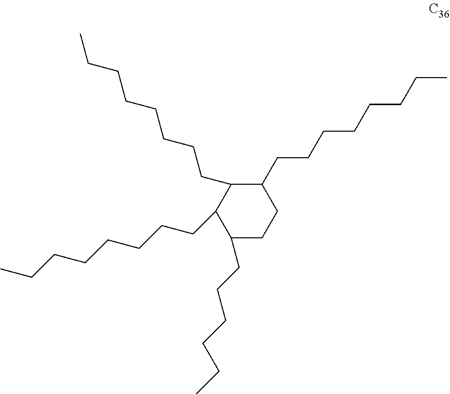 [SMILES: CCCCCCCCC1CCC(CCCCCC)C(CCCCCCCC)C1CCCCCCCC]

As used herein, “cycloalkyl” refers to cyclic ring-containing groups containing about 3 to about 20 carbon atoms, typically 3 to about 15 carbon atoms. In certain embodiments, cycloalkyl groups have about 4 to about 12 carbon atoms, and in yet further embodiments, cycloalkyl groups have about 5 to about 8 carbon atoms. “Substituted cycloalkyl” refers to cycloalkyl groups further bearing one or more substituents as set forth below.

As used herein, the term “aryl” refers to an unsubstituted, mono-, di- or trisubstituted monocyclic, polycyclic, biaryl aromatic groups covalently attached at any ring position capable of forming a stable covalent bond, certain preferred points of attachment being apparent to those skilled in the art (e.g., 3-phenyl, 4-naphtyl and the like). “Substituted aryl” refers to aryl groups further bearing one or more substituents as set forth above.

Specific examples of moieties encompassed by the definition of “aryl” include but are not limited to, phenyl, biphenyl, naphthyl, dihydronaphthyl, tetrahydronaphthyl, indenyl, indanyl, azulenyl, anthryl, phenanthryl, fluorenyl, and pyrenyl and the like.

As used herein, “arylene” refers to a divalent aryl moiety. “Substituted arylene” refers to arylene moieties bearing one or more substituents as set forth above.

As used herein, “alkylaryl” refers to alkyl-substituted aryl groups and “substituted alkylaryl” refers to alkylaryl groups further bearing one or more substituents as set forth above.

As used herein, “arylalkyl” refers to aryl-substituted alkyl groups and “substituted arylalkyl” refers to arylalkyl groups further bearing one or more substituents as set forth below. Some examples of included but are not limited to (4-hydroxyphenyl)ethyl, or (2-aminonaphthyl) hexenyl.

As used herein, “arylalkenyl” refers to aryl-substituted alkenyl groups and “substituted arylalkenyl” refers to arylalkenyl groups further bearing one or more substituents as set forth above.

As used herein, “arylalkynyl” refers to aryl-substituted alkynyl groups and “substituted arylalkynyl” refers to arylalkynyl groups further bearing one or more substituents as set forth above.

As used herein, “aroyl” refers to aryl-carbonyl species such as benzoyl and “substituted aroyl” refers to aroyl groups further bearing one or more substituents as set forth above.

As used herein, “hetero” refers to groups or moieties containing one or more non-carbon heteroatoms, such as N, O, Si and S. Thus, for example “heterocyclic” refers to cyclic (i.e., ring-containing) groups having e.g. N, O, Si or S as part of the ring structure, and having 3 to 14 carbon atoms. “Heteroaryl” and “heteroalkyl” moieties are aryl and alkyl groups, respectively, containing e.g. N, O, Si or S as part of their structure. The terms “heteroaryl”, “heterocycle” or “heterocyclic” refer to a monovalent unsaturated group having a single ring or multiple condensed rings, from 1 to 8 carbon atoms and from 1 to 4 hetero atoms selected from nitrogen, sulfur or oxygen within the ring.

The definition of heteroaryl includes but is not limited to thienyl, benzothienyl, isobenzothienyl, 2,3-dihydrobenzothienyl, furyl, pyranyl, benzofuranyl, isobenzofuranyl, 2,3-dihydrobenzofuranyl, pyrrolyl, pyrrolyl-2,5-dione, 3-pyrrolinyl, indolyl, isoindolyl, 3H-indolyl, indolinyl, indolizinyl, indazolyl, phthalimidyl (or isoindoly-1,3-dione), imidazolyl. 2H-imidazolinyl, benzimidazolyl, pyridyl, pyrazinyl, pyradazinyl, pyrimidinyl, triazinyl, quinolyl, isoquinolyl, 4H-quinolizinyl, cinnolinyl, phthalazinyl, quinazolinyl, quinoxalinyl, 1,8-naphthyridinyl, pteridinyl, carbazolyl, acridinyl, phenazinyl, phenothiazinyl, phenoxazinyl, chromanyl, benzodioxolyl, piperonyl, purinyl, pyrazolyl, triazolyl, tetrazolyl, thiazolyl, isothiazolyl, benzthiazolyl, oxazolyl, isoxazolyl, benzoxazolyl, oxadiazolyl, thiadiazolyl, pyrrolidinyl-2,5-dione, imidazolidinyl-2,4-dione, 2-thioxo-imidazolidinyl-4-one, imidazolidinyl-2,4-dithione, thiazolidinyl-2,4-dione, 4-thioxo-thiazolidinyl-2-one, piperazinyl-2,5-dione, tetrahydro-pyridazinyl-3,6-dione, 1,2-dihydro-[1,2,4,5]tetrazinyl-3,6-dione, [1,2,4,5]tetrazinanyl-3,6-dione, dihydro-pyrimidinyl-2,4-dione, pyrimidinyl-2,4,6-trione, 1H-pyrimidinyl-2,4-dione, 5-iodo-1H-pyrimidinyl-2,4-dione, 5-chloro-1H-pyrimidinyl-2,4-dione, 5-methyl-1H-pyrimidinyl-2,4-dione, 5-isopropyl-1H-pyrimidinyl-2,4-dione, 5-propynyl-1H-pyrimidinyl-2,4-dione, 5-trifluoromethyl-1H-pyrimidinyl-2,4-dione, 6-amino-9H-purinyl, 2-amino-9H-purinyl, 4-amino-1H-pyrimidinyl-2-one, 4-amino-5-fluoro-1H-pyrimidinyl-2-one, 4-amino-5-methyl-1H-pyrimidinyl-2-one, 2-amino-1,9-dihydro-purinyl-6-one, 1,9-dihydro-purinyl-6-one, 1H-[1,2,4]triazolyl-3-carboxylic acid amide, 2,6-diamino-N.sub.6-cyclopropyl-9H-purinyl, 2-amino-6-(4-methoxyphenylsulfanyl)-9H-purinyl, 5,6-dichloro-1H-benzoimidazolyl, 2-isopropylamino-5,6-dichloro-1H-benzoimidazolyl, 2-bromo-5,6-dichloro-1H-benzoimidazolyl, and the like. Furthermore, the term “saturated heterocyclic” represents an unsubstituted, mono-, di- or trisubstituted monocyclic, polycyclic saturated heterocyclic group covalently attached at any ring position capable of forming a stable covalent bond, certain preferred points of attachment being apparent to those skilled in the art (e.g., 1-piperidinyl, 4-piperazinyl and the like).

Hetero-containing groups may also be substituted. For example, “substituted heterocyclic” refers to a ring-containing group having 3 to 14 carbon atoms that contains one or more heteroatoms and also bears one or more substituents, as set forth above.

As used herein, the term “phenol” includes compounds having one or more phenolic functions per molecule, as illustrated below:

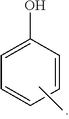

The terms aliphatic, cycloaliphatic and aromatic, when used to describe phenols, refers to phenols to which aliphatic, cycloaliphatic and aromatic residues or combinations of these backbones are attached by direct bonding or ring fusion.

As used herein, “alkenyl,” “alkene” or “olefin” refers to straight or branched chain unsaturated hydrocarbyl groups having at least one carbon-carbon double bond and having about 2 to 500 carbon atoms. In certain embodiments, alkenyl groups have about 5 to about 250 carbon atoms, 5 to about 100 carbon atoms, 5 to about 50 carbon atoms or 5 to about 25 carbon atoms. In other embodiments, alkenyl groups have about 6 to about 500 carbon atoms, 8 to about 500 carbon atoms, 10 to about 500 carbon atoms or 20 to about 500 carbon atoms or 50 to about 500 carbon atoms. In yet further embodiments, alkenyl groups have about 6 to about 100 carbon atoms, 10 to about 100 carbon atoms, 20 to about 100 carbon atoms or 50 to about 100 carbon atoms, while in other embodiments, alkenyl groups have about 6 to about 50 carbon atoms, 6 to about 25 carbon atoms, 10 to about 50 carbon atoms, or 10 to about 25 carbon atoms. “Substituted alkenyl” refers to alkenyl groups further bearing one or more substituents as set forth above.

As used herein, “alkylene” refers to a divalent alkyl moiety, and “oxyalkylene” refers to an alkylene moiety containing at least one oxygen atom instead of a methylene (CH₂) unit. “Substituted alkylene” and “substituted oxyalkylene” refer to alkylene and oxyalkylene groups further bearing one or more substituents as set forth above.

As used herein, “alkynyl” refers to straight or branched chain hydrocarbyl groups having at least one carbon-carbon triple bond and having 2 to about 100 carbon atoms, typically about 4 to about 50 carbon atoms, and frequently about 8 to about 25 carbon atoms. “Substituted alkynyl” refers to alkynyl groups further bearing one or more substituents as set forth below.

As used herein, “oxiranylene or “epoxy” refer to divalent moieties having the structure:

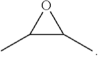

The term “epoxy” also refers to thermosetting epoxide polymers that cure by polymerization and crosslinking when mixed with a catalyzing agent or “hardener,” also referred to as a “curing agent” or “curative.” Epoxies of the present invention include, but are not limited to aliphatic, cycloaliphatic, glycidyl ether, glycidyl ester, glycidyl amine epoxies, and the like, and combinations thereof.

As used herein, “acyl” refers to alkyl-carbonyl species.

As used herein, the term “oxetane” refers to a compound bearing at least one moiety having the structure:

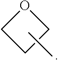

“Allyl” as used herein, refers to refers to a compound bearing at least one moiety having the structure:

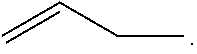

As used herein, “vinyl ether” refers to a compound bearing at least one moiety having the structure:

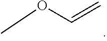

As used herein, the term “vinyl ester” refers to a compound bearing at least one moiety having the structure:

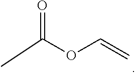

As used herein, “styrenic” refers to a compound bearing at least one moiety having the structure:

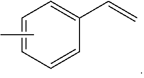

“Fumarate” as used herein, refers to a compound bearing at least one moiety having the structure:

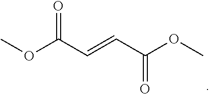

“Propargyl” as used herein, refers to a compound bearing at least one moiety having the structure:

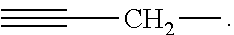

“Cyanate ester” as used herein, refers to a compound bearing at least one moiety having the structure:

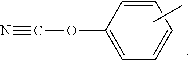

As used herein, “norbornyl” refers to a compound bearing at least one moiety having the structure:

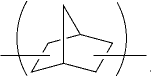

“Imide” as used herein, refers to a functional group having two carbonyl groups bound to a primary amine or ammonia. The general formula of an imide of the invention is:

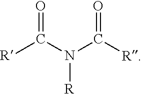

“Polyimides” are polymers of imide-containing monomers. Polyimides are typically linear or cyclic. Non-limiting examples of linear and cyclic (e.g. an aromatic heterocyclic polyimide) polyimides are shown below for illustrative purposes.

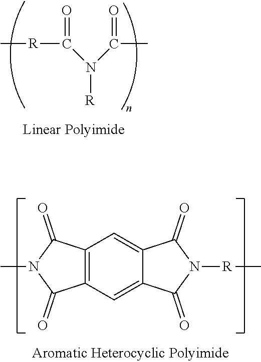

where R is an aromatic, heteroaromatic, aliphatic, or polymeric moiety.

“Maleimide,” as used herein, refers to an N-substituted maleimide having the formula as shown below:

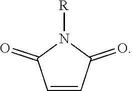

where R is an aromatic, heteroaromatic, aliphatic, or polymeric moiety.

“Bismaleimide” or “BMI”, as used herein, refers to compound in which two imide moieties are linked by a bridge, i.e. a compound a polyimide having the general structure shown below:

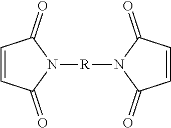

where R is an aromatic, heteroaromatic, aliphatic, or polymeric moiety.

BMIs can cure through an addition rather than a condensation reaction, thus avoiding problems resulting from the formation of volatiles. BMIs can be cured by a vinyl-type polymerization of a pre-polymer terminated with two maleimide groups.

As used herein, the term “acrylate” refers to a compound bearing at least one moiety having the structure:

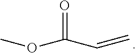

As used herein, the term “acrylamide” refers to a compound bearing at least one moiety having the structure:

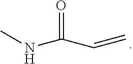

As used herein, the term “methacrylate” refers to a compound bearing at least one moiety having the structure:

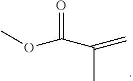

As used herein, the term “methacrylamide” refers to a compound bearing at least one moiety having the structure:

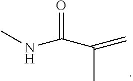

As used herein, “maleate” refers to a compound bearing at least one moiety having the structure:

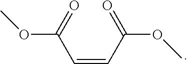

As used herein, the terms “citraconimide” and “citraconate” refer to a compound bearing at least one moiety having the structure:

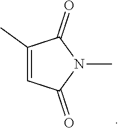

“Itaconimide” and “itaconate”, as used herein, refer to a compound bearing at least one moiety having the structure:

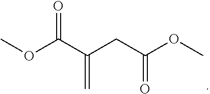

As used herein, “benzoxazine” refers to moieties including the following bicyclic structure:

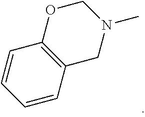

As used herein, the term “acyloxy benzoate” or “phenyl ester” refers to a compound bearing at least one moiety having the structure:

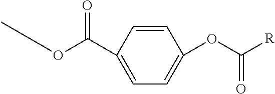

where R is H, lower alkyl, or aryl.

As used herein, the terms “halogen,” “halide,” or “halo” include fluorine, chlorine, bromine, and iodine.

As used herein, “siloxane” refers to any compound containing a Si—O moiety. Siloxanes may be either linear or cyclic. In certain embodiments, siloxanes of the invention include 2 or more repeating units of Si—O. Exemplary cyclic siloxanes include hexamethylcyclotrisiloxane, octamethylcyclotetrasiloxane, decamethylcyclopentasiloxane, dodecamethylcyclohexasiloxane and the like.

As used herein, a “primary amine terminated difunctional siloxane bridging group” refers to a moiety having the structural formula:

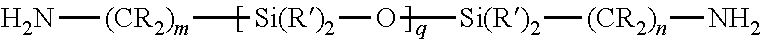

where each R is H or Me, each R′ is independently H, lower alkyl, or aryl; each of m and n is an integer having the value between 1 to about 10, and q is an integer having the value between 1 and 100.

As used herein, the term “free radical initiator” refers to any chemical species which, upon exposure to enough energy (e.g., light, heat, or the like), decomposes into parts, which are uncharged, but every one of such part possesses at least one unpaired electron.

“Photoinitiation” as used herein, refers to polymerization initiated by light. In most cases, photoinduced polymerization, utilizes initiators to generate radicals, which can be one of two types: “Type I Photoinitiators” (unimolecular photoinitiators), which undergo homolytic bond cleavage upon absorption of light; and “Type II Photoinitiators” (bimolecular photoinitiators), consisting of a photoinitiator such as benzophenone or thioxanthone and a coinitiator such as alcohol or amine.

As used herein, the term “coupling agent” refers to chemical species that are capable of bonding to a mineral surface and which also contain polymerizably reactive functional group(s) to enable interaction with the adhesive composition. Coupling agents thus facilitate linkage of the die-attach paste to the substrate to which it is applied.

“Diamine,” as used herein, refers generally to a compound or mixture of compounds, where each species has 2 amine groups.

“Anhydride” as used herein, refers to a compound bearing at least one moiety having the structure:

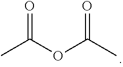

“Dianhydride,” as used herein, refers generally to a compound or mixture of compounds, where each species has 2 anhydride (—NH₂) groups.

The term “solvent,” as used herein, refers to a liquid that dissolves a solid, liquid, or gaseous solute, resulting in a solution. “Co-solvent” refers to a second, third, etc. solvent used with a primary solvent.

As used herein, “polar protic solvents” are ones that contain an O—H or N—H bond, while “polar aprotic solvents” do not contain an O—H or N—H bond.

“Glass transition temperature” or “T_{g}”, is used herein to refer to the temperature at which an amorphous solid, such as a polymer, becomes brittle on cooling, or soft on heating. More specifically, it defines a pseudo second order phase transition in which a supercooled melt yields, on cooling, a glassy structure and properties similar to those of crystalline materials e.g. of an isotropic solid material.

“Low glass transition temperature” or “Low T_{g}” as used herein, refers to a T_{g} at or below about 50° C. “High glass transition temperature” or “High T_{g}” as used herein, refers to a T_{g} of at least about 60° C., at least about 70° C., at least about 80° C., at least about 100° C. “Very high glass transition temperature” and “very high T_{g}” as used herein, refers to a T_{g} of at least about 150° C., at least about 175° C., at least about 200° C., at least about 220° C. or higher. High glass transition temperature compounds and compositions of the invention typically have a T_{g} in the range of about 70° C. to about 300° C.

“Modulus” or “Young's modulus” as used herein, is a measure of the stiffness of a material. Within the limits of elasticity, modulus is the ratio of the linear stress to the linear strain, which can be determined from the slope of a stress-strain curve created during tensile testing.

The “Coefficient of Thermal Expansion” or “CTE” is a term of art describing a thermodynamic property of a substance. The CTE relates a change in temperature to the change in a material's linear dimensions. As used herein “α₁ CTE” or “α₁” refers to the CTE before the T_{g}, while “α₂ CTE” refers to the CTE after the T_{g}.

“Low Coefficient of Thermal Expansion” or “Low CTE” as used herein, refers to an CTE of less than about 50 ppm/° C., typically less than about 30 ppm/° C. or less than about 10 ppm/° C.

“Thermogravimetric analysis” or “TGA” refers to a method of testing and analyzing a material to determine changes in weight of a sample that is being heated in relation to change in temperature.

“Decomposition onset” or “Td” refers to a temperature when the loss of weight in response to the increase of the temperature indicates that the sample is beginning to degrade. “Td (5%)” is the temperature at which 5% of sample has degraded. When measured in an air environment “air” is typically noted in the Td (5%) abbreviation such as “Td (5%), air”.

The present invention provides polyimides with high molecular weight (i.e. >20,000 Daltons) with curable, phenol-functionalizations. Several factors influence the molecular weight of a synthetic polymer, such as the phenol-functionalized polyimides of the invention. The ratio of diamine to dianhydride, the solvent, temperature, and the nature of the diamines and dianhydrides (solubility issues, bulkiness or steric hindrance). Typically, high molecular weight polyimides are prepared by adding one equivalent of a dianhydride to one equivalent of a diamine in a polar aprotic solvent such as NMP, DMSO, DMAC, or DMF. The solution is often allowed to stir for 20 or more hours at subzero temperatures to gradually form a very high molecular weight polyamic acid solution. The polyamic acid solution is then cast into a very thin film and dried to remove most of the solvent, which is then followed by very high temperatures (typically 200-300° C.) for several hours to undergo the condensation reaction and form the polyimide.

The polyimides of the present invention are synthesized using a 1:1 ratio of diamine to dianhydride to maximize molecular weight according to the following general Scheme 1, (which depicts an optional end-terminal functionalization with a maleimide group):

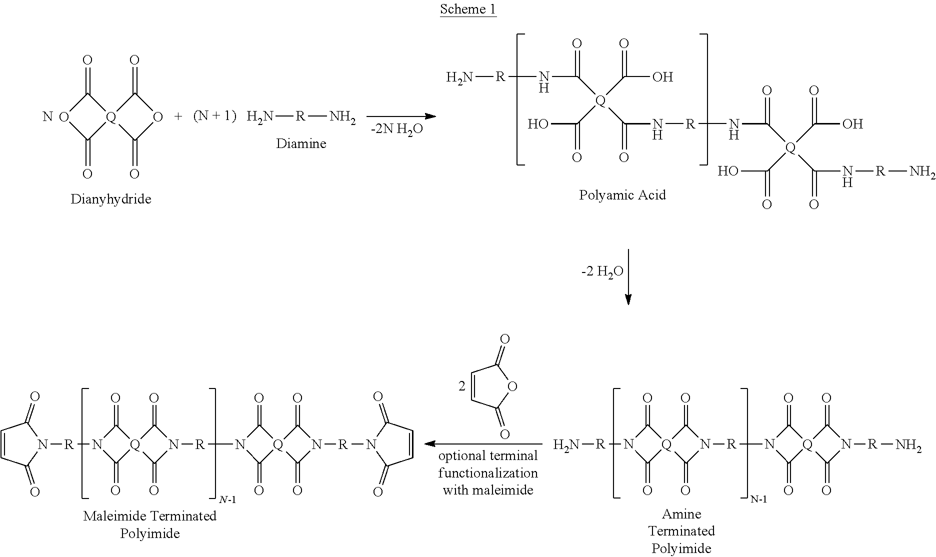

The synthetic reactions are typically performed in anisole and the water azeotropically removed at a temperature of ˜155° C. to ensure the complete imidization. The average molecular weight of the invention polymers is in excess of 100,000 Daltons. Due to this, very high molecular the materials are not isolated, but instead kept in anisole and used “as is” or combined with other co-monomers in compositions to make thin films.

The invention compositions once cast into a film, and cured are very flexible and can be bent 180° and are easily creased.

Another embodiment of the invention is based on the discovery of alternatives to polar aprotic solvents have been found that work well during the synthesis of phenolic-functionalized polyimides. These solvents include aromatic solvents, especially ether functionalized aromatic solvents such as anisole. Polyimides and the polyamic acid intermediate are soluble in anisole. Anisole is relatively unreactive and non-toxic, and produces polyimides with minimum color, whereas the polar aprotic solvents such as NMP, DMF, DMAC and DMSO frequently impart color to polyimides, which may be very dark.

Various diamines with phenolic functionality are commercially available; these compounds along with other diamines can be used in combination with various dianhydrides to produce polyimides with pendent phenolic moieties. The following are non-limiting examples of diamines useful in the practice of the invention:

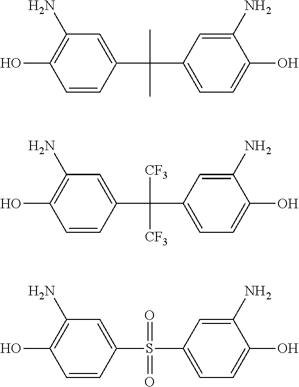 [SMILES: CC(C)(c1ccc(O)c(N)c1)c1ccc(O)c(N)c1 ; Nc1cc(C(c2ccc(O)c(N)c2)(C(F)(F)F)C(F)(F)F)ccc1O ; Nc1cc(S(=O)(=O)c2ccc(O)c(N)c2)ccc1O]

In yet another embodiment of the invention the polyimide is prepared by contacting a diamine with a dianhydride in a solvent such as anisole or other heteroaromatic solvent, followed by thermal dehydration to form the polyimide. The polyimide concentration in anisole can be adjusted and the epoxy resin, anionic initiator and coupling agents added to the solution. The solution can then be cast into a film by a drying process to form a B-staged film. The B-staged film can be laminated between copper foils using heat and pressure to form a copper-clad laminate.

Often adhesion promoters and coupling agents are necessary to obtain the ultimate adhesion especially to copper surface. The coupling agents that are the most useful contain nitrogen groups, and or anhydride groups. Certain polybutadiene oligomers containing anhydride groups are particularly desired in the formulations. Compounds containing amine functionality also have been found to offer greater adhesion to the copper surface.

Silane coupling agents are often used to improve the adhesion of the polymeric material to the copper surface. Amino-functionalized coupling agents are particularly advantageous in that they help to block the migration of copper oxide layer into the resin matrix and therefore prevent delamination.

Some of the lower molecular weight polymers that can prepared in high solids content are also contemplated for use in making prepregs. The invention compounds in solvent along with epoxy resins, benzoxazine resins, cyanate ester resins, oxetane resins as well as others can be impregnated into a fabric and dried or B-staged. Several layers can then be laminated at high temperature and pressure to form very low Dk and Df boards that can be useful in making printed wiring boards.

The invention compounds are also contemplated for use in milliwave radar applications. For use as capacitors, for use in making lithium ion batteries, for use as copper-clad laminates, for use as radar antenna applications, for use in automotive applications, for use in aerospace applications.

The formulations using the invention compounds can also contain fillers to enhance the properties. For example, the addition of silica and poly tetrafluoroethylene (Teflon™) has been shown to reduce the Df of the laminates tremendously. The addition of alumina can also reduce the Df, but also raise the Dk of the materials; this is very applicable for use as capacitors. Other non-conductive fillers such as boron nitride, carbon black, or carbon nanotubes are also contemplated for use.

Conductive fillers such as gold, copper, silver; platinum, palladium and alloys thereof are also contemplated for use in the practice of the invention.

Generic representations of phenol-functionalized polyimides of the invention are shown by Formula I, Formula II and Formula III:

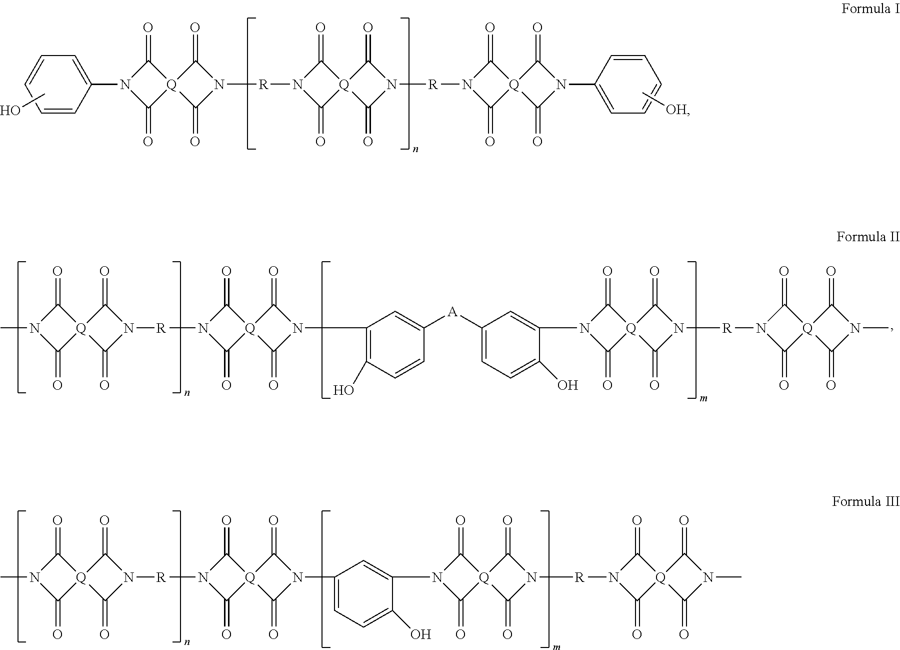

where R, Q and A are each independently a substituted or unsubstituted aromatic, aliphatic, cycloaliphatic, alkenyl, polyether, polyester, polyamide, heteroaromatic, or siloxane moiety; and n is 0 or an integer having the value from 1-100; with the proviso that the average molecular weight of the polyimide is greater than 20,000 Daltons. In certain aspects, n is ˜20-100.

The invention is based in part on the discovery that certain functionalized polyimide compounds can be cast into thin, flexible films that are suitable for preparing flexible copper-clad laminates, when they are synthesized to have a high molecular weight that is greater than 20,000 Daltons. Polyimides with average molecular weights less than 20,000 Daltons produce films that are very brittle and are not suitable for applications where flexibility is needed, such as thin, rollable films.

The invention polyimides are curable; thereby obviating the use of adhesive layers for the preparation of FCCL. The curable invention polyimide material can be cast from solution to form thin films that are flexible and rollable. The films can be cut to size and placed between copper foils. Once heated during a lamination process, the material cures and adheres to the copper foil acting as a dielectric layer for FCCL

Flexibility and rollability are determined by the polyimide composition (substantially aromatic) and molecular weight (MW). It has been discovered that an average molecular weight of 20,000 Daltons yields a flexible polyimide, as disclosed below in the EXAMPLES, while lower MW leads to brittle polyimides that crack and cannot be formed into malleable films. When mostly aromatic polyimides are synthesized with an average MW of less than 20,000 Daltons, films cast from the polymer are very brittle and neither flexible nor rollable. When the average molecular weight of an aromatic polyimide of the invention is greater than 20,000 Daltons, films cast and dried from a solution of the polyimide in solvent are a flexible and rollable.

In one embodiment, the polyimides of the invention have an average molecular weight at least about 20,000 Daltons, such as at least about 25,000 Daltons at least about 30,000 Daltons, at least about 35,000 Daltons, at least about 40,000 Daltons, at least about 45,000 Daltons or at least about 50,000 Daltons. In other embodiments, the polyimides of the invention have an average molecular weight of about 20,000 to about 50,000 Daltons, about 25,000 to about 50,000 Daltons, about 30,000 to about 50,000 Daltons, about 35,000 to about 50,000 Daltons about 40,000 to about 50,000 Daltons, or about 45,000 to about 50,000 Daltons. An average molecular weight above 25,000 Daltons allows for terminal functionalization that facilitates curing to produce a thermoset.

In one embodiment, the compounds of the invention are prepared by adding one or more diamine to a reactor with anisole, followed by the addition of one or more dianhydride. Stirring at room temperature as well as having nearly equivalent amount of diamine and dianhydride produces the highest molecular weights. Often the polyamic acid intermediate is not highly soluble in the solvent, however, as the material is slowly heated the reagents dissolve and production of water is observed as a byproduct of a cyclodehydration reaction. After one to two hours of reflux all of the water is removed from the reaction and the fully imidized polymer is formed. If a slight excess of dianhydride is used, then another reaction with a compound such as an aminophenol derivative followed by another dehydration step produces phenol-terminated polyimide a structure according to Formula I.

Polyimides with other terminal reactive moieties can also be prepared. U.S. Pat. Nos. 7,884,174 B2, 7,157,587 B2, and 8,513,375 B2, which are incorporated by reference herein in their entirety, describe various terminal functionalizations that can be applied to compounds of the invention.

Alternatively, various diamines with phenolic functionality that are commercially available can be used to produce the phenolic-functionality. These compounds, alone or in combination with other diamines, can be used in combination with various dianhydrides to produce polyimides with phenolic moieties. The following structures are non-limiting examples of diamines useful in the practice of the invention.

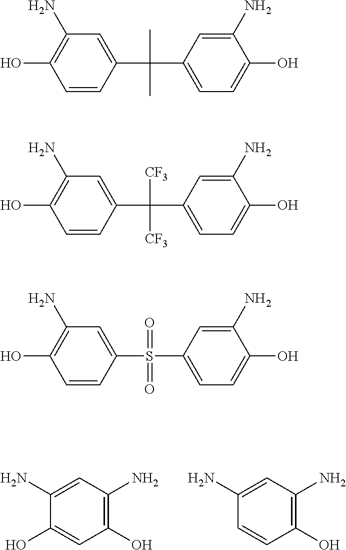 [SMILES: CC(C)(c1ccc(O)c(N)c1)c1ccc(O)c(N)c1 ; Nc1cc(C(c2ccc(O)c(N)c2)(C(F)(F)F)C(F)(F)F)ccc1O ; Nc1cc(S(=O)(=O)c2ccc(O)c(N)c2)ccc1O ; Nc1cc(N)c(O)cc1O ; Nc1ccc(O)c(N)c1]

A wide variety of diamines are contemplated for use in the practice of the invention, such as for example, 1,10-diaminodecane; 1,12-diaminododecane; dimer diamine; hydrogenated dimer diamine; 1,2-diamino-2-methylpropane; 1,2-diaminocyclohexane; 1,2-diaminopropane; 1,3-diaminopropane; 1,4-diaminobutane; 1,5-diaminopentane; 1,7-diaminoheptane; 1,8-diaminomenthane; 1,8-diaminooctane; 1,9-diaminononane; 3,3′-diamino-N-methyldipropylamine; diaminomaleonitrile; 1,3-diaminopentane; 9,10-diaminophenanthrene; 4,4′-diaminooctafluorobiphenyl; 3,5-diaminobenzoic acid; 3,7-diamino-2-methoxyfluorene; 4,4′-diaminobenzophenone; 3,4-diaminobenzophenone; 3,4-diaminotoluene; 2,6-diaminoanthroquinone; 2,6-diaminotoluene; 2,3-diaminotoluene; 1,8-diaminonaphthalene; 2,4-diaminotoluene; 2,5-diaminotoluene; 1,4-diaminoanthroquinone; 1,5-diaminoanthroquinone; 1,5-diaminonaphthalene; 1,2-diaminoanthroquinone; 2,4-cumenediamine; 1,3-bisaminomethylbenzene; 1,3-bisaminomethylcyclohexane; 2-chloro-1,4-diaminobenzene; 1,4-diamino-2,5-dichlorobenzene; 1,4-diamino-2,5-dimethylbenzene; 4,4′-diamino-2,2′-bistrifluoromethylbiphenyl; bis(amino-3-chlorophenyl)ethane; bis(4-amino-3,5-dimethylphenyl)methane; bis(4-amino-3,5-diisopropylphenyl)methane; bis(4-amino-3,5-methyl-isopropylphenyl)methane; bis(4-amino-3,5-diethylphenyl)methane; bis(4-amino-3-ethylphenyl)methane; diaminofluorene; 4,4′-(9-Fluorenylidene)dianiline; diaminobenzoic acid; 2,3-diaminonaphthalene; 2,3-diaminophenol; -5-methylphenyl)methane; bis(4-amino-3-methylphenyl)methane; bis(4-amino-3-ethylphenyl)methane; 4,4′-diaminophenylsulfone; 3,3′-diaminophenylsulfone; 2,2-bis(4-(4-aminophenoxy)phenyl)sulfone; 2,2-bis(4-(3-aminophenoxy)phenyl)sulfone; 4,4′-oxydianiline; 4,4′-diaminodiphenyl sulfide; 3,4′-oxydianiline; 2,2-bis(4-(4-aminophenoxy)phenyl)propane; 1,3-bis(4-aminophenoxy)benzene; 4,4′-bis(4-aminophenoxy)biphenyl; 4,4′-diamino-3,3′-dihydroxybiphenyl; 4,4′-diamino-3,3′-dimethylbiphenyl; 4,4′-diamino-3,3′-dimethoxybiphenyl; Bisaniline M; Bisaniline P; 9,9-bis(4-aminophenyl)fluorene; o-tolidine sulfone; methylene bis(anthranilic acid); 1,3-bis(4-aminophenoxy)-2,2-dimethylpropane; 1,3-bis(4-aminophenoxy)propane; 1,4-bis(4-aminophenoxy)butane; 1,5-bis(4-aminophenoxy)butane; 2,3,5,6-tetramethyl-1,4-phenylenediamine; 3,3′,5,5′-tetramehylbenzidine; 4,4′-diaminobenzanilide; 2,2-bis(4-aminophenyl)hexafluoropropane; polyoxyalkylenediamines; 1,3-cyclohexanebis(methylamine); m-xylylenediamine; p-xylylenediamine; bis(4-amino-3-methylcyclohexyl)methane; 1,2-bis(2-aminoethoxy)ethane; 3(4),8(9)-bis(aminomethyl)tricyclo(5.2.1.0^{2,6})decane; and any other diamines or polyamines.

A wide variety of anhydrides are contemplated for use in the practice of the invention, such as, for example, polybutadiene-graft-maleic anhydride; polyethylene-graft-maleic anhydride; polyethylene-alt-maleic anhydride; polymaleic anhydride-alt-1-octadecene; polypropylene-graft-maleic anhydride; poly(styrene-co-maleic anhydride); pyromellitic dianhydride; maleic anhydride, succinic anhydride; 1,2,3,4-cyclobutanetetracarboxylic dianhydride; 1,4,5,8-naphthalenetetracarboxylic dianhydride; 3,4,9,10-perylenentetracarboxylic dianhydride; bicyclo(2.2.2)oct-7-ene-2,3,5,6-tetracarboxylic dianhydride; diethylenetriaminepentaacetic dianhydride; ethylenediaminetetraacetic dianhydride; 3,3′,4,4′-benzophenone tetracarboxylic dianhydride; 3,3′,4,4′-biphenyl tetracarboxylic dianhydride; 4,4′-oxydiphthalic anhydride; 3,3′,4,4′-diphenylsulfone tetracarboxylic dianhydride; 2,2′-bis(3,4-dicarboxyphenyl)hexafluoropropane dianhydride; 4,4′-bisphenol A diphthalic anhydride; 5-(2,5-dioxytetrahydro)-3-methyl-3-cyclohexene-1,2-dicarboxylic anhydride; ethylene glycol bis(trimellitic anhydride); hydroquinone diphthalic anhydride; allyl nadic anhydride; 2-octen-1-ylsuccinic anhydride; phthalic anhydride; 1,2,3,6-tetrahydrophthalic anhydride; 3,4,5,6-tetrahydrophthalic anhydride; 1,8-naphthalic anhydride; glutaric anhydride; dodecenylsuccinic anhydride; hexadecenylsuccinic anhydride; hexahydrophthalic anhydride; methylhexahydrophthalic anhydride; tetradecenylsuccinic anhydride; and the like. In the use of the mono-anhydrides the chain would be terminated.

The invention specifically contemplates toward the inclusion of epoxy resins, anionic initiators and coupling agents in a formulation that can be cured to form a very good dielectric layer and adhesive for laminating copper foil.

In another embodiment of the invention, alternative solvents have been found that work well in producing the functionalized polyimides. These solvents include aromatic solvents especially ether functionalized aromatic solvents such as anisole. Anisole does a nice job of dissolving the polyimides as well as being able to handle the polyamic acid intermediate. Anisole is relatively unreactive and non-toxic, also it seems to produce polyimides with minimum color, whereas the polar aprotic solvents seem to produce polyimides that are very dark. Although the use of NMP, DMF, DMAC and DMSO is also contemplated in the practice of the invention.

The epoxy component can be selected from the group consisting of a phenyl glycidyl ether; a cresyl glycidyl ether; a nonylphenyl glycidyl ether; a p-tert-butylphenyl glycidyl ether; a diglycidyl or polyglycidyl ether of any of: bisphenol A, of bisphenol F, ethylidenebisphenol, dihydroxydiphenyl ether, bis(4-hydroxyphenyl)sulfone, bis(hydroxyphenyl)sulfide, 1,1-bis(hydroxyphenyl)cyclohexane, 9,19-bis(4-hydroxyphenyl)fluorene, 1,1,1-tris(hydroxyphenyl)ethane, tetrakis(4-hydroxyphenyl)ethane, trihydroxytritylmethane, 4,4′-(1-alpha-methylbenzylidene)bisphenol, 4,4′-dihydroxybenzophenone, dihydroxy naphthalene, 2,2′-dihydroxy-6,6′-dinaphthyl disulfide, a 1,8,9-trihydroxyanthracene, resorcinol, catechol and tetrahydroxydiphenyl sulfide; triglycidyl-p-aminophenol; N,N,N′,N′-tetraglycidyl-4,4′-diphenylmethane; triglycidyl isocyanurate; a glycidyl ether of a cresol formaldehyde condensate; a glycidyl ether of a phenol formaldehyde condensate; a glycidyl ether of a cresol dicyclopentadiene addition compound; a glycidyl ether of a phenol dicyclopentadiene addition compound; a diglycidyl ether of 1,4 butanediol; a diglycidyl ether of diethylene glycol; a diglycidyl ether of neopentyl glycol; a diglycidyl ether of cyclohexane dimethanol; a diglycidyl ether of tricyclodecane dimethanol; a trimethyolethane triglycidyl ether; mono- or di-glycidyl ether of naphthalene derivative; perfluorinated alkyl glycidyl ethers; a trimethyol propane triglycidyl ether; a glycidyl ether of a polyglycol; a polyglycidyl ether of castor oil; a polyoxypropylene diglycidyl ether and a glycidyl derivative of an aromatic amine.

The following epoxy resins contemplated for use as co-curing resins in the practice of the invention.

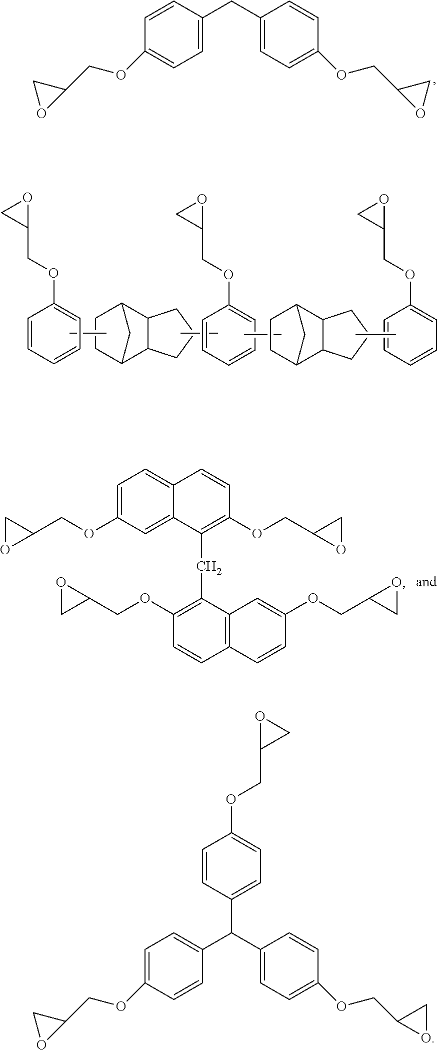

In certain aspects, the epoxy component is selected from the group consisting of epoxy-terminated polydimethylsiloxanes, and epoxy functionalized cyclosiloxanes, or epoxy functionalized polyhedral oligomeric silsesquioxane (POSS). Typically, the epoxy component comprises about 1 to about 90 weight %, about 5 to about 50 weight %, or about 10 to about 25 weight %, based on the total weight of the resin composition.

The anionic curing catalyst can include one or more compounds selected from the group consisting of: imidazole; 1-benzyl-2-phenylimidazole (1B2PZ); 1-benzyl-2-methylimidazole (1B2MZ); 2-phenyl-4-methylimidazole (2P4MZ); 2-phenylimidazole (2PZ); 2-ethyl-4-methylimidazole (2E4MZ); 1,2-dimethylimidazole (1.2DMZ); 2-heptadecylimidazole (C17Z); 2-undecylimidazole (C11Z); 2-methylimidazole (2MZ); imidazole (SIZ); 1-cyanoethyl-2-methylimidazole (2MZ-CN); 1-cyanoethyl-2-undecylimidazole (C11Z-CN); 1-cyanoethyl-2-ethyl-4-methylimidazole (2E4MZ-CN); 1-cyanoethyl-2-phenylimidazole (2PZ-CN); 1-cyanoethyl-2-phenylimidazolium-trimellitate (2PZCNS-PW); 1-cyanoethyl-2-undecylimidazolium-trimellitate (C11Z-CNS); 2,4-diamino-6-[2′-ethyl-4′-methylimidazolyl-(1′)]-ethyl-s-triazine (2E4MZ-A); 2,4-diamino-6-[2′-undecylimidazolyl-(1′)]-ethyl-s-triazine (C11Z-A); 2,4-diamino-6-[2′-methylimidazolyl-(1′)]-ethyl-s-triazine (2MZA-PW); 2,4-diamino-6-[2′-methylimidazolyl-(1′)]-ethyl-s-triazine (2MZ-A); 2-phenylimidazoleisocyanuric acid adduct (2PZ-OK); 2,4-diamino-6-[2′-methylimidazolyl-(1′)]-ethyl-s-triazineisocyanuric acid adduct dehydrate (2MA-OK); 2-phenyl-4-methyl-5-hydroxymethylimidazole (2P4MHZ-PW); 2-phenyl-4,5-dihydroxymethylimidazole (2PHZ-PW); 1-dodecyl-2-methyl-3-benzylimidazolium chloride (SFZ); 2,3-dihydro-1H-pyrrolo[1,2-a]benzimidazole (TBZ); 2-phenylimidazoline (2PZL-T); 2,4-diamino-6-methacryloyloxyethyl-1,3,5-triazine (MAVT); 2,4-diamino-6-vinyl-1,3,5-triazineisocyanuric acid adduct (OK); 2,4-diamino-6-vinyl-1,3,5-triazine (VT); Imidazole-4-carboxaldehyde (4FZ); 2-Phenylimidazole-4-carboxaldehyde (2P4FZ); Imidazole-2 carboxaldehyde (2FZ); Imidazole-4-carbonitrile (4CNZ); 2-Phenylimidazole-4-carbonitrile (2P4CNZ); 4-Hydroxymethylimidazolehydrochloride (4HZ-HCL); 2-Hydroxymethylimidazolehydrochloride (2HZ-HCL); Imidazole-4-carboxylic acid (4GZ); Imidazole-4-dithiocarboxylic acid (4SZ); Imidazole-4-thiocarboxamide (4TZ); 2-Bromoimidazole (2BZ); 2-Mercaptoimidazole (2SHZ); 1,2,4-Triazole-1-carboxamidinehydrochloride (TZA); (t-Butoxycarbonylimino-[1,2,4]triazol-1-yl-Methyl)-carbamic acid t-butyl ester (TZA-BOC); Thiazole-2-carboxaldehyde (2FTZ); Thiazole-4-carboxaldehyde (4FTZ); Thiazole-5-carboxaldehyde (5FTZ); Oxazole-2-carboxaldehyde (2FOZ); Oxazole-4-carboxaldehyde (4FOZ); Oxazole-5-carboxaldehyde (5FOZ); Pyrazole-4-carboxaldehyde (4FPZ); Pyrazole-3-carboxaldehyde (3FPZ); 1-azabicyclo[2.2.2]octane (ABCO); 1,4-diazabicyclo[2.2.2]octane (DABCO); 1,5-diazabicyclo[4.3.0]non-5-ene (DBN); 1,8-diazabicyclo[5.4.0]undec-7-ene (DBU); 1,5,7-triazabicyclo[4.4.0]dec-5-ene (TBD); 7-methyl-1,5,7-triazabicyclo[4.4.0]dec-5-ene (MTBD); 1,2,2,6,6-pentamethylpiperidine (PMP); and 4-(dimethylamino)-1,2,2,6,6-pentamethylpiperidine.

Typically, the anionic curing catalyst component comprises about 0.1 to about 10 weight % or 0.5 to about 5 weight % based on the total weight of the resin composition.

The curable polyimides with phenolic moieties can also react with other resins, such as oxetanes, cyanate esters, and benzoxazines in a ring-opening function to form thermosets. Those are also contemplated in the practice of the invention.

### Prepregs, Copper-Clad Laminates and Printed Circuit Boards

A process for forming copper-clad laminate typically requires formulations of dielectric materials to be dissolved in a solvent and doctor bladed or otherwise spread onto a continuous moving thin copper sheet on a heated conveyor belt. On the continuous line a second sheet of copper is applied on top of the dried B-staged dielectric, followed by lamination between hot rollers to form a 3-layer copper-clad laminate. Further heating up to 200° C. with pressure may be required to obtain a fully cured polymer and to assure high adhesion to both sides of the copper.

The present invention also provides compositions and methods for making prepregs (reinforcement fiber pre-impregnated with a resin), copper-clad laminates and printed circuit boards. Also provided are prepregs, copper-clad laminates and printed circuit boards comprising polyimides of the invention.

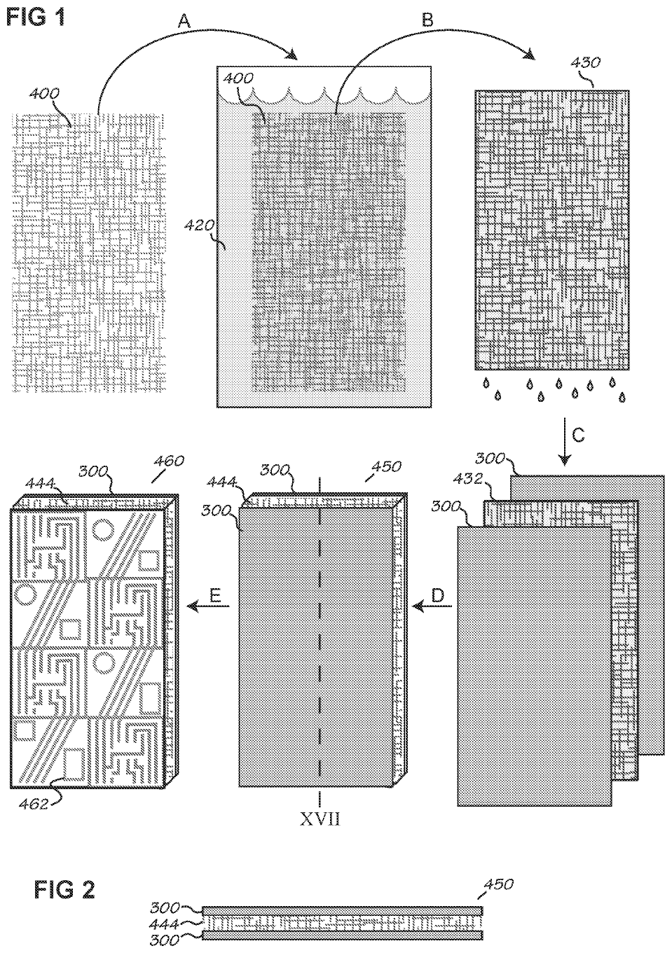

The process for preparing prepregs, copper-clad laminates and printed circuit boards is illustrated in FIG. 1. Steps in the process are indicate by arrows. The process begins with a reinforcing fiber 400 such as, fiberglass or carbon fiber. The fiber can be in the form of a woven or unwoven fabric, or single strands of fiber that will be held together by the polymer. The fiber 400 is immersed in a liquid formulation 420 containing an uncured polyimide compound or composition described herein (step A), thereby impregnating the fiber with the polyimide formulation to form a prepreg. The wet prepreg 430 is then drained and dried to remove excess solvent (step B). Conveniently, the dried prepreg 432 can then be stored until needed.

The dried prepreg will typically be coated on one or both side with a layer of copper to form a copper-clad laminate (CCL). The copper can be applied by electroplating or by laminating thin copper foil to the prepreg. FIG. 1 illustrates preparation of a double-sided copper-clad laminate using copper foil 300. Thus. in step C, the dried prepreg 432 is assembled in a sandwich fashion with a sheet of copper foil 300 on either side. Optionally, layers of adhesive can be interleaved between the foil to increase adhesion (not shown). This is likely unnecessary because polyimides of the invention have strong adhesive properties. In some embodiments, adhesion promoters can be added to formulation 420 to increase bonding of the foil to the prepreg. In step D, the foil 300 is laminated to the prepreg 432 using heat and pressure. Advantageously, polyimides of the invention can be cured using heat. FIG. 2 shows a cross section of CCL 450 having a central core of fiber-reinforced, cured polyimide 444, laminated to copper foil 300 on each side.

Circuit patterns 462 can then be formed on either or both sides (double-sided CCL) of the CCL 450 by photolithography to from a printed circuit board (PCB). 460. The resulting PCB exhibits the high structural strength and very high thermo-oxidative resistance necessary for contemporary electronics applications.

### Flexible Copper-Clad Laminates

The compounds and compositions of the invention are useful in any application that requires high temperature stability, adhesion and flexibility, such as copper-clad laminates. Copper-clad laminates are materials that are made from layers of a polymer dielectric material sandwiched between copper foil. In many cases multi-layers of these materials impregnated onto glass fiber are laminated together under pressure and heat to produce a composite that can be used to make printed wiring boards.

To make copper-clad laminate a piece of flexible film is typically cut from a large roll of film, adhesive is applied to one or both sides of the film and then copper foil is placed on both sides, this is followed by lamination process using heat and pressure. Alternatively, a solution containing the oligomeric materials along with co-reactants can be doctor bladed onto long copper sheet on a conveyor belt and dried or B-staged. A second layer of copper foil is placed on top and laminated between hot rollers. The triple-layer copper-clad laminate can go through an oven curing process or laminated under pressure and heat to form the product.

In both cased the material during the B-staged process needs to be flat and flexible. Curling of single sided copper foil is a significant problem to be avoided. Also, a brittle B-staged film is difficult to work with and not desirable in the application.

The invention polyimide material is curable with epoxies and other resins; therefore, it does not require the use of adhesive layers. The invention curable polyimide material is cast from solution to form a thin film that needs to be flexible and rollable. The material is then cut to size and placed between copper foils. Once heated during the lamination process the material cures and adheres to the copper foil acting as a dielectric layer.

Also, the invention polyimide material is flexible enough at the B-staged phase that it does not cause curling of the copper foil. The material on a single side of copper foil once dried, remain stays flat and allows for a process that is continuous and very manufacturable.

Ideally, an adhesive dielectric film is curable so that is has maximal adhesion to copper surfaces. Curable films achieve maximal the maximal effect of adhesion promoters and coupling agents

In order to produce a copper-clad laminate from our materials one would need to cast a continuous thin film of the uncured polyimide; the polyimide would need to be dried and wound into giant rolls. The rolls of polyimide are then cut to size and sandwiched between copper foils. Multi-layered material can also be prepared, followed by lamination process under heat and pressure. The heat will cause a polymerization of the functionalized polyimide and offer good adhesion to the copper foil.

In order to have a material that can be cast into a thin flexible film and be able to be wound into a roll, it has been determined through experimentation that the average molecular weight of the polyimide needs to be greater than 20,000 Daltons. An average molecular weight of less than 20,000 Daltons produces a material that when dried is very brittle and cannot be wound into a roll. The average molecular weight is preferably between 50,000 and 70,000 Daltons, this would allow for enough functionalization at the terminal positions in order to cure the material and produce a thermoset material.

Alternatively, the phenol moieties can also be placed on the backbone of the polymer as pendent groups. Using these technology high molecular weights in excess of 50,000 Daltons can be synthesized. Using pendent phenolic groups also has the benefit of being able to increase the functionality, which would in turn produce much higher cross-link density

In another embodiment of the invention the terminal groups are functionalized with polymerizable moieties. The invention polyimides are functionalized with phenolic moieties.

Another process for forming copper-clad laminate would require the invention formulations to be dissolved in a solvent and doctor bladed onto a continuous moving thin copper sheet on a heated conveyor belt. On the continuous line a second sheet of copper would be applied on top of the dried B-staged material followed by lamination between hot rollers to form a 3-layer copper-clad laminate. Further heating with pressure may be required to obtain a fully cured polymer and to assure high adhesion to both sides of the copper.

In particular, flexible copper-clad laminates (FCCLs) are increasingly used in electronics as they can provide the ultrathin profile demanded by increasing miniaturization. Moreover, circuitry is becoming prevalent in non-traditional situations, such as clothing, where the ability to conform to a three-dimensional shape other than a flat board is required.

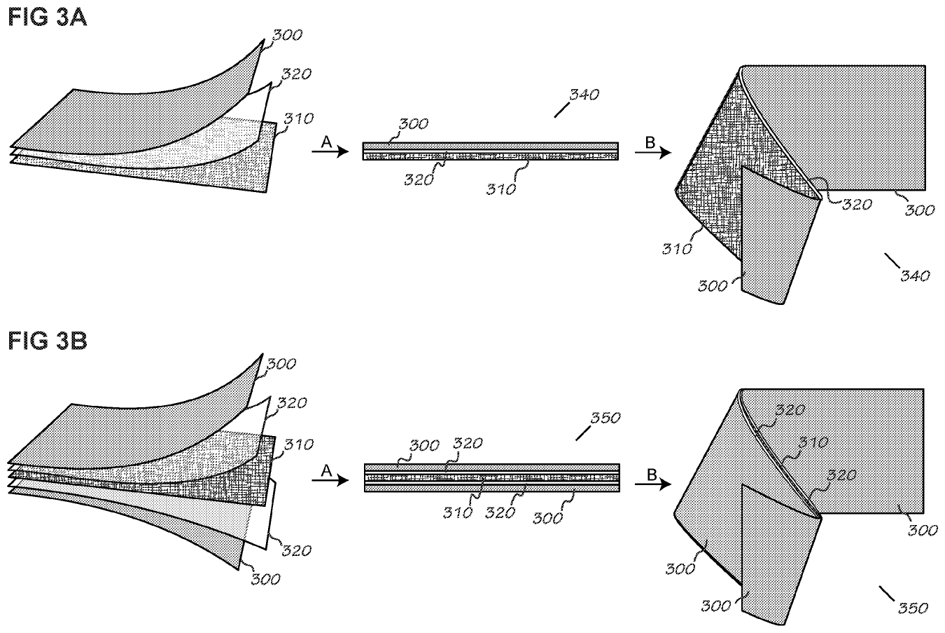

A process of forming FCCLs according to one embodiment of the invention is illustrated in FIGS. 3A and 3B for single- and double-sided FCCLs, respectively. The process is similar to preparing a prepreg-based CCL but is much thinner and lacks the rigidity of a prepreg. A thin and flexible film of polyimide polymer 310 prepared as described herein, is assembled with an adhesive layer 320 and copper foil 300 (FIG. 3A). The assembly is then laminated (step A) to form a single-sided copper-clad laminate 340. The FCCL can then be rolled, bent or formed as needed (step B), while providing the basis for thin, flexible circuitry that can be used in consumer electronics, clothing and other goods.

Double-sided FCCL production according to one embodiment of the invention, is illustrated in FIG. 3B. This process is identical to that illustrated in FIG. 3A, except that the adhesive layer 320 and copper foil 300 are placed on both sides of polymer film 310 to form a 5-layer assembly, which is then laminated (step A) to form a double-sided FCCL 350.

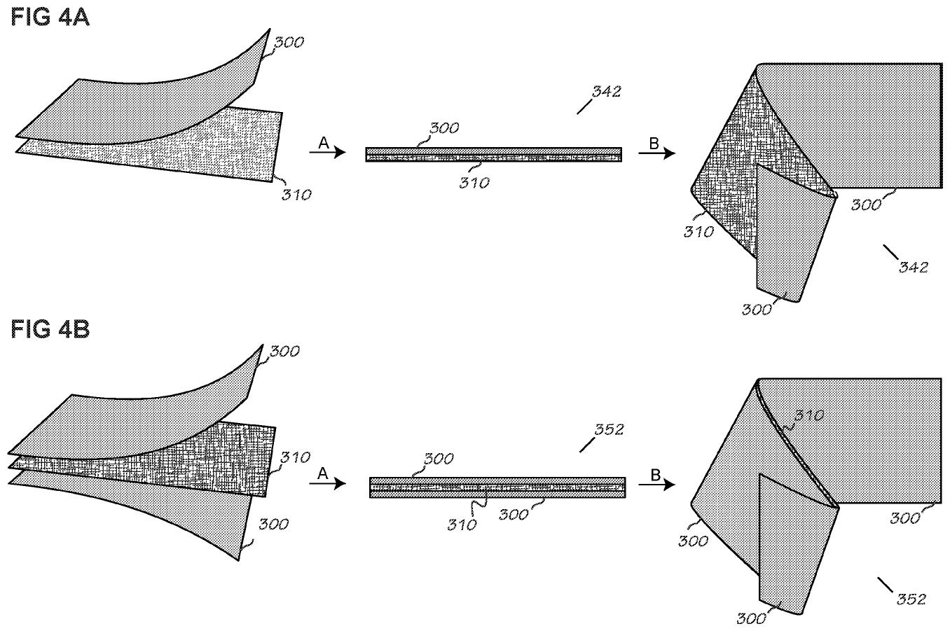

In another embodiment of the invention, adhesiveless processes for producing FCCL are provided as shown in FIGS. 4A and 4B. Single-sided FCCL (FIG. 4A) is prepared by contacting copper foil 300 with one side of a polyimide film 310 prepared as described herein. The film is then heat-cured (step A), onto the foil to form an adhesiveless FCCL 342, which is thinner and more flexible than FCCL that includes an extra layer (i.e., the adhesive layer). The single-sided, adhesiveless FCCL 342 can be rolled, bent, or formed into a desired shape before (step B) or after patterning (not shown).

Double-sided, adhesiveless FCCL can be prepared (FIG. 4B) in the same manner as the single-sided product, except that both sides of film 310 are contacted with foil 300 prior to curing (step B). The double-sided adhesiveless FCCL 352 according to this embodiment of the invention can similarly be rolled, shaped, and formed (step B).

In yet another FCCL embodiment of the invention eliminates the step of forming a polymer film prior to assembly. Instead, a liquid formulation of the polymer is applied directly to the copper foil. Application can be by any method known in the art, such as by pouring, dropping, brushing, rolling or spraying, followed by drying and heat-curing. To prepare a double sided FCCL according to this embodiment of the invention, polymer-coated foil is prepared, dried and then a second foil is contacted on the polymer side of the foil prior to curing.

Application of circuit traces to FCCL can be performed using standard photolithography processes developed for patterning printed circuit boards.

### Temporary Adhesives

Temporary adhesives are used through the fabrication of electronics devices and components, at various steps where a removable attachment is required, or when permanent attachment is facilitated by temporarily holding two or more parts together. An exemplary use of temporary adhesive is in the process of backgrinding silicon wafers to a desired thickness.

Backgrinding is a semiconductor device fabrication process that reduces the thickness of semiconductor wafers (e.g., crystalline silicon wafers), which allows stacking and high-density packaging of integrated circuits (IC), often referred to as “chips”. ICs are produced from semiconductor wafers that may undergo a multitude of processing steps under harsh conditions to produce a final package. Silicon wafers predominantly in use today have diameters of 200 mm and 300 mm from which hundreds of IC microchips can be made. Wafers can also be made of materials other than pure silicon and/or can be doped with metals such as B, Al, Ar, P, Li, Bi, Ga and combinations thereof. For the purposes of this disclosure, “wafer” refers to semiconductor wafers made from silicon, doped silicon and/or any other material.

Wafers are initially produced having a thickness of approximately 750 m, which ensures mechanical stability and avoids warping during processing steps. These thick wafers are then ground down to application-specific thickness, typically 75 to 50 m.

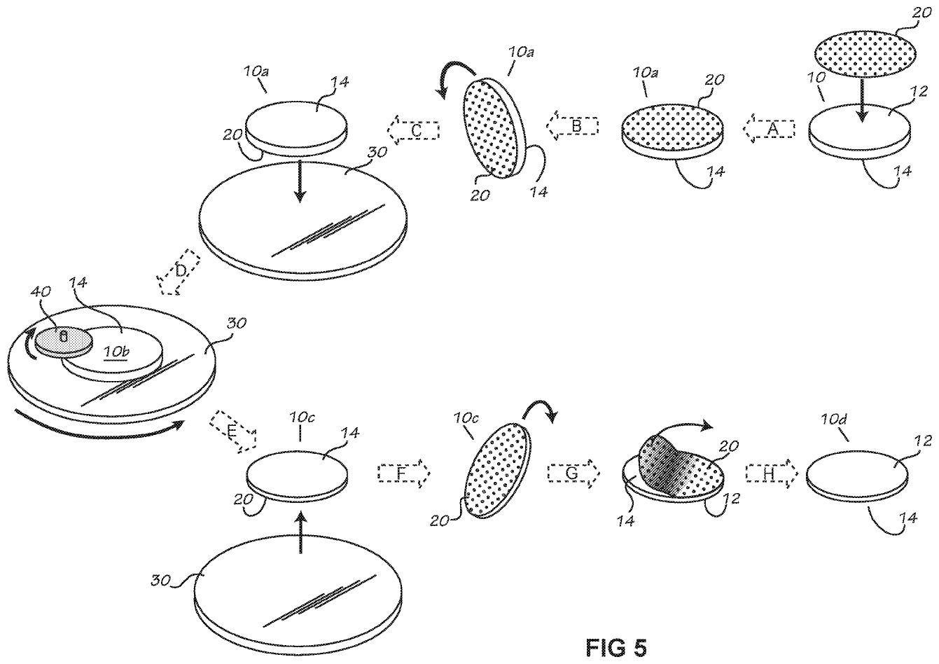

The process of thinning a wafer is referred to as “backgrinding” and is illustrated in FIG. 5 (where each of steps A-H is represented by a lettered arrow). A temporary adhesive 20 is applied to the top surface 12 of a wafer 10 (step A). In some embodiments, a release layer or compound (not shown) is also applied to wafer 10 and/or support 30 prior to applying temporary adhesive 20 to facilitate subsequent removal (described below). Backgrinding can generate significant heat. Thus, the temporary adhesive selected for this process should be very thermally stable for extended periods of time at temperatures in excess of 250° C., preferably in excess of 300° C. and often in excess of 350° C. with little or no weight loss that would cause delamination.

In some embodiments, the wafer 10 incudes a circuit pattern and/or other electronic elements (e.g. solder bumps) disposed on the top surface 12 prior to backgrinding. In other embodiments, these patterns and/or elements are applied following backgrinding as illustrated in FIG. 5.

In addition to securing the wafer in place, the temporary backgrinding adhesive 20 protects the wafer surface from surface damage and contamination. Thus, the adhesive materials must be tough enough to withstand physical assaults, as well as being resistant to many solvents used in the grinding and cleaning processes. Typically, the adhesive 20 is a UV-curable or is pressure-sensitive tape or film. In certain embodiments of the invention, the adhesive 20 is sprayed or spin-coated onto wafer 10. Advantageously, sprayed or spin-coated adhesive can be applied to a layer thickness that accommodates surface variabilities (e.g. solder bumps, vias, etc.).

Next (step B), the adhesive-coated wafer 10a is inverted to expose the back side of the wafer, and the adhesive side is bonded to a support 30 (step C), which support is frequently glass. In some embodiments, a release layer or compound (not shown) is also applied to wafer 10 and/or support 30 prior to applying temporary adhesive 20 to facilitate subsequent removal (described below. The resulting support-bound wafer 10b, is then ground with grinding and polishing means 40 to a desired thickness in step D. The grinding and polishing means 40 can include abrasive grinding tools that contact the wafer back side 14 as well as various grits of grinding and polishing compounds. Grinding is completed when the wafer thickness has been reduced, the back side 14 of the support-bound wafer 10b has been polished to the required smoothness, and the wafer thoroughly cleaned to remove all traces of grinding residue and contaminants.

The wafer is then removed from the support (step E), which in some embodiments of the invention, can be accomplished by further exposure to UV irradiation. In these embodiments, the adhesive composition is either pressure sensitive or is initially partially cured (e.g., with a controlled exposure to UV), producing a highly adhesive composition that effectively adheres to both the wafer top side 12 (step A) and backgrinding wafer support 30 (step C). To remove the adhesive from the support, further exposure to UV fully cures the adhesive to a glassy, high T_{g} composition which separates easily from support 30. In other embodiments of the invention, the adhesive is thermoplastic, and UV-curable such that it stiffens when cured and is easier to peel off. In certain embodiments of the present invention, removal of thinned wafer 10b from support 30 is accomplished with the assistance of an air jet, which introduces voids and/or gaps between wafer 10b and support 30.

The thinned wafer 10c, once removed from the support (step F), can be inverted (step G) and the remaining adhesive removed by peeling with the assistance of an air jet (step H) and if needed, soaking in a dish of cyclopentanone or cyclohexanone (not shown) to dissolve the polymer leaving the adhesive-free, thinned wafer 10d.

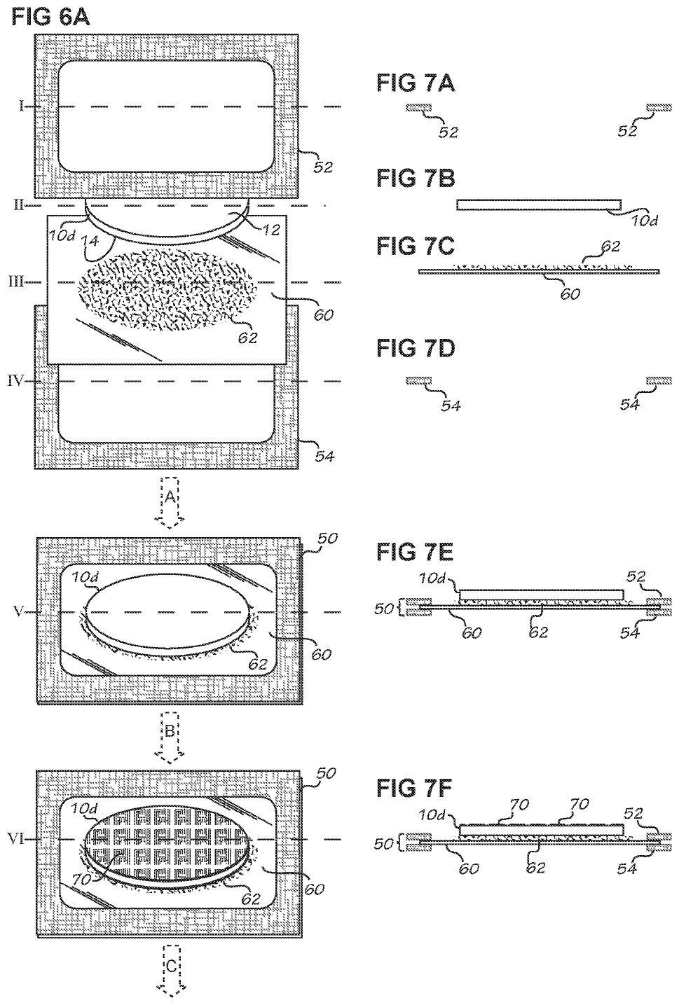

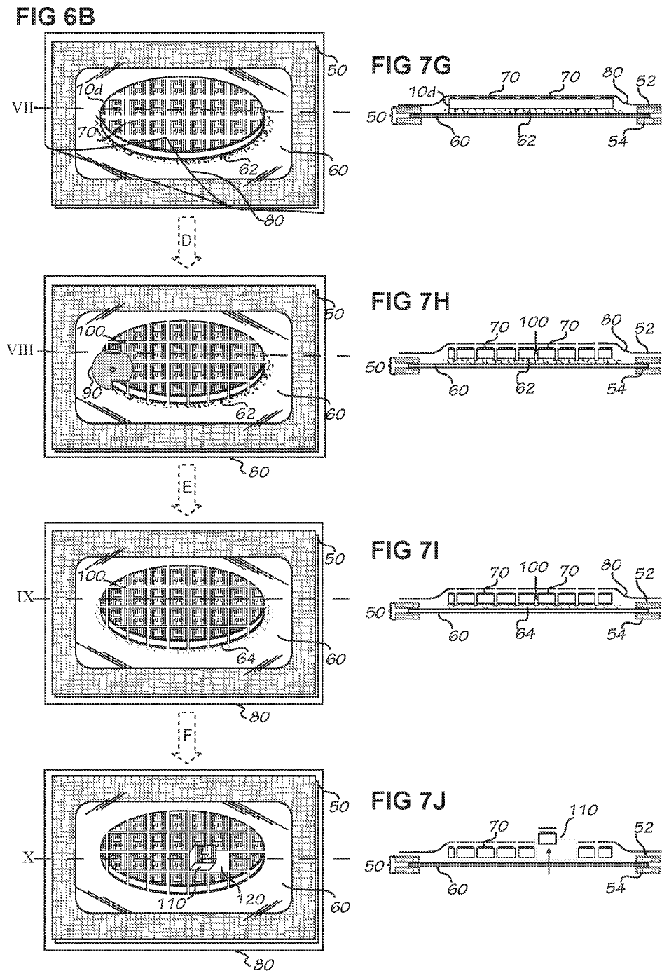

Dicing is the process by which die are separated from a semiconductor wafer, typically following the processing of the wafer, as illustrated in FIGS. 6A and 6B, and in parallel FIGS. 7A-7J, which show cross-sections of the structures illustrated in FIGS. 6A and 6B. FIGS. 6, 6A, 6B and 7A-J, illustrate an exemplary work flow in which wafers are first thinned, then processed (e.g., “patterned” to form circuits on the wafer), and thereafter, cut into individual dies. Is should be noted that these steps can be performed in any order, such as circuit formation, followed by thinning, and thereafter dicing. Indeed, even packaging, typically a post-singulation process, can be performed at the wafer-level prior to dicing. This process, known as “fan-in” wafer-level packaging, yields packages that are die-sized instead of larger than die size. In some aspects, partial dicing can be performed prior to patterning and thinning. In this aspect, the final separation of individual dies occurs when the wafer is ground to meet the partial dicing cuts. Variations on these steps, including the order in which they are performed, are encompassed by the invention and within the ordinary level of skill in the art.

As illustrated in FIG. 6A, wafer dicing typically begins with mounting a thinned wafer 10d on dicing tape 60 that includes an adhesive 62. Dicing tape 60 typically has a PVC (polyvinylchloride), PO (polyoxymethylene), PE (polyethylene), PET (polyethylene terephthalate), or similar strong, high-temperature-resistant plastic backing, with an adhesive deposited thereon. In some embodiments, adhesive 62 covers the complete surface of the tape. In other embodiments, adhesive 62 covers a surface area corresponding to wafer size as illustrated in FIG. 6A. In some embodiments, the adhesive is pressure-sensitive, while in other embodiments, the adhesive is UV-cured. The tape, with mounted wafer is assembled with a support frame 50 (step A). Typically, support frame 50 is made of thin metal and may consist of a bottom frame 54 and a top frame 52. Alternatively, frame 50 may have only a bottom frame 54 with the top frame function supplied by securing the frame in a dicing device. In either case, the frame must elevate the wafer to permit access by subsequent processing equipment as shown in FIG. 7E.

The requirements for dicing tape 60, and particularly the adhesive 62, are that it withstand the conditions of temperature and pressure of dicing and any other processes that will be performed on the mounted wafer, yet easily release each individual “singulated” die 110. As the processes carried out on wafers prior to dicing vary, dicing tape 60 with a range of tack strengths are required. In some embodiments, low tack adhesive is used to facilitate easy release, while for other applications that require higher adhesion during processing, a UV-releasable adhesive is required. Such adhesives initially have high tack strength upon partial curing. After dicing, the adhesive is fully cured, which reduces adhesion and releases the die 110.

The mounted wafer can be processed by applying circuit tracings/patterns, and other pre-packaging features, which may be performed by plating, photolithography, drilling, or any other suitable method known in the art. Application of circuit patterns 70 is represented by step B. Advantages of performing such steps on a wafer rather than singulated die include efficient use of the wafer, the ability to inspect and analyze circuits en masse, and positioning of circuitry to allow a regularly spaced unpatterned scribe line or “saw street” matched to the dicing equipment.

After patterning, the wafer 10d is covered with a film 80, typically Mylar® (polyethylene terephthalate) (step C), to protect the delicate wiring 70 from sawdust and physical damage during dicing.

The wafer 10d is then cut with a dicing means 90, such as a saw (as illustrated) or a laser, along the saw street, forming a channel 100 between individual die (step D). If a UV release adhesive is used, the adhesive 62 is then exposed to UV light to release 64 the die from the dicing tape (step E). Finally, the individual die 110 are removed one at a time (step F) from wafer 10d, leaving a void 120. Removal can include picking the individual die from above (e.g. using a vacuum device), pushing the die from below (see arrow in FIG. 7J), or a combination thereof.

### EXAMPLES

### Materials and Methods

### Dynamic Mechanical Analysis (DMA)

Polymer formulations were prepared in a suitable solvent (e.g. anisole) with <5% dicumyl peroxide (Sigma-Aldrich, St. Louis Mo.), and 500 ppm inhibitor mix (Designer Molecules, Inc.; Cat. No. A619730; weight % p-Benzoquinone and 70 weight % 2,6-di-tert-butyl-4-methylphenol) and dispensed into a to 5 inch×5 inch stainless steel mold. The mixture was then vacuum degassing and the solvent (e.g. anisole) was allowed to slowly evaporate at 100° C. for ˜16 hours in an oven. The oven temperature was then ramped to 180° C. and held for 1 hour for curing. Then the oven temperature was ramped to 200° C. and held for 1 hour before cooling to room temperature. The resulting film (400-800 m thick) was then released from mold and cut into strips (˜ 2 inch×˜7.5 mm) for 6±1 mm×23±1 mm×0.5±0.3 mm thickness) for measurement.

The strips were analyzed on a Rheometrics Solids Analyzer (RSA ii) (Rheometric Scientific Inc.; Pisca away, N.J.) with a temperature ramp from 10 to 250° C. at a rate of 5° C./min under forced air using the Dynamic Temperature Ramp type test with a frequency of 6.28 rad/s. The autotension sensitivity was 1.0 g with max autotension displacement of 3.0 mm and max autotension rate of 0.01 mm/s. During the test, maximum allowed Force was 900.0×g and min allowed force is 3.0×g. Storage modulus and loss modulus temperature were plotted against and temperature. The maximum loss modulus value found was defined as the glass transition (T_{g}).

### Coefficient of Thermal Expansion (CTE)

Formulations were prepared as above for DMA. Samples sufficient to give a 0.2 mm to 10 mm thick film were dried at 100° C. for 2 hours to overnight and cured for 1-2 hours at ˜180° C. to ˜250° C.

Hitachi TMA7100 was used for CTE measurement in expansion mode. The film was placed on the top of a sample holder (disk type quartz) and move down quartz testing probe was lowered onto top of the sample to measure sample thickness. The temperature ramped from 25° C. to 250° C. at a 10° C./min, load 10 mN to measure expansion/compression. CTE was calculated as the slope of length change verses temperature change in ppm/° C. α1 CTE and α2 CTE are calculated based on T_{g}.

### Thermalgravimetric Analysis (TGA)

The test film sample was prepared by drying a solution of the test sample at 100° C. for 1 hour to remove the solvent followed by curing at 200° C. for 1 hour.

Thermalgravimetric analysis measurements were performed on an TGA-50 Analyzer (Shimadzu Corporation; Kyoto, Japan) under an air flow of 40 mL/min with heating from room temperature to 505° C. at a 10° C./min heating rate. The sample mass lost versus temperature change was recorded and the decomposition temperature was defined at the temperature at which the sample lost 5% of its original mass. Td (5%) is the temperature at which a 5% weight loss of cured sample was observed in air atmosphere.

### Tensile Strength and Percent Elongation

Samples were dried to remove solvent at 100° C. for 2 hours to overnight and cured for 1-2 hours at 180° C.˜250° C. in a metal mold to obtain thin films. Test strip film dimension for test was 6 inch×0.5 inch×0.25 inch; measurement length 4.5 inches.

The tensile strength and percent elongation were measure using an Instron 4301 Compression Tension Tensile Tester. Tensile strength was calculated as the ratio of load verses sample cross-section area (width×thickness). Percent elongation was calculated as the ratio of original length of sample (4.5 inch) verses length at break point.

### Permittivity/Dielectric Constant (Dk) and Loss Tangent/Dielectric Dissipation Factor (Df)

Formulations were prepared as above for DMA, except that 30 mm×30 mm×>300 μm thickness was used for analysis.

Dk and Df measurements were carried out by National Technical Systems (Anaheim, Calif., USA) with IPC TM-650 2.5.5.9 (JEDEC Solid State Technology Association 2000, Arlington, Va.; viewed at www [dot] ipc [dot] org/TM/2.5.5.9.pdf). as the test procedure using an AET Anritsu tester at 20 GHz frequency. The samples were placed in a conditioning cabinet at 23±2° C. and 50±5% relative humidity for 24 hours prior to testing, which was performed at measured conditions of 22.2° C. and 49.7% relative humidity. One sweep of the impedance material analyzer was performed with an oscillatory voltage of 500 mV at 1.5 GHz and the sweep was performed between 99.5% and 100.5% of the desired value (1.4925 GHz and 1.5075 GHz).

### Peel Strength

This test was performed to determine adhesion strength of dielectric material (polymer film) on a copper surface. Samples were prepared by coating and drying test material on Cu foil. A second Cu foil was laminated onto the b-staged/dried dielectric layer in a Hogdog 120DX laminator at 100° C. with speed 3. Double sided Cu-dielectric material-Cu specimens were cured at 200° C. for 1 hour. Peel strength measurement was based on IPC-TM-650 2.4.9 by Instron (JEDEC Solid State Technology Association 2000, Arlington, Va.; viewed at www [dot] ipc [dot] org/TM/2.4.9e.pdf).

### Percent Elongation and Tensile Strength

Measured were taken using an Instron instrument with dog-bone shape samples, based on the IPC-TM-650 2.4.18.1 method (JEDEC Solid State Technology Association 2000, Arlington, Va.; viewed at www [dot] ipc [dot] org/4.0_Knowledge/4.1_Standards/test/2.4.18.1.pdf).

### Water Absorption

This test was performed by immersing a cured sample in deionized water for 24 hours at 23° C. Percent water absorption was calculated by measuring sample weight before and after immersion. Solder Float Test

Solder float test was performed to decide material stability during solder reflow process of laminated substrates. This test was performed as described in IPC-TM-650 2.4.13 (The Institute for Interconnecting and Packaging Electronic Circuits, Northbrook, Ill.; viewed at www [dot] ipc [dot]org/TM/2.4.13f.pdf) with flexible copper-clad laminate (FCCL) samples prepared from dielectric test material laminated to copper foil. FCCL samples were prepared by laminating dielectric test film between two sheets of copper foil, followed by curing at 200° C. for 1 hour. Lead-free solder (Sn95/Sb5).

### 250 TC Temperature Cycles Test

This test was conducted to determine the ability of components to withstand vieeechanical stresses induced by alternating high- and low-temperature extremes based on JESD22-A104 test method (test condition C) (JEDEC Solid State Technology Association 2000, Arlington, Va.; viewed at: web [dot] cecs [dot] pdx [dot] edu/˜cgshirl/Documents/22a104b %20Temperature %20Cycling.pdf).

Evaluation was performed by visual inspection for blisters, delamination, or other appearance change after 250 cycles from −65° C. to 150° C. Total transfer time from −65° C. to 150° C. was 1 minute and total dwell time at each temperature was 30 min. TC 250 “PASS” means there was no appearance change observed such as blister or delamination.

### Gel Permeation Chromatography

Gel permeation chromatography analysis of polymer molecular weight was carried out on an Ultimate 3000 HPLC instrument (Thermo Scientific; Carlsbad, Calif.) using tetrahydrofuran (THF) as eluent solvent and polystyrene standards as reference for molecular weight (MW) calculation based on the retention time of the polymer samples compared to a standard curve. The standards used had MWs of: 96,000; 77,100; 58,900; 35,400; 25,700; 12,500; 9,880; 6,140; 1,920; 953; 725; 570; 360; and 162. UV-vis detecting mode was applied at wavelength 220 nm and 10 mg/mL polymer in THF solution were used for testing.

### Fourier Transform Infrared Spectroscopy (FTIR)

FTIR analysis was performed using a Bruker Alpha II FT-IR spectrophotometer (Bruker Corp.; Billerica, Mass.).

### Nuclear Magnetic Resonance (NMR)

Proton (¹H) and carbon (¹³C) NMR were carried out by NuMega Resonance Labs (San Diego, Calif.) using a Bruker 500 MHz Bruker NMR spectrometers.

### Chemicals

Unless another supplier is indicated, chemicals were purchased from TCI America, Portland Oreg.

### Example 1: Synthesis of Phenolic-Functionalized Polyimide (Compound 1)

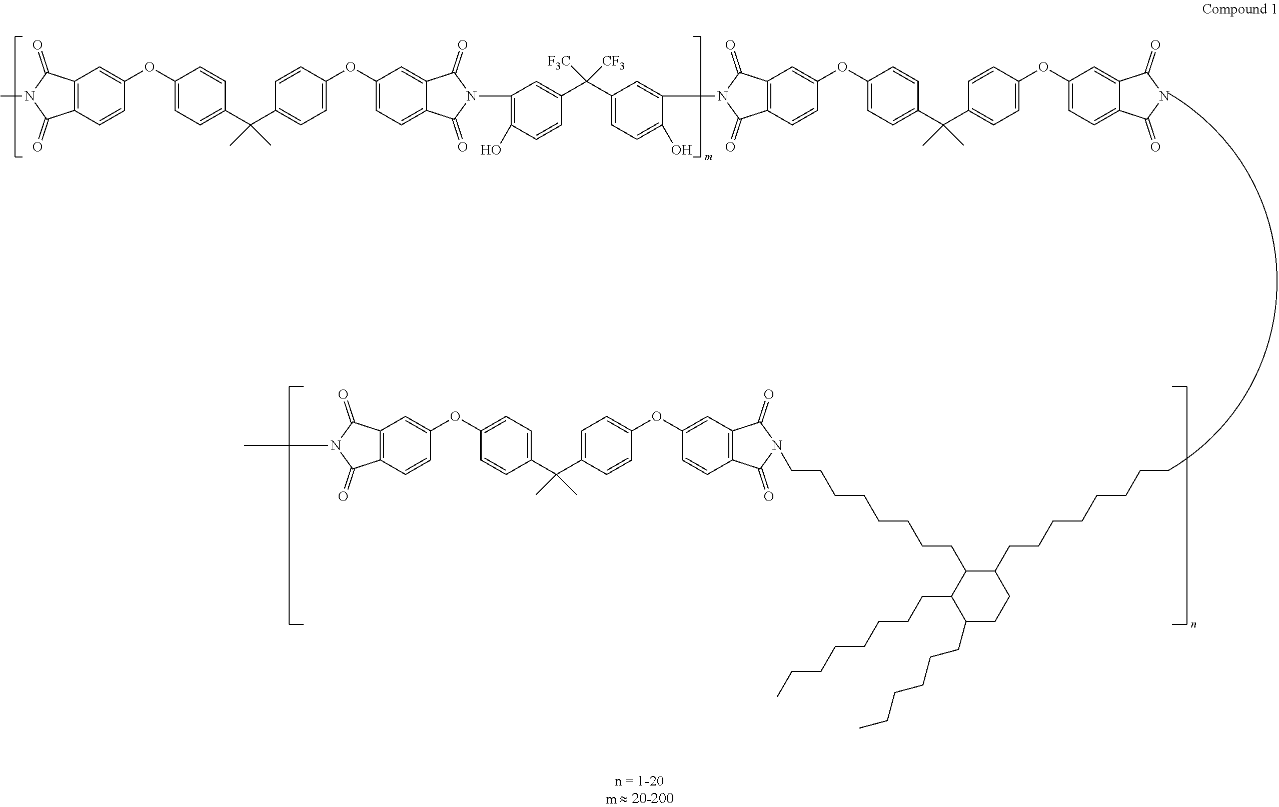

A 1 L 3-neck flask with mechanical stirrer was charged with 10 mmol (3.66 g) of 2,2-bis(3-amino-4-hydroxyphenyl) hexafluoro propane (Wilshire Technologies; Princeton, N.J.), and 90 mmol (49.41 g) of PRIAMINE®-1075 (Croda International; Snaith, East Riding of Yorkshire, UK). To the flask was added 500 grams of anisole (Kessler Chemicals; Charlotte, N.C.). The mixture was stirred at room temperature for 15 minutes to completely dissolve the reagents. 102 mmol (53.2 g) of bisphenol-A dianhydride (Millipore Sigma; Burlington, Mass.) was added, and the solution was heated to reflux at 155° C. for 2 hours to complete formation of a phenolic-functionalized polyimide, with the azeotropic removal of approximately 4 mL of water. The light-yellow solution containing 100% of theoretical yield of polyimide product, was adjusted to a 15% solids solution in anisole and stored in anisole until use.

Characterization of Product. ¹H NMR (CDCl₃) δ 0.86 (t, 6H), 1.30 (m, 30H), 1.73 (m, 6H), 3.70 (m, 2H), 6.99 (d, 1H), 7.30 (m, 1H), 7.95 (s, 2H), 8.08 (s, 1H). ¹³C NMR (CDCl₃) d 14.3, 22.9, 27.1, 28.8, 29.4, 29.5, 29.9, 30.3, 31.2, 32.1, 33.9, 38.6, 42.7, 111.8, 120.1, 122.1, 122.5, 125.2, 128.8, 132.1, 132.9, 133.6, 145.3, 147.6, 153.0, 163.5, 168.0. Fourier Transform Infrared Spectroscopy (FTIR) vₘₐₓ revealed prominent absorptions at 2918, 2849, 1704, 1390, 1363, 1232, 843, 740, 545 wavenumbers.

Molecular Weight. Permeation Chromatography (GPC) analysis showed an average molecular weight (MW) of ˜100,000±20,000 Daltons.

Film Preparation. A film was cast from the 15% solids solution in anisole into a flat aluminum mold (127 mm×127 mm×0.5 mm) coated with release agent. The mold was placed in an oven at 100° C. for 3 hours to evaporate the solvent. The material was then heated to about 200° C. for 1 hour to ensure complete removal of all volatiles and cure the polyimide.

The film composition was analyzed for properties described above under Materials and Methods. Properties of Compound 1 are summarized in Table 1 below.

TABLE 1
Properties of Compound 1 Film

| Property | Value |
|---|---|
| Tensile Strength (MPa) | ~18 |
| Elongation (%) | ~350 |
| Dk @20 GHz | 2.4 |
| Df @20 GHz | 0.0014 |
| T_{g} (TMA) (° C.) | 47.3 |
| Young's Modulus@ 25° C. (MPa) | 587.15 |
| Td (5%) (° C.) | 415.3 |
| Peel Strength on Copper foil (kN/m) | 0.79 |
| Water absorption (23° C./24 hrs) (%) | 0.27 |
| Solder float test, 30 sec@288° C. | Pass |
| 250 TC temperature cycles | Pass |

### Example 2. Synthesis of Phenolic-Functionalized Polyimide (Compound 2)

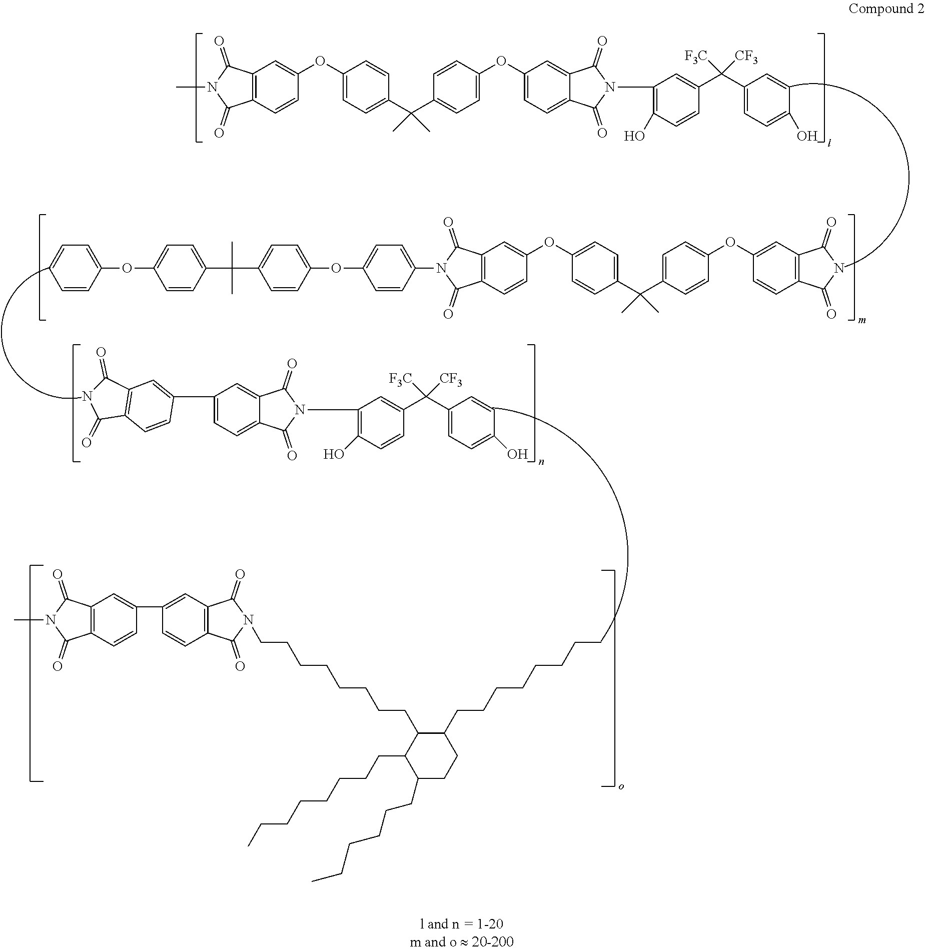

A 1 L 3-neck flask with mechanical stirrer was charged with 10 mmol (3.66 g of 2,2-bis(3-amino-4-hydroxyphenyl) hexafluoro propane (Wilshire Technologies), 70 mmol (38.43 g) of PRIAMINE®-1075 (Croda International), and 20 mmol (8.21 g) of 2,2-bis[4-(4-aminophenoxy)phenyl]propane (Wilshire Technologies). 500 grams anisole (Kessler Chemicals) was added to the flask. The mixture was stirred at room temperature for 15 minutes to completely dissolve the reagents in the solvent. To the flask was added 75 mmol (39.0 g) of bisphenol-A dianhydride (Millipore Sigma) and 25 mmol (7.35 g) of biphenyltetracarboxylic dianhydride (Akron Polymer Systems; Akron, Ohio). The material was heated to reflux at 155° C. for 2 hours to complete the formation of the phenolic functionalized polyimide, with azeotropic removal of approximately 4 mL of water. The clear, colorless-solution containing 100% of theoretical yield, was adjusted to a 15% solids solution in anisole and stored in anisole until use.

Characterization of Product: ¹H NMR (CDCl₃) d d 0.863 (t, 4H), 1.30 (m, 24H), 1.73 (m, 4H), 3.69 (m, 2H), 6.98 (d, 1H), 7.20 (m, 1H), 7.95 (s, 2H), 8.08 (s, 1H). ¹³C NMR (CDCl₃) d 14.3, 22.9, 27.1, 28.8, 29.4, 29.5, 29.9, 30.3, 31.1, 32.1, 33.9, 38.3, 38.6, 42.7, 111.8, 120.9, 122.1, 122.2, 122.5, 124.2, 125.2, 132.1, 132.9, 133.6, 134.8, 145.3, 147.6, 153.0, 163.5, 168.1. (FTIR) vₘₐₓ revealed prominent absorptions at 2918, 2850, 1705, 1390, 1230, 842, 742, 545 wavenumbers.

Molecular Weight. Gel Permeation Chromatography (GPC) analysis showed an average molecular weight (MW) of ˜100,000±20,000 Daltons.

Film Preparation. A film was cast from the 15% solids solution in anisole into a flat aluminum mold (127 mm×127 mm×0.5 mm) coated with release agent. The mold was placed in an oven at 100° C. for 3 hours to evaporate the solvent. The material was then heated to about 200° C. for 1 hour to ensure complete removal of all volatiles and cure the phenol-functionalized polyimide.

The film composition was analyzed for properties described above under Materials and Methods. Properties of the Compound 2 film are summarized in Table 2 below.

TABLE 2
Properties of Compound 2 Film

| Property | Value |
|---|---|
| Tensile Strength (MPa) | ~18 |
| Elongation (%) | ~350 |
| Dk @20 GHz | 2.4 |
| Df @20 GHz | 0.0014 |
| T_{g} (TMA) (° C.) | 47.3 |
| Young's Modulus @25° C. (MPa) | 587.15 |
| Td (5%) air (° C.) | 415.3 |
| Peel Strength on Copper foil (kN/m) | 0.79 |
| Water absorption (23° C./24 hrs) (%) | 0.27 |
| Solder float test, 30 sec@288° C. | Pass |
| 250 TC temperature cycles | Pass |

### Example 3. Synthesis of Phenolic-Functionalized Polyimide (Compound 3)

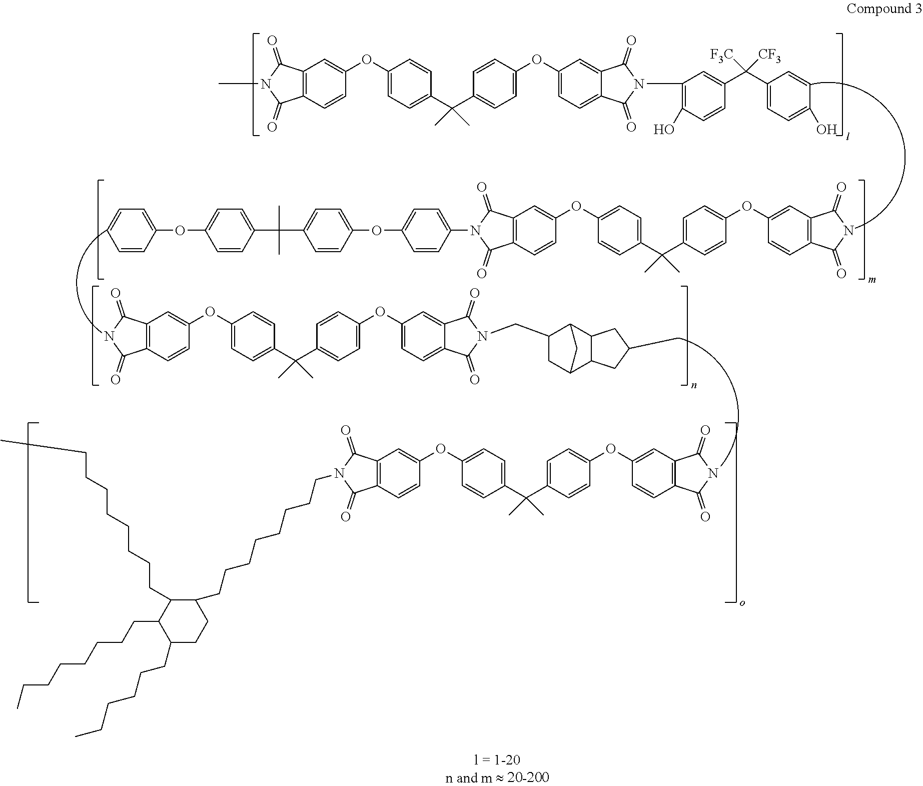

A 1 L 3-neck flask with mechanical stirrer was charged with 20 mmol (7.32 g) 2,2-bis(3-amino-4-hydroxyphenyl) hexafluoro propane (Wilshire Technologies), 50 mmol (27.45 g) PRIAMINE®-1075 (Croda International, Snaith, East Riding of Yorkshire, UK), 10 mmol (4.10 g) of 2,2-bis[4-(4-aminophenoxy)phenyl]propane (Wilshire Technologies), and 20 mmol (3.88 g) 3(4),8(9)-Bis-(aminomethyl)-tricyclo-[5.2.1.02,6] decane (TCD-diamine) (Oxea; Oberhausen, DE). 500 grams of anisole (Kessler Chemicals) was added to the flask. The mixture was stirred at room temperature for 15 minutes to completely dissolve the reagents in the solvent. 100 mmol (52.0 g) of bisphenol-A dianhydride (Millipore Sigma) was added to the mixture. The mixture was heated to reflux at 155° C. for 2 hours to complete formation of a phenolic functionalized polyimide, with the azeotropic removal of approximately 4 mL of water. The clear, colorless solutions containing 100% of theoretical yield, was adjusted to a 15% solids solution in anisole and stored in anisole until use.

Characterization of Product. ¹H NMR (CDCl₃) d (CDCl₃) d 0.87 (t, 2H), 1.30 (m, 13H), 1.73 (m, 5H), 3.63 (s, 1H), 6.99 (d, 2H), 7.29 (m, 4H), 7.75 (m, 1H). ¹³C NMR (CDCl₃) d 14.3, 22.9, 27.0, 28.8, 29.4, 29.6, 29.9, 31.2, 32.1, 38.3, 42.7, 111.8, 118.9, 119.1, 120.0, 122.5, 123.7, 125.2, 128.1, 134.8, 153.0, 154.5, 163.6, 168.1. FTIR vₘₐₓ revealed prominent absorptions at 2918, 2850, 1705, 1390, 1230, 842, 742, 545. wavenumbers

Molecular Weight. Gel Permeation Chromatography (GPC) analysis showed an average molecular weight (MW) of ˜100,000±20,000 Daltons.

Film Preparation. A film was cast from the 15% solids solution in anisole into a flat aluminum mold (127 mm×127 mm×0.5 mm) coated with release agent. The mold was placed in an oven at 100° C. for 3 hours to evaporate the solvent. The film was then heated to about 200° C. for 1 hour to ensure complete removal of all volatiles.

The film composition was analyzed for properties described above under Materials and Methods. Properties of Compound 3 are summarized in Table 3 below.

TABLE 3
Properties of Compound 3 Film

| Property | Value |
|---|---|
| Tensile Strength (MPa) | 19.2 |
| Elongation (%) | 350.00 |
| Dielectric Constant (Dk) | 2.342@20 GHz |
| Loss Tangent (Df) | 0.0021@20 GHz |
| T_{g} (TMA) (° C.) | 110.95 |
| Young's Modulus@25° C. (MPa) | 16.15 |
| Td (5%), air (° C.) | 445 |
| Peel Strength on Copper foil (kN/m) | 0.76_ |
| Water absorption (23° C./24 hrs) (%) | 0.32 |
| Solder float test, 30 sec@288° C. | Pass |
| 250 TC temperature cycles | Pass |

### Example 4: Comparison of Phenolic-Functionalized Polyimide Film Properties

Table 4 below is a comparison of the properties of the phenol-functionalized polyimides described in EXAMPLES 1-3. Extended imide-linked polyimides with phenolic-functionalization demonstrated excellent dielectric properties, which are required for 5G application; for 5G applications, a Df of less than 0.002 is preferred. For making flexible circuits it is also very important to have a high degree of flexibility, which is demonstrated by the high percent elongation observed with Compounds 1-3. Among the other desirable properties of these compounds are the high thermal stability (Td (5%) above 400° C.) and very low moisture absorption (0.37% or less). Since FCCL materials go through several heating processes during lamination and soldering, it is important that they pass the solder float test and 250TC temperature cycling tests.

TABLE 4
Summary of Film Properties of Phenolic-Functionalized Polyimide Resins

| | Compound | | |
|---|---|---|---|
| | 1 | 2 | 3 |
| Property | Values | | |
| T_{g} (DMA) | 47.33 | 64.84 | 110.95 |
| Modulus @25° C. | 587.15 | 50.45 MPa | 16.15 MPa |
| Dk | 2.4 | 2.435 | 2.342 |
| Df | 0.0014 | 0.0015 | 0.0021 |
| Td (5%) (° C.) | 415.3 | 415.31 | 445 |
| Peel strength on Cu, kN/m | 0.79 | 0.8 | 0.76 |
| % Elongation | 350.00 | 377.00 | 350.00 |
| Tensile strength, MPa | 18.0 | 17.8 | 19.2 |
| Water Absorption (23° C./24hr) | 0.27 | 0.37 | 0.32 |
| Solder float test, 30sec @288° C. | Pass | Pass | Pass |
| 250TC temperature cycles | Pass | Pass | Pass |

### Example 5. Formulation A: Combination of Compound 1 and Benzoxazine-Functionalized C₃₆ Co-Reactant

### Synthesis of Compound 4

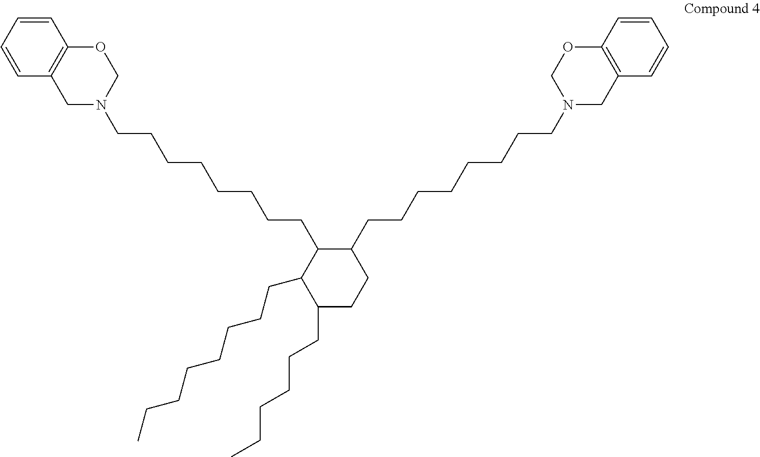 [SMILES: CCCCCCCCC1C(CCCCCC)CCC(CCCCCCCCN2COc3ccccc3C2)C1CCCCCCCCN1COc2ccccc2C1]

A 1 L 3-neck flask with mechanical stirrer was charged with 20 mmol (7.32 g) of 2,2-bis(3-amino-4-hydroxyphenyl) hexafluoro propane (Wilshire Technologies), 50 mmol (27.45 g) of PRIAMINE®-1075 (Croda International), 10 mmol (4.10 g) of 2,2-bis[4-(4-aminophenoxy) phenyl]propane (Wilshire Technologies), and 20 mmol (3.88 g) of TCD-diamine) (Oxea). To the flask is added 500 grams of anisole (Kessler Chemicals). The mixture was stirred at room temperature for 15 minutes to completely dissolve the materials. 100 mmol (52.0 g) of bisphenol-A dianhydride (Millipore Sigma) was added to the flask. The mixture was heated to reflux at 155° C. for 2 hours to complete formation of a phenolic functionalized polyimide, with the azeotropic removal of approximately 4 mL of water. The material was maintained in anisole as a 15% solids solution and used without further processing.

Characterization of FM51-13 Product: ¹H NMR (CDCl₃) δ 0.87 (t, 2H), 1.30 (m, 13H), 1.73 (m, 5H), 3.63 (s, 1H), 6.99 (d, 2H), 7.29 (m, 4H), 7.75 (m, 1H). ¹³C NMR (CDCl₃) d 14.3, 22.9, 27.0, 28.8, 29.4, 29.6, 29.9, 31.2, 32.1, 38.3, 42.7, 111.8, 118.9, 119.1, 120.0, 122.5, 123.7, 125.2, 128.1, 134.8, 153.0, 154.5, 163.6, 168.1. FTIR vₘax revealed prominent absorptions at 2918, 2850, 1705, 1390, 1230, 842, 742, 545 wavenumbers.

Formulation of Compound 1 with Co-Reactant (Compound 4)

### Preparation of Film

A film formulation was prepared by combining 85% by weight Compound 1 in anisole and 15% by weight of Compound 4, and casting a film from the formulation using an aluminum mold (127 mm×127 mm×0.5 mm) with release agent. The formulation was poured into mold, followed by degassing in a vacuum chamber. The film was dried for at least 1 hour at 100° C., followed by curing at 200° C. for 1 hour.

The Formulation A film composition was analyzed for properties described above under Materials and Methods. Properties of film formulation are summarized in Table 5 below.

TABLE 5

| Properties of Formulation A Film | | |
|---|---|---|
| Property | Value | |
| Tensile Strength | 9.2 | MPa |
| CTE (TMA): | 444 | ppm |
| Elongation | 283% | |
| Dielectric Constant (Dk) | 2.5175 @20 | GHz |
| Loss Tangent (Df) | 0.0018 @20 | GHz |
| Glass Transition Temperature (T_{g}) (TMA) | 33.58° C. | |
| Young's Modulus@25° C. | 13.25 | MPa |
| Td (5%): | 433.5° C. | |
| Peel Strength on Copper foil: | 1.26 | kN/m |

| | |
|---|---|
| Water absorption (23° C./24 hrs); | 0.33% |

### Example 6. Formulation B: Combination of Compound 1 and P-d Benzoxazine Co-Reactant

A solution containing 90% by weight of COMPOUND 1 in anisole (EXAMPLE 1) and 10% by weight of Shikoku Benzoxazine P-d (shown below) (Shikoku Chemicals; Tokyo JP) was prepared.

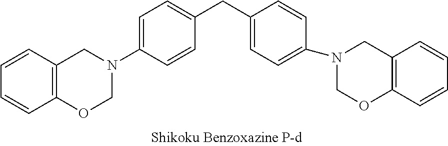 [SMILES: c1ccc2c(c1)CN(c1ccc(Cc3ccc(N4COc5ccccc5C4)cc3)cc1)CO2]

A film was cast from the solution using an aluminum mold (127 mm×127 mm×0.5 mm) with release agent. The solution was poured into the mold and degassed in a vacuum chamber. The film was dried for at least one hour at 100° C., followed by curing at 200° C. for 1 hour.

The Formulation B film composition was analyzed for properties described above under MATERIALS AND METHODS. Properties of the Formulation B film are summarized in Table 6 below.

TABLE 6
Properties of Formulation B Film

| Property | Value |
|---|---|
| Dielectric Constant (Dk) | 2.436 @220 GHz |
| Loss Tangent (Df) | 0.0018 @20 GHz |
| Glass Transition Temperature (T_{g}) (TMA) | 54.8° C. |
| Young's Modulus@25° C. (MPa) | 31.85 |
| Td (5%) air (° C.) | 404 |
| Peel Strength on Copper foil, kN/m | 0.53 |

Formulation B film had low Dk and Df with high thermal stability.

### Example 7. Comparison of Phenolic-Functionalized Polyimide—Benzoxazine Co-Reactant Formulations

Compound 1 was formulated into films with two different benzoxazine-terminated polyimides that differed in molecular weight, as described above in EXAMPLES 4 and 5.

TABLE 7
Effect of Co-reactive Benzoxazine on Properties
of Phenolic-functionalized Polyimide

| | Formulation | |
|---|---|---|
| | A | B |
| | Phenolic-polyimide | |
| | 85% (Compound 1) | 90% (Compound 1) |
| | Benzoxazine | |
| | 15% (Compound 4) | 10% (P-d) |
| Property | Value | Value |
| CTE, ppm/° C. | 444 (linear) | |
| T_{g} (DMA) | 33.58 | 54.81 |
| Modulus @25° C. | 13.25 MPa | 31.85 MPa |
| Dk | 2.5175 | 2.436 |
| Df | 0.0018 | 0.0018 |
| Td (5%) | 433.5 | 404 |
| Peel strength, kN/m | 1.26 | 0.53 |
| % Elongation | 283.00% | 255.00% |
| Tensile strength, MPa | 9.2 | 25.0 |
| Water Absorption (23° C./24hr5) | 0.33% | 0.35% |

The data indicate that phenolic-functionalized polyimide (Compound 1) can be co-cured with commercially available benzoxazine resins while maintaining desirable dielectric properties

### Example 8. Formulations of Phenolic-Functionalized Polyimide (Compound 1) with Silica Fillers and Benzoxazine Co-Reactant

Various percentages of Phenolic-Polyimide (Compound 1), Benzoxazine Co-reactive Resin (Compound 4), and fused Silica (5 μm or 1 μm) were combined and the formulations cast into films as described above.

Films were analyzed for properties described above under Materials and Methods. Properties of film formulation are summarized in Table 8 below.

TABLE 8
Effects of Fused Silica on Selected Properties
of Phenolic-Polyimide-containing Films

| | Formulation | | | | |
|---|---|---|---|---|---|
| Component | C | D | E | F | G |
| Phenolic-Polyimide (Compound 1) | 75% | 50% | 25% | 25% | 21.25% |
| Benzoxazine Resin (Compound 4) | — | — | — | — | 3.75% |
| 5 μm Silica | 25% | 50% | 75% | — | 75% |
| l μm Silica | — | — | — | 75% | — |
| Property | Values | | | | |
| T_{g} (DMA) | 47.46 | 47.12 | 52.13 | 46.138 | 42.2 |
| Modulus @25° C. | 336.8 MPa | 730 MPa | 1.2 GPa | 1.38 GPa | 869 MPa |
| Dk | 2.385 | 2.466 | 2.948 | 3.18 | 2.36 |
| Df | 0.0013 | 0.0010 | 0.0009 | 0.00098 | 0.0011 |
| Td (5%) | 437.65 | 444.38 | 467 | | 467.5 |

The dielectric properties of Compound 1 formulation were improved by adding fused silica, regardless size of the fused silica. The more fused silica, the better the dielectric properties observed. Industry target for dissipation factor (Df) is less than 0.002, which is readily attainable with silica-containing formulations the containing phenol-functionalized polyimide, Compound 1.

### Example 9. Formulations of Phenolic-Functionalized Polyimide and Bismaleimide Resins with and without Fused Silica

Films were cast (as described above) from formulations of Phenolic-functionalized Polyimide (Compound 1) and a Bismaleimide (BMI-3000J), with and without fused silica, in the amounts (weight percent) listed in Table 9 below. BMI-3000J (Designer Molecules; San Diego Calif.) is a proprietary aliphatic maleimide-terminated polyimide with an average molecular weight of 3,000 Daltons. The structure of (BMI-3000J) is shown below.

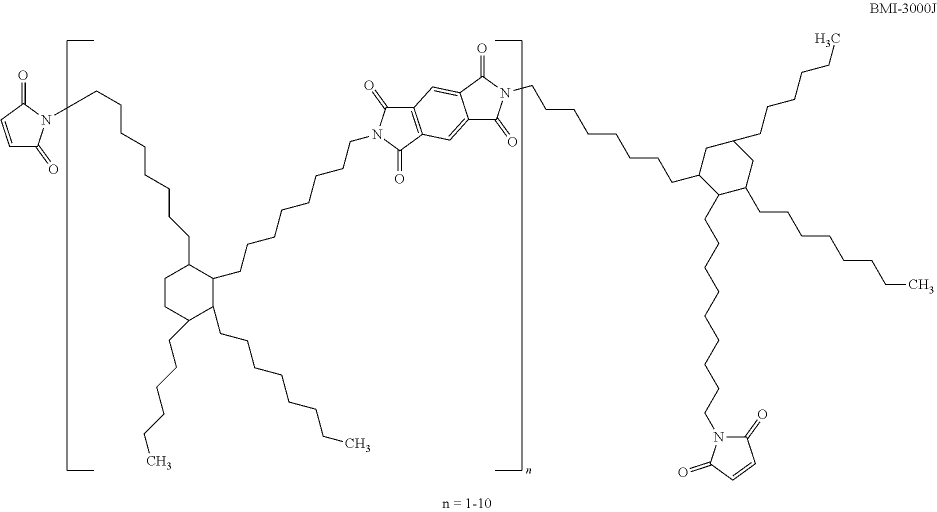

Films were analyzed for properties described above under Materials and Methods. Properties of film formulations are summarized in Table 9 below.

Comparison of Film Properties of Bismaleimide and
Phenolic-functionalized Polyimide
with and without Fused Silica Filler

| | Formulation | | | |
|---|---|---|---|---|
| | H | I | J | K |
| BMI-3000J | 100% | 25% | — | — |
| Compound 1 | — | — | 100% | 25% |
| Fused Silica | — | 75% | — | 75% |
| Properties | Values | | | |
| T_{g} (DMA), ° C. | 65 | 68 | 47.33 | |
| Modulus @25° C., MPa | 300 | 600 | 587 | 1200 |
| Dk @20 GHz | 2.3 | 2.9 | 2.4 | 2.948 |
| Df @20 GHz | 0.0017 | 0.00125 | 0.0014 | 0.0009 |
| Td (5%), C | 438 | 448 | 415.3 | 467 |

This data show that Compound 1 with 75% silica had better dielectric properties than BMI-3000J with 75%.

### Example 10. Formulations of Phenolic-Functionalized Polyimide (Compound 1) with Epoxy Co-Reactant and Silica

Compound 1 (EXAMPLE 1) was combined with Epiclon® HP-4032D epoxy resin (1,6-bis(2,3-Epoxypropoxy) naphthalene) (DIC Corp.; Tokyo, JP)) or the epoxy plus Admafine® SO-E4 1 μm spherical silica filler (Admatechs Co. Ltd.; Miyoshi, JP) in the amounts indicated in Table 10 below. Thin films were cast from each of the formulations and cured as described above.

Films were analyzed for properties as described under Materials and Methods. Properties of the film formulations are summarized below in Table 10.

TABLE 10
Properties of Epoxy-Compound 1 Film Formulations with and without Silica Filler

| | Formulations | | | | | |
|---|---|---|---|---|---|---|
| | L | M | N | O | P | Q |
| Compound 1 | 90% | 80% | 70% | 22.5% | 20% | 17.5% |
| Epiclon ® HP-4032D | 10% | 20% | 30% | 2.5% | 5% | 7.5% |
| Admafine ® SO-E4 | — | — | — | 75% | 75% | 75% |
| Properties | Values | | | | | |
| Peel strength | 0.52 | 0.88 | 1.08 | 0.4 | 0.41 | 0.32 |
| Dk @20 GHz | 2.555 | 2.469 | 2.419 | 3.009 | 3.012 | 3.094 |
| Df @20 GHz | 0.0039 | 0.00492 | 0.00669 | 0.00185 | 0.00275 | 0.0036 |
| T_{g} (° C.) (DMA) | 39.88 | 47.07 | 47.24 | 49.98 | 44.84 | 44.82 |
| Modulus @25° C. | 445.92 MPa | 802.61 MPa | 612.94 MPa | 2.1 GPa | 2.964 GPa | 2.041 GPa |

Co-curing the phenolic-functionalized polyimide with increasing amounts of an epoxy co-reactant increased the adhesion to a copper surface as indicated by commensurate increases in peel strength. However, with increased epoxy content of film formulations, the Df also rose sharply. The addition of silica mitigated the effects on Df somewhat.

1-69. (canceled)

70. A composition comprising a the phenolic-functionalized polyimide having a structure according to Formula I, II or III: 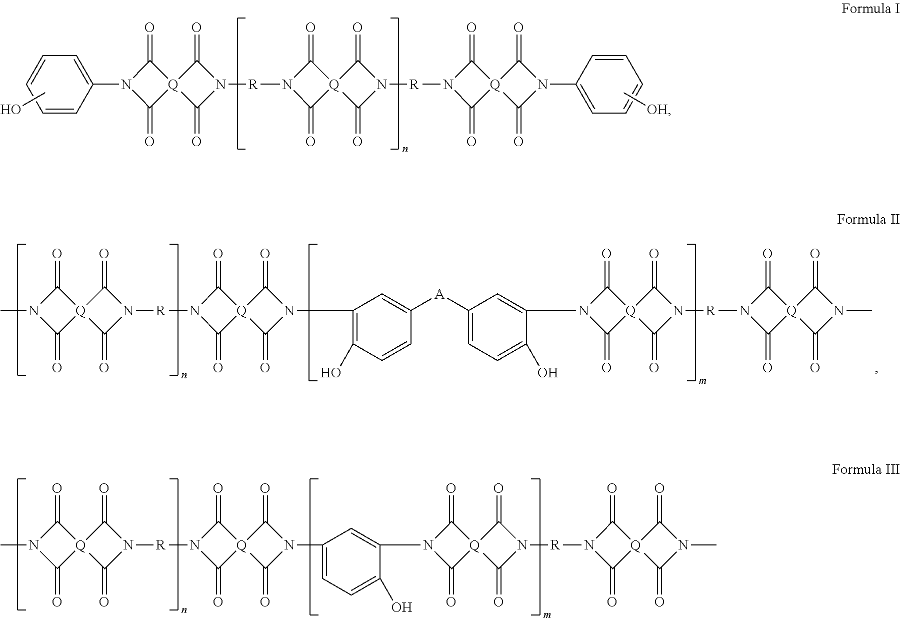
wherein:
R is a moiety independently selected from the group consisting of: substituted or unsubstituted aromatic, heteroaromatic aliphatic, cycloaliphatic, alkenyl, polyether, polyester, polyamide, and siloxane;
Q is a moiety independently selected from the group consisting of: substituted or unsubstituted aromatic, heteroaromatic aliphatic, cycloaliphatic, alkenyl, polyether, polyester, polyamide, and siloxane;
A is a moiety independently selected from the group consisting of: substituted or unsubstituted aromatic, heteroaromatic aliphatic, cycloaliphatic, alkenyl, polyether, polyester, polyamide, and siloxane; and
n and m are each independently 0 or an integer having the value from 1-100 or an integer having the value 20-100;
with the proviso that the average molecular weight of the polyimide is greater than 20,000 Daltons or is 25,000 to 50,000 Daltons; and
optionally comprising anisole.

71. The composition of claim 70, wherein the phenolic-functionalized polyimide is the product of a condensation of at least one diamine with at least one dianhydride.

72. The composition of claim 71, wherein the at least one diamine comprises a diamine selected from the group consisting of: 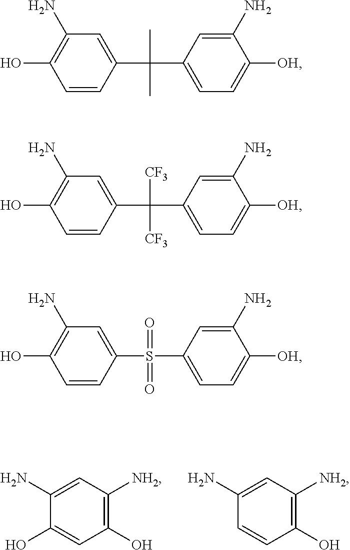 [SMILES: CC(C)(c1ccc(O)c(N)c1)c1ccc(O)c(N)c1 ; Nc1cc(C(c2ccc(O)c(N)c2)(C(F)(F)F)C(F)(F)F)ccc1O ; Nc1cc(S(=O)(=O)c2ccc(O)c(N)c2)ccc1O ; Nc1cc(N)c(O)cc1O ; Nc1ccc(O)c(N)c1]
and combinations thereof; or
comprises a diamine selected from the group consisting of: 1,10-diaminodecane; 1,12-diaminododecane; dimer diamine; hydrogenated dimer diamine; 1,2-diamino-2-methylpropane; 1,2-diaminocyclohexane; 1,2-diaminopropane; 1,3-diaminopropane; 1,4-diaminobutane; 1,5-diaminopentane; 1,7-diaminoheptane; 1,8-diaminomenthane; 1,8-diaminooctane; 1,9-diaminononane; 3,3′-diamino-N-methyldipropylamine; diaminomaleonitrile; 1,3-diaminopentane; 9,10-diaminophenanthrene; 4,4′-diaminooctafluorobiphenyl; 3,5-diaminobenzoic acid; 3,7-diamino-2-methoxyfluorene; 4,4′-diaminobenzophenone; 3,4-diaminobenzophenone; 3,4-diaminotoluene; 2,6-diaminoanthroquinone; 2,6-diaminotoluene; 2,3-diaminotoluene; 1,8-diaminonaphthalene; 2,4-diaminotoluene; 2,5-diaminotoluene; 1,4-diaminoanthroquinone; 1,5-diaminoanthroquinone; 1,5-diaminonaphthalene; 1,2-diaminoanthroquinone; 2,4-cumenediamine; 1,3-bisaminomethylbenzene; 1,3-bisaminomethylcyclohexane; 2-chloro-1,4-diaminobenzene; 1,4-diamino-2,5-dichlorobenzene; 1,4-diamino-2,5-dimethylbenzene; 4,4′-diamino-2,2′-bistrifluoromethylbiphenyl; bis(amino-3-chlorophenyl)ethane; bis(4-amino-3,5-dimethylphenyl)methane; bis(4-amino-3,5-diisopropylphenyl)methane; bis(4-amino-3,5-methyl-isopropylphenyl)methane; bis(4-amino-3,5-diethylphenyl)methane; bis(4-amino-3-ethylphenyl)methane; diaminofluorene; 4,4′-(9-Fluorenylidene)dianiline; diaminobenzoic acid; 2,3-diaminonaphthalene; 2,3-diaminophenol; -5-methylphenyl)methane; bis(4-amino-3-methylphenyl)methane; bis(4-amino-3-ethylphenyl)methane; 4,4′-diaminophenylsulfone; 3,3′-diaminophenylsulfone; 2,2-bis(4-(4-aminophenoxy)phenyl)sulfone; 2,2-bis(4-(3-aminophenoxy)phenyl)sulfone; 4,4′-oxydianiline; 4,4′-diaminodiphenyl sulfide; 3,4′-oxydianiline; 2,2-bis(4-(4-aminophenoxy)phenyl)propane; 1,3-bis(4-aminophenoxy)benzene; 4,4′-bis(4-aminophenoxy)biphenyl; 4,4′-diamino-3,3′-dihydroxybiphenyl; 4,4′-diamino-3,3′-dimethylbiphenyl; 4,4′-diamino-3,3′-dimethoxybiphenyl; Bisaniline M; Bisaniline P; 9,9-bis(4-aminophenyl)fluorene; o-tolidine sulfone; methylene bis(anthranilic acid); 1,3-bis(4-aminophenoxy)-2,2-dimethylpropane; 1,3-bis(4-aminophenoxy)propane; 1,4-bis(4-aminophenoxy)butane; 1,5-bis(4-aminophenoxy)butane; 2,3,5,6-tetramethyl-1,4-phenylenediamine; 3,3′,5,5′-tetramehylbenzidine; 4,4′-diaminobenzanilide; 2,2-bis(4-aminophenyl)hexafluoropropane; polyoxyalkylenediamines; 1,3-cyclohexanebis(methylamine); m-xylylenediamine; p-xylylenediamine; bis(4-amino-3-methylcyclohexyl)methane; 1,2-bis(2-aminoethoxy)ethane; and 3(4),8(9)-bis(aminomethyl)tricyclo(5.2.1.0^{2,6})decane and combinations thereof.

73. The composition of claim 71, wherein the at least one dianhydride comprises a dianhydride selected from the group consisting of: polybutadiene-graft-maleic anhydride; polyethylene-graft-maleic anhydride; polyethylene-alt-maleic anhydride; polymaleic anhydride-alt-1-octadecene; polypropylene-graft-maleic anhydride; poly(styrene-co-maleic anhydride); pyromellitic dianhydride; maleic anhydride, succinic anhydride; 1,2,3,4-cyclobutanetetracarboxylic dianhydride; 1,4,5,8-naphthalenetetracarboxylic dianhydride; 3,4,9,10-perylenentetracarboxylic dianhydride; bicyclo(2.2.2)oct-7-ene-2,3,5,6-tetracarboxylic dianhydride; diethylenetriaminepentaacetic dianhydride; ethylenediaminetetraacetic dianhydride; 3,3′,4,4′-benzophenone tetracarboxylic dianhydride; 3,3′,4,4′-biphenyl tetracarboxylic dianhydride; 4,4′-oxydiphthalic anhydride; 3,3′,4,4′-diphenylsulfone tetracarboxylic dianhydride; 2,2′-bis(3,4-dicarboxyphenyl)hexafluoropropane dianhydride; 4,4′-bisphenol A diphthalic anhydride; 5-(2,5-dioxytetrahydro)-3-methyl-3-cyclohexene-1,2-dicarboxylic anhydride; ethylene glycol bis(trimellitic anhydride); hydroquinone diphthalic anhydride; allyl nadic anhydride; 2-octen-1-ylsuccinic anhydride; phthalic anhydride; 1,2,3,6-tetrahydrophthalic anhydride; 3,4,5,6-tetrahydrophthalic anhydride; 1,8-naphthalic anhydride; glutaric anhydride; dodecenylsuccinic anhydride; hexadecenylsuccinic anhydride; hexahydrophthalic anhydride; methylhexahydrophthalic anhydride; tetradecenylsuccinic anhydride; and combinations thereof.

74. The composition of claim 70, further comprising at least one co-reactant, filler, catalyst, initiator, coupling agent or a combination thereof; and,
optionally, comprising at least one epoxy resin, at least one anionic initiator and at least one coupling agent;
wherein, optionally, the at least one co-reactant is selected from the group consisting of oxetanes, cyanate esters, benzoxazines and combinations thereof; or
is a co-curing epoxy selected from the group consisting of a phenyl glycidyl ether; a cresyl glycidyl ether; a nonylphenyl glycidyl ether; a p-tert-butylphenyl glycidyl ether; a diglycidyl or polyglycidyl ether of any of: bisphenol A, of bisphenol F, ethylidenebisphenol, dihydroxydiphenyl ether, bis(4-hydroxyphenyl)sulfone, bis(hydroxyphenyl)sulfide, 1,1-bis(hydroxyphenyl)cyclohexane, 9,19-bis(4-hydroxyphenyl)fluorene, 1,1,1-tris(hydroxyphenyl)ethane, tetrakis(4-hydroxyphenyl)ethane, trihydroxytritylmethane, 4,4′-(1-alpha-methylbenzylidene)bisphenol, 4,4′-dihydroxybenzophenone, dihydroxy naphthalene, 2,2′-dihydroxy-6,6′-dinaphthyl disulfide, a 1,8,9-trihydroxyanthracene, resorcinol, catechol and tetrahydroxydiphenyl sulfide; triglycidyl-p-aminophenol; N,N,N′,N′-tetraglycidyl-4,4′-diphenylmethane; triglycidyl isocyanurate; a glycidyl ether of a cresol formaldehyde condensate; a glycidyl ether of a phenol formaldehyde condensate; a glycidyl ether of a cresol dicyclopentadiene addition compound; a glycidyl ether of a phenol dicyclopentadiene addition compound; a diglycidyl ether of 1,4 butanediol; a diglycidyl ether of diethylene glycol; a diglycidyl ether of neopentyl glycol; a diglycidyl ether of cyclohexane dimethanol; a diglycidyl ether of tricyclodecane dimethanol; a trimethyolethane triglycidyl ether; mono- or diglycidyl ether of naphthalene derivative; perfluorinated alkyl glycidyl ethers; a trimethyol propane triglycidyl ether; a glycidyl ether of a polyglycol; a polyglycidyl ether of castor oil; a polyoxypropylene diglycidyl ether; a glycidyl derivative of an aromatic amine; and a combination thereof; or
is selected from the group consisting of: 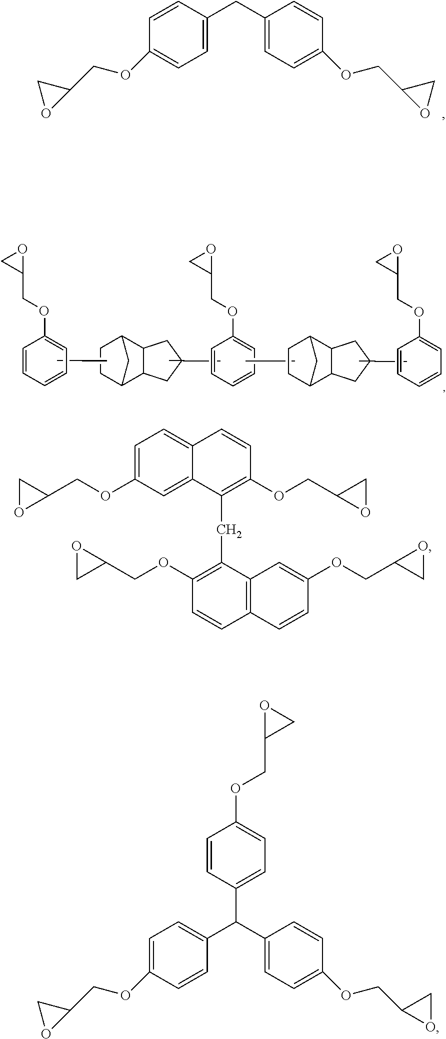
and combinations thereof; or
is selected from the group consisting of: epoxy-terminated polydimethylsiloxanes, and epoxy functionalized cyclosiloxanes, epoxy functionalized polyhedral oligomeric silsesquioxane (POSS), and combinations thereof; and
optionally, wherein the epoxy comprises about 1- to about 90-weight %, about 5- to about 50-weight %, or about 10- to about 25-weight %, of the composition, based on the total weight of the composition.

75. The composition of claim 74, wherein the catalyst is an anionic curing catalyst, or comprises a compound selected from the group consisting of: imidazole; 1-benzyl-2-phenylimidazole (1B2PZ); 1-benzyl-2-methylimidazole (1B2MZ); 2-phenyl-4-methylimidazole (2P4MZ); 2-phenylimidazole (2PZ); 2-ethyl-4-methylimidazole (2E4MZ); 1,2-dimethylimidazole (1.2DMZ); 2-heptadecylimidazole (C17Z); 2-undecylimidazole (C11IZ); 2-methylimidazole (2MZ); imidazole (SIZ); 1-cyanoethyl-2-methylimidazole (2MZ-CN); 1-cyanoethyl-2-undecvlimidazole (C11Z-CN); 1-cyanoethyl-2-ethyl-4-methylimidazole (2E4MZ-CN); 1-cyanoethyl-2-phenylimidazole (2PZ-CN); 1-cyanoethyl-2-phenylimidazolium-trimellitate (2PZCNS-PW); 1-cyanoethyl-2-undecylimidazolium-trimellitate (C11Z-CNS); 2,4-diamino-6-[2′-ethyl-4′-methylimidazolyl-(1′)]-ethyl-s-triazine (2E4MZ-A); 2,4-diamino-6-[2′-undecylimidazolyl-(1′)]-ethyl-s-triazine (C11Z-A); 2,4-diamino-6-[2′-methylimidazolyl-(1′)]-ethyl-s-triazine (2MZA-PW); 2,4-diamino-6-[2′-methylimidazolyl-(1′)]-ethyl-s-triazine (2MZ-A); 2-phenylimidazoleisocyanuric acid adduct (2PZ-OK); 2,4-diamino-6-[2′-methylimidazolyl-(1′)]-ethyl-s-triazineisocyanuric acid adduct dehydrate (2MA-OK); 2-phenyl-4-methyl-5-hydroxymethylimidazole (2P4MHZ-PW); 2-phenyl-4,5-dihydroxymethylimidazole (2PHZ-PW); 1-dodecyl-2-methyl-3-benzylimidazolium chloride (SFZ); 2,3-dihydro-1H-pyrrolo[1,2-a]benzimidazole (TBZ); 2-phenylimidazoline (2PZL-T); 2,4-diamino-6-methacryloyloxyethyl-1,3,5-triazine (MAVT); 2,4-diamino-6-vinyl-1,3,5-triazineisocyanuric acid adduct (OK); 2,4-diamino-6-vinyl-1,3,5-triazine (VT); Imidazole-4-carboxaldehyde (4FZ); 2-Phenylimidazole-4-carboxaldehyde (2P4FZ); Imidazole-2 carboxaldehyde (2FZ); Imidazole-4-carbonitrile (4CNZ); 2-Phenylimidazole-4-carbonitrile (2P4CNZ); 4-Hydroxymethylimidazolehydrochloride (4HZ-HCL); 2-Hydroxymethylimidazolehydrochloride (2HZ-HCL); Imidazole-4-carboxylic acid (4GZ); Imidazole-4-dithiocarboxylic acid (4SZ); Imidazole-4-thiocarboxamide (4TZ); 2-Bromoimidazole (2BZ); 2-Mercaptoimidazole (2SHZ); 1,2,4-Triazole-1-carboxamidinehydrochloride (TZA); (t-Butoxycarbonylimino-[1,2,4]triazol-1-yl-Methyl)-carbamic acid t-butyl ester (TZA-BOC); Thiazole-2-carboxaldehyde (2FTZ); Thiazole-4-carboxaldehyde (4FTZ); Thiazole-5-carboxaldehyde (5FTZ); Oxazole-2-carboxaldehyde (2FOZ); Oxazole-4-carboxaldehyde (4FOZ); Oxazole-5-carboxaldehyde (5FOZ); Pyrazole-4-carboxaldehyde (4FPZ); Pyrazole-3-carboxaldehyde (3FPZ); 1-azabicyclo[2.2.2]octane (ABCO); 1,4-diazabicyclo[2.2.2]octane (DABCO); 1,5-diazabicyclo[4.3.0]non-5-ene (DBN); 1,8-diazabicyclo[5.4.0]undec-7-ene (DBU); 1,5,7-triazabicyclo[4.4.0]dec-5-ene (TBD); 7-methyl-1,5,7-triazabicyclo[4.4.0]dec-5-ene (MTBD); 1,2,2,6,6-pentamethylpiperidine (PMP); 4-(dimethylamino)-1,2,2,6,6-pentamethylpiperidine; and combinations thereof; or
comprises about 0.1 to about 10-weight %, or about 0.5 to about 5-weight % of the composition, based on the total weight of the composition.

76. The composition of claim 74, wherein the filler comprises at least one filler selected from the group consisting of: silica, polytetrafluoroethylene, alumina, boron nitride, carbon black, carbon nanotubes or a combination thereof, or
wherein the filler is conductive and is optionally selected from the group consisting of: gold, copper, silver; platinum, palladium and combinations and alloys thereof.

77. The composition of claim 70, wherein the composition is an adhesive that is optionally removable, or is B-staged, or is a film or a coating.

78. The composition of claim 77, wherein the adhesive is cured.

79. A method for preparing a prepreg comprising the steps of:
a. providing a reinforcing fiber which is optionally a woven or unwoven fabric; and
b. immersing the reinforcing fiber in a liquid formulation of an uncured composition comprising a composition of claim 70, thereby impregnating the reinforcing fiber;
and optionally the steps of:
c. draining the prepreg to remove excess liquid formulation; and
d. drying the prepreg;
thereby preparing a prepreg.

80. A prepreg prepared according to the method of claim 79.

81. A method for preparing a copper-clad laminate (CCL) comprising the steps of:
a. providing the prepreg of claim 80; and
b. disposing copper on one or both sides of the prepreg;
wherein, optionally, disposing consists of electroplating copper to the one or the both sides of the prepreg or laminating copper foil to the one or the both sides of the prepreg;
thereby. preparing a copper-clad laminate.

82. A CCL comprising a reinforcing fiber impregnated with a composition of claim 1 having copper disposed on one or both sides,
wherein, optionally, the CCL is prepared by a method comprising the steps of:
a. providing the prepreg comprising a reinforcing fiber impregnated with a composition of claim 70; and
b. disposing copper on one or both sides of the prepreg;
wherein, optionally, disposing consists of electroplating copper to the one or the both sides of the prepreg or laminating copper foil to the one or the both sides of the prepreg;
thereby. preparing a copper-clad laminate.

83. A method for preparing a printed circuit board (PCB) comprising the steps of:
a. providing the CCL of claim 82;
b. etching circuit traces in the copper disposed on the one or the both sides of the CCL,
thereby preparing a printed circuit board.

84. A method for preparing a flexible copper-clad laminate (FCCL) comprising the steps of:
a. providing a film that is optionally adhesive comprising a compound according to claim 70;
b. optionally, applying an adhesive to one of both sides of the film; and
c. laminating copper foil to the adhesive on the one or the both sides of the film,
thereby preparing a FCCL.

85. An FCCL comprising a film formulation of the composition of claim 70, wherein the film formulation is optionally adhesive;
having copper foil laminated to one or both sides of the film; and
optionally comprising an adhesive layer between each copper foil and the film.

86. An FCCL prepared according to the method of claim 84.

87. A method for preparing a thin, flexible electronic circuit, comprising the steps of:
a. providing the FCCL of claim 86; and
b. etching circuit traces in the copper foil on one or both sides of the FCCL;
thereby preparing a thin, flexible circuit.

88. A method for backgrinding a wafer, comprising the steps of:
a. applying a removable adhesive composition of claim 70 to the top of a wafer, wherein applying the removable adhesive composition optionally comprises spin-coating;
b. adhering the wafer to a support;
c. grinding and polishing the wafer;
d. removing the wafer from the support; and
e. removing the adhesive from the wafer;
wherein removing the adhesive optionally comprises, the steps of:
i. applying an air jet to the removable adhesive composition;
ii. peeling the adhesive from the temporary wafer; and
iii. optionally, soaking the wafer in a chemical solvent that removes residual adhesive.
thereby backgrinding a wafer.

89. A method for synthesizing a phenolic-functionalized compound having a structure according to Formula I, II or III: 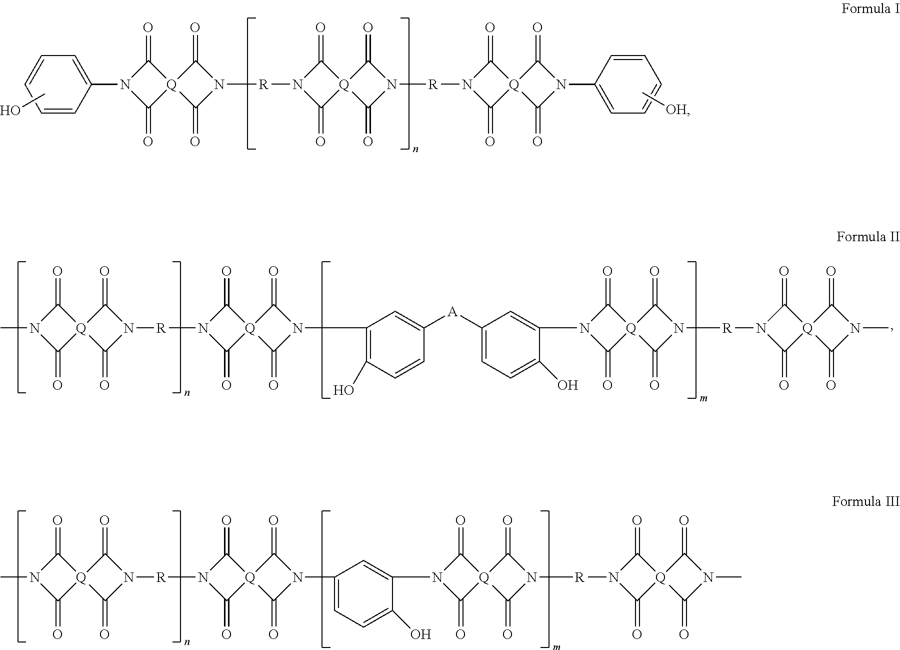
wherein:
R is a moiety independently selected from the group consisting of: substituted or unsubstituted aromatic, heteroaromatic aliphatic, cycloaliphatic, alkenyl, polyether, polyester, polyamide, and siloxane;
Q is a moiety independently selected from the group consisting of: substituted or unsubstituted aromatic, heteroaromatic aliphatic, cycloaliphatic, alkenyl, polyether, polyester, polyamide, and siloxane;
A is a moiety independently selected from the group consisting of: substituted or unsubstituted aromatic, heteroaromatic aliphatic, cycloaliphatic, alkenyl, polyether, polyester, polyamide, and siloxane; and n and m are each independently 0 or an integer having the value from 1-100; with the proviso that the average molecular weight of the polyimide is greater than 20,000 Daltons;
comprising the steps of
a. providing at least one diamine and at least one dianhydride;
b. combining the at least one diamine with the at least one dianhydride in a solvent to form a mixture, wherein the solvent is optionally anisole;
c. refluxing the mixture, thereby forming a polyamic acid in the solution; and
d. azeotropically distilling the polyamic acid in the solution; thereby forming an amine-terminated polyimide in the solution;
wherein either:
i. the at least one diamine comprises a phenol functionality;
ii. the at least one dianhydride comprises a phenol functionality; or
iii. further comprising the step of functionalizing the amine-terminated polyimide by reacting the terminal amine groups to form a phenol functional terminal moiety.
thereby synthesizing the phenol-functionalized compound.
